(19) United States
(12) Patent Application Publication
(10) Pub. No.: US 2024/0298541 A1
(43) Pub. Date: Sep. 5, 2024

(54) ORGANIC ELECTROLUMINESCENT MATERIALS CONTAINING B-N FUSED RINGS, AND APPLICATIONS THEREOF

(71) Applicant: GUANGDONG AGLAIA OPTOELECTRONIC MATERIALS CO., LTD., Foshan, Guangdong (CN)

(72) Inventors: Keyan BAI, Foshan (CN); Kaichun LIANG, Foshan (CN); Shaofu CHEN, Foshan (CN); Lei DAI, Foshan (CN); Lifei CAI, Foshan (CN)

(73) Assignee: GUANGDONG AGLAIA OPTOELECTRONIC MATERIALS CO., LTD., Foshan, Guangdong (CN)

(21) Appl. No.: 18/562,205

(22) PCT Filed: May 10, 2022
(86) PCT No.: PCT/CN2022/091828

§ 371 Date: Nov. 17, 2023

(30) Foreign Application Priority Data
Jun. 24, 2021 (CN) 202110702684.X
Mar. 15, 2022 (CN) 202210251081.7

(51) Int. Cl. H10K 85/60; C07F 5/02; C09K 11/06; H10K 50/12; H10K 101/20

(52) U.S. Cl. CPC H10K 85/658; C07F 5/027; C09K 11/06; C09K 2211/1007; C09K 2211/1018; H10K 50/12; H10K 2101/20

(57) ABSTRACT

The present invention relates to a series of organic electroluminescent materials containing B—N fused rings, which has a structure represented by Formula (I). Based on the principle of thermally activated delayed fluorescence (TADF), the materials have internal quantum efficiency of 100%. In addition, by utilizing a multiple resonance effect between B—N, the materials have small half-wave width and good color purity. With introduction of indolo[3,2,1-JK]carbazole, the multiple resonance effect is further enhanced, and the luminous efficiency and the color purity are significantly improved. Moreover, such compounds have good thermal stability and meet requirements of OLED panels for luminescent materials. The present invention further provides an organic electroluminescent device, and at least one of organic layers in the device contains the compound represented by Structural Formula (I).

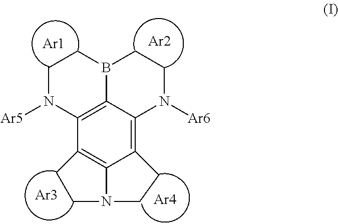

### TECHNICAL FIELD

The present invention relates to the field of luminescent materials, and specifically relates to organic luminescent materials containing B—N fused rings and application thereof in an organic light-emitting diode.

### BACKGROUND

Organic light emission diodes (OLEDs) have been widely used in the display and lighting industries, especially in mobile phone display. OLED screens are used in all latest mobile phone products promoted by mobile phone manufacturers, such as Apple, Samsung, Huawei and Xiaomi, mainly because the OLEDs have excellent characteristics of spontaneous luminescence, wide viewing angle, high contrast, high response speed, possibility in preparing flexible devices and the like.

At present, commercial OLEDs have a multi-layer sandwich structure, including an anode, a hole injection layer, a hole transport layer, a light-emitting layer, an electron transport layer, an electron injection layer, a cathode and the like. Holes produced in the anode move to the light-emitting layer through the hole injection layer and the hole transport layer, electrons move from the cathode to the light-emitting layer through the electron injection layer and the electron transport layer, and the holes and electrons are compounded in the light-emitting layer to produce excitons. The excitons undergo transition from an excited state to a ground state, so as to emit visible light. In order to achieve colorful display, the principle of additive color is used in the OLEDs, that is to say, the light-emitting layer is further divided into a blue light-emitting layer, a green light-emitting layer and a red light-emitting layer, and organic materials with different light-emitting colors are used for different light-emitting layers.

When applied to display, the OLEDs are required to have low driving voltage, high luminous efficiency and long service life. Therefore, during gradual improvement of display performance, the organic materials have been developed from fluorescent materials to phosphorescent materials, and then to thermally activated delayed fluorescence (TADF) materials. At present, phosphorescent materials are used as green and red light materials, which can use both singlet excitons to emit light and triplet excitons to emit light, thus having internal quantum efficiency of 100%. However, the phosphorescent materials contain heavy metals and have the problems of expensive price, poor material stability and the like. Meanwhile, fluorescent materials are used as blue light materials, which can only use singlet excitons to emit light. Although the principle of triplet-triplet annihilation (TTA, two triplet excitons are converted into one singlet exciton) is used, the fluorescent materials only have theoretical efficiency of 40%, which is far from meeting market demands. As for the TADF materials, based on small singlet-triplet energy splitting (ΔEST), triplet excitons can be converted into singlet excitons by reverse intersystem crossing. Therefore, the TADF materials can also have internal quantum efficiency of 100%. However, the TADF materials have strong charge transfer characteristics (CT) and too large spectrum half-wave width, which are not conducive to display with high color purity.

### SUMMARY

In view of the existing problems of the above organic materials, the present invention provides organic luminescent materials containing B—N fused rings and application thereof in an organic luminescent device. Based on the principle of TADF, B—N fused ring structures of the materials can achieve a multiple resonance effect. In addition, with introduction of indolo[3,2,1-JK]carbazole and derivatives thereof, the multiple resonance effect is further enhanced. Resulting molecules have large rigid planes, intramolecular vibration can be effectively inhibited, and efficient organic luminescent materials with small half-wave width are obtained.

The present invention further provides organic electroluminescent materials containing B—N fused ring structures, which have a structure represented by General Formula (I):

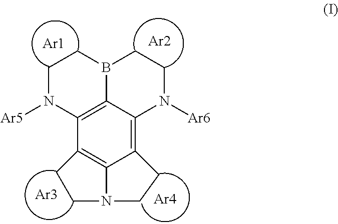

where
Ar1 to Ar4 are independently selected from substituted or unsubstituted aryl containing 6-30 carbon atoms, and substituted or unsubstituted heteroaryl containing 5-30 carbon atoms;
Ar5 and Ar6 are independently selected from substituted or unsubstituted C₁-C₆₀ alkyl, substituted or unsubstituted C₂-C₆₀ alkenyl, substituted or unsubstituted C₂-C₆₀alkynyl, substituted or unsubstituted C₁-C₆₀alkoxyl, substituted or unsubstituted C₃-C₁₀cycloalkyl, substituted or unsubstituted C₁-C₁₀ heterocyclic alkyl, substituted or unsubstituted C₃-C₁₀cycloalkenyl, substituted or unsubstituted C₁-C₁₀ heterocyclic alkenyl, substituted or unsubstituted C₆-C₆₀ aryl, substituted or unsubstituted C₆-C₆₀ aryloxyl, substituted or unsubstituted C₆-C₆₀ arylthio, substituted or unsubstituted C₁-C₆₀ heteroaryl, a substituted or unsubstituted non-aromatic fused polycyclic ring, and a substituted or unsubstituted non-aromatic fused heteropolycyclic ring, or one or more of the Ar1 to Ar6 are bonded to the adjacent group Ar1 or Ar2 by any one or more of a single bond, —C—C—, —C═C—, —C═N—, —C═P—, —C≡C—,

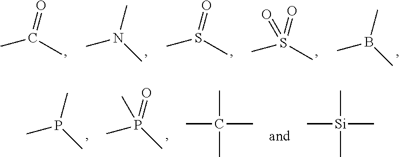

to form a ring structure, respectively;
at least one group of the Ar1 and the Ar2, and the Ar5 and the Ar6 are different;
the “substituted” refers to substitution with one or more of deuterium, cyano, nitro, halogen, hydroxyl, alkylthio containing 1 to 4 carbon atoms, substituted or unsubstituted alkyl containing 1 to 30 carbon atoms, substituted or unsubstituted cycloalkyl containing 1 to 20 carbon atoms, aryloxyl containing 6 to 30 carbon atoms, alkoxyl containing 1 to 30 carbon atoms, alkyl amino containing 1 to 30 carbon atoms, aryl amino containing 6 to 30 carbon atoms, aralkyl amino containing 6 to 30 carbon atoms, heteroaryl amino containing 2 to 24 carbon atoms, alkyl silyl containing 1 to 30 carbon atoms, aryl silyl containing 6 to 30 carbon atoms, alkyl containing 1 to 30 carbon atoms, alkenyl containing 2 to 30 carbon atoms, alkynyl containing 2 to 24 carbon atoms, aralkyl containing 7 to 30 carbon atoms, aryl containing 6 to 30 carbon atoms, heteroaryl containing 5 to 60 carbon atoms, and heteroaryl alkyl containing 6 to 30 carbon atoms;
and the heterocyclic alkyl, the heterocyclic alkenyl and the heteroaryl contain one or more heteroatoms of N, S, O, P, B and Si.

The structure is selected from one of structures represented by General Formulas (II-1)-(II-10):

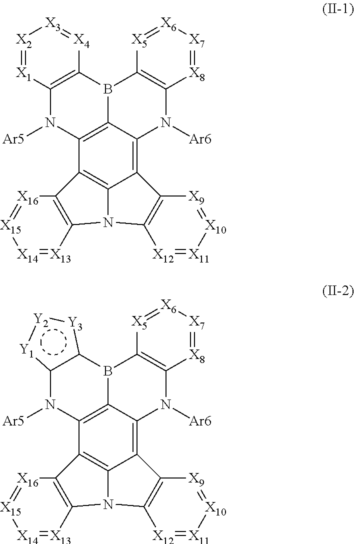

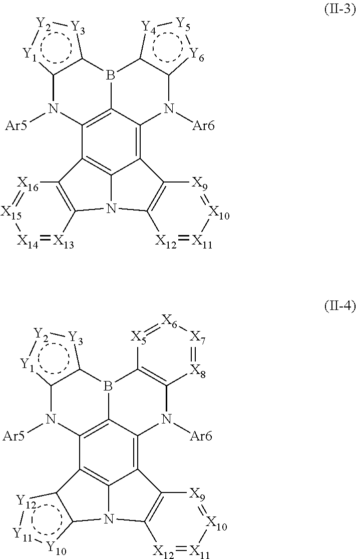

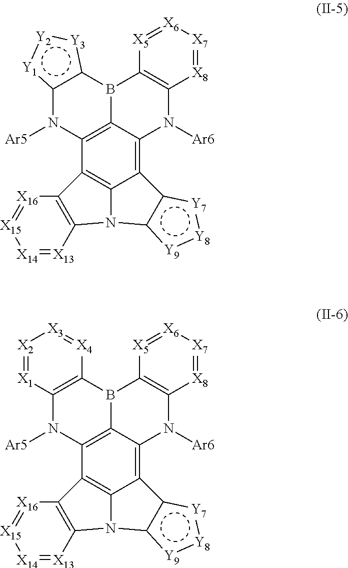

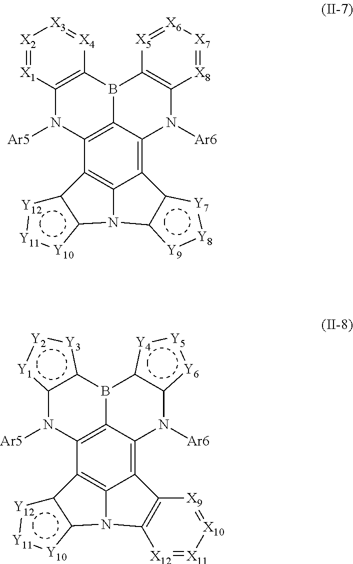

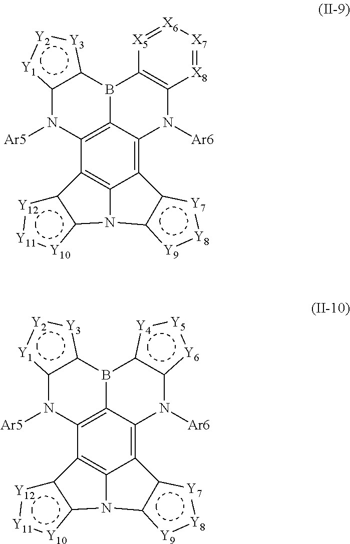

where X₁-X₁₆ independently refer to a nitrogen atom or CR1, R1 is eaually or unequally independently selected from one of a hydrogen atom, a protium atom, a deuterium atom, a tritium atom, a fluorine atom, cyano, phosphoric acid or salts thereof, linear or branched C₁-C₂₀ alkyl, linear or branched silyl substituted with C₁-C₂₀ alkyl, substituted or unsubstituted C₆-C₃₀ aryl, and substituted or unsubstituted C₅-C₃₀heteroaryl, or two or more R1 are connected to each other to form an alkyl ring, a heteroalkyl ring, an aromatic ring, or a heteroaromatic ring;
one of Y₁-Y₃, Y₄-Y₆, Y₇-Y₉ and Y₁₀-Y₁₂ independently refers to an oxygen atom, a sulfur atom, N—R2, R3-C—R4, C═O, C═S, R5-Si—R6, P—R7, P═O, or O═P═O, other groups are independently selected from a nitrogen atom or C—R8, R2 to R8 are equally or unequally independently selected from one of a hydrogen atom, a protium atom, a deuterium atom, a tritium atom, a fluorine atom, cyano, phosphoric acid or salts thereof, linear or branched C₁-C₂₀ alkyl, linear or branched silyl substituted with C₁-C₂₀ alkyl, substituted or unsubstituted C₆-C₃₀ aryl, and substituted or unsubstituted C₅-C₃₀heteroaryl, or the R2-R8 are independently or mutually bonded to each other by any one or more of a single bond, —C—C—, —C═C—, —C═N—, —C═P—, —C≡C—,

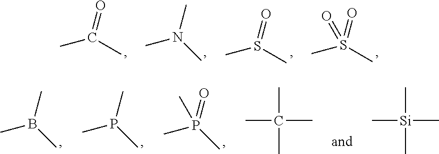

to form a ring structure;

Ar5 and Ar6 are independently selected from a substituted or unsubstituted C₁-C₆₀ alkyl group, a substituted or unsubstituted C₂-C₆₀ alkenyl group, a substituted or unsubstituted C₂-C₆₀alkynyl group, a substituted or unsubstituted C₁-C₆₀alkoxyl group, a substituted or unsubstituted C₃-C₁₀cycloalkyl group, a substituted or unsubstituted C₁-C₁₀ heterocyclic alkyl group, a substituted or unsubstituted C₃-C₁₀cycloalkenyl group, a substituted or unsubstituted C₁-C₁₀ heterocyclic alkenyl group, a substituted or unsubstituted C₆-C₆₀ aryl group, a substituted or unsubstituted C₆-C₆₀aryloxyl group, a substituted or unsubstituted C₆-C₆₀arylthio group, a substituted or unsubstituted C₁-C₆₀heteroaryl group, a substituted or unsubstituted non-aromatic fused polycyclic ring group, and a substituted or unsubstituted non-aromatic fused heteropolycyclic ring group, and one or more of the Ar5 and the Ar6 are connected to the adjacent group Ar1 or Ar2 by any one or more of a single bond, —C—C—, —C═C—, —C═N—, —C═P—, —C≡C—,

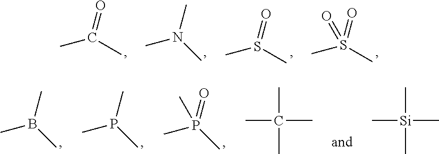

to form a ring, respectively;
the “substituted” refers to substitution with one or more substituents selected from the group consisting of deuterium, cyano, nitro, halogen, hydroxyl, alkylthio containing 1 to 4 carbon atoms, substituted or unsubstituted alkyl containing 1 to 30 carbon atoms, substituted or unsubstituted cycloalkyl containing 1 to 20 carbon atoms, aryloxyl containing 6 to 30 carbon atoms, alkoxyl containing 1 to 30 carbon atoms, alkyl amino containing 1 to 30 carbon atoms, aryl amino containing 6 to 30 carbon atoms, aralkyl amino containing 6 to 30 carbon atoms, heteroaryl amino containing 2 to 24 carbon atoms, alkyl silyl containing 1 to 30 carbon atoms, aryl silyl containing 6 to 30 carbon atoms, alkyl containing 1 to 30 carbon atoms, alkenyl containing 2 to 30 carbon atoms, alkynyl containing 2 to 24 carbon atoms, aralkyl containing 7 to 30 carbon atoms, aryl containing 6 to 30 carbon atoms, heteroaryl containing 5 to 60 carbon atoms, and heteroaryl alkyl containing 6 to 30 carbon atoms;
and the heteroaryl, the heteroalkyl ring and the heteroaromatic ring contain one or more heteroatoms selected from N, O, S, or Si.

At least one group of the X1 and the X8, the X2 and the X7, the X3 and the X6, the X4 and the X5, the Y1 and the Y6, the Y2 and the Y5, the Y3 and the Y4, and the Ar5 and the Ar6 are different.

The X₁-X₁₆ independently refer to a nitrogen atom or CR1, R1 is equally or unequally independently selected from one of a hydrogen atom, a protium atom, a deuterium atom, a tritium atom, a fluorine atom, cyano, linear or branched C₁-C₈ alkyl, substituted or unsubstituted C₆-C₂₀ aryl, and substituted or unsubstituted C₅-C₂₀heteroaryl, or two or more R1 are connected to each other to form an alkyl ring, a heteroalkyl ring, an aromatic ring, or a heteroaromatic ring;
one of the Y₁-Y₃, the Y₄-Y₆, the Y₇-Y₉ and the Y₁₀-Y₁₂ independently refers to an oxygen atom, a sulfur atom, N—R2, or R3-C—R4, other groups are independently selected from a nitrogen atom or C—R8, the R2 to R8 are equally or unequally independently selected from one of a hydrogen atom, a protium atom, a deuterium atom, a tritium atom, a fluorine atom, cyano, linear or branched C₁-C₂₀ alkyl, substituted or unsubstituted C₆-C₃₀ aryl, and substituted or unsubstituted C₅-C₃₀heteroaryl, or the R2-R8 are independently or mutually bonded to each other by any one or more of a single bond, —C—C—, —C═C—, —C═N—, —C≡C—,

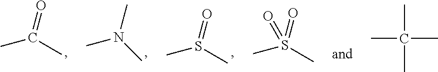

to form an alkyl ring, a heteroalkyl ring, an aromatic ring, or a heteroaromatic ring;
the Ar5 and the Ar6 are independently selected from substituted or unsubstituted C₁-C₈ alkyl, substituted or unsubstituted C₂-C₁₀ alkenyl, substituted or unsubstituted C₂-C₁₀alkynyl, substituted or unsubstituted C₁-C₈₀alkoxyl, substituted or unsubstituted C₃-C₁₀cycloalkyl, substituted or unsubstituted C₁-C₈ heterocyclic alkyl, substituted or unsubstituted C₃-C₁₀cycloalkenyl, substituted or unsubstituted C₁-C₁₀ heterocyclic alkenyl, substituted or unsubstituted C₆-C₂₀ aryl, substituted or unsubstituted C₆-C₂₀aryloxyl, a substituted or unsubstituted C₆-C₂₀arylthio group, substituted or unsubstituted C₁-C₂₀heteroaryl, a substituted or unsubstituted non-aromatic fused polycyclic ring group, and a substituted or unsubstituted non-aromatic fused heteropolycyclic ring group, and one or more of the Ar5 and the Ar6 are connected to the adjacent group Ar1 or Ar2 by any one or more of a single bond, —C—C—, —C═C—, —C═N—, —C≡C—,

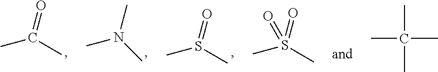

to form a ring, respectively;
the “substituted” refers to substitution with one or more substituents selected from the group consisting of deuterium, cyano, nitro, halogen, hydroxyl, alkylthio containing 1 to 4 carbon atoms, substituted or unsubstituted alkyl containing 1 to 8 carbon atoms, substituted or unsubstituted cycloalkyl containing 1 to 10 carbon atoms, aryloxyl containing 6 to 20 carbon atoms, alkoxyl containing 1 to 10 carbon atoms, alkyl amino containing 1 to 10 carbon atoms, aryl amino containing 6 to 20 carbon atoms, aralkyl amino containing 6 to 20 carbon atoms, heteroaryl amino containing 2 to 10 carbon atoms, alkenyl containing 2 to 10 carbon atoms, alkynyl containing 2 to 10 carbon atoms, aralkyl containing 7 to 20 carbon atoms, aryl containing 6 to 20 carbon atoms, heteroaryl containing 5 to 20 carbon atoms, and heteroaryl alkyl containing 6 to 20 carbon atoms;
and the heteroaryl, the heteroalkyl ring and the heteroaromatic ring contain one or more heteroatoms selected from N, O, S, or Si.

The X₁-X₁₆ independently refer to a nitrogen atom or CR1, R1 is equally or unequally independently selected from one of a hydrogen atom, linear or branched C₁-C₈ alkyl, substituted or unsubstituted C₆-C₂₀ aryl, and substituted or unsubstituted C₅-C₂₀heteroaryl, or two or more R1 are connected to each other to form an alkyl ring, a heteroalkyl ring, an aromatic ring, or a heteroaromatic ring; one of the Y₁-Y₃, the Y₄-Y₆, the Y₇-Y₉ and the Y₁₀-Y₁₂ independently refers to an oxygen atom, a sulfur atom, or N—R2, other groups are independently selected from a nitrogen atom or C—R8, the R2 and the R8 are equally or unequally independently selected from one of a hydrogen atom, linear or branched C₁-C₂₀ alkyl, substituted or unsubstituted C₆-C₂₀ aryl, and substituted or unsubstituted C₅-C₂₀ heteroaryl, or the R2 and the R8 are independently or mutually bonded to each other by any one or more of a single bond, —C—C—, —C═C—, —C═N—,

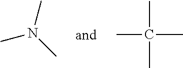

to form an alkyl ring, a heteroalkyl ring, an aromatic ring, or a heteroaromatic ring;
the Ar5 and the Ar6 are independently selected from substituted or unsubstituted C₁-C₈ alkyl, substituted or unsubstituted C₂-C₁₀ alkenyl, substituted or unsubstituted C₁-C₅₀alkoxyl, substituted or unsubstituted C₃-C₁₀cycloalkyl, substituted or unsubstituted C₁-C₈ heterocyclic alkyl, substituted or unsubstituted C₃-C₁₀cycloalkenyl, substituted or unsubstituted C₁-C₁₀ heterocyclic alkenyl, substituted or unsubstituted C₆-C₂₀ aryl, substituted or unsubstituted C₆-C₂₀aryloxyl, a substituted or unsubstituted C₆-C₂₀arylthio group, substituted or unsubstituted C₁-C₂₀heteroaryl, a substituted or unsubstituted non-aromatic fused polycyclic ring group, and a substituted or unsubstituted non-aromatic fused heteropolycyclic ring group, or one or more of the Ar5 and the Ar6 are connected to the adjacent group Ar1 or Ar2 by any one or more of a single bond, —C—C—, —C═C—, —C═N—,

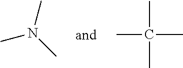

to form a ring, respectively;
the “substituted” refers to substitution with one or more substituents selected from the group consisting of deuterium, alkyl containing 1 to 8 carbon atoms, cycloalkyl containing 1 to 10 carbon atoms, aryl containing 6 to 20 carbon atoms, heteroaryl containing 5 to 20 carbon atoms, and heteroaryl alkyl containing 6 to 20 carbon atoms;
and the heteroaryl, the heteroalkyl ring and the heteroaromatic ring contain one or more heteroatoms selected from N, O, or S.

The structure is selected from one of the structures represented by General Formulas (II-1)-(II-3), where the X₁-X₁₆ independently refer to a nitrogen atom or CR1, and R1 is equally or unequally independently selected from one of a hydrogen atom, linear or branched C₁-C₈ alkyl, and substituted or unsubstituted C₆-C₂₀ aryl;
one of the Y₁-Y₃, the Y₄-Y₆, the Y₇-Y₉ and the Y₁₀-Y₁₂ independently refers to an oxygen atom, a sulfur atom, or N—R2, other groups are independently selected from C—R8, the R2 and the R8 are equally or unequally independently selected from one of a hydrogen atom, linear or branched C₁-C₂₀ alkyl, and substituted or unsubstituted C₆-C₂₀ aryl, or the R8 is mutually bonded by any one or more of a single bond, —C—C— and —C═C— to form an alkyl ring or a six-membered aromatic ring;
the Ar5 and the Ar6 are independently selected from substituted or unsubstituted C₁-C₈ alkyl, substituted or unsubstituted C₆-C₂₀ aryl, substituted or unsubstituted C₁-C₂₀heteroaryl, a substituted or unsubstituted non-aromatic fused polycyclic ring group, and a substituted or unsubstituted non-aromatic fused heteropolycyclic ring group, or one of the Ar5 and the Ar6 is connected to the adjacent group Ar1 or Ar2 by any one or more of a single bond and —C—C— to form a ring, respectively;
the “substituted” refers to substitution with one or more substituents selected from the group consisting of deuterium, alkyl containing 1 to 8 carbon atoms, cycloalkyl containing 1 to 10 carbon atoms, and aryl containing 6 to 10 carbon atoms;
and the heteroaryl contains one or more heteroatoms selected from N, O, S, or Si.

Optionally, the X₉-X₁₆ independently refer to CR1, and R1 is equally or unequally independently selected from one of a hydrogen atom, linear or branched C₁-C₄ alkyl, and substituted or unsubstituted C₆-C₁₀ aryl.

The aryl is optionally selected from one or more of phenyl, naphthyl, anthracyl, binaphthyl, phenanthryl, dihydrophenanthryl, pyrenyl, perylenyl, tetracenyl, pentacenyl, benzoperylenyl, benzocyclopentadienyl, spirofluorenyl and fluorenyl; and the aryl is more optionally selected from one or more of phenyl, naphthyl, anthracyl, phenanthryl, dihydrophenanthryl, tetracenyl, pentacenyl, benzoperylenyl, benzocyclopentadienyl, spirofluorenyl and fluorenyl.

The heteroaryl is optionally selected from one or more of pyrrolyl, imidazolyl, thienyl, furyl, 1,2-thiazolyl, 1,3-thiazolyl, 1,2,3-oxadiazolyl, 1,2,4-oxadiazolyl, thiadiazolyl, selenadiazolyl, 1,2,3-triazolyl, 1,2,4-triazolyl, pyridinyl, pyrazinyl, pyrimidinyl, 1,3,5-triazinyl, 1,2,4-triazinyl, 1,2,3-triazinyl, indolyl, isoindolyl, benzimidazolyl, naphthoimidazolyl, phenanthroimidazolyl, benzotriazolyl, purinyl, benzoxazolyl, naphthoxazolyl, phenanthroxazolyl, benzothiadiazolyl, benzoselenadiazolyl, benzotriazolyl, quinolyl, isoquinolyl, benzopyrazinyl, benzothienyl, benzofuryl, benzopyrrolyl, carbazolyl, acridinyl, dibenzothienyl, dibenzofuryl, silafluorenyl, dibenzothiophene-5,5-dioxo, naphthothiadiazolyl, naphthoselenadiazolyl and 10,15-dihydro-5H-diindolo[3,2-a:3′,2′-c]carbazolyl; and the heteroaryl is more optionally selected from one or more of pyrrolyl, imidazolyl, thienyl, furyl, 1,2-thiazolyl, 1,3-thiazolyl, 1,2,3-oxadiazolyl, 1,2,4-oxadiazolyl, thiadiazolyl, selenadiazolyl, 1,2,3-triazolyl, 1,2,4-triazolyl, pyridinyl, pyrazinyl, pyrimidinyl, 1,3,5-triazinyl, 1,2,4-triazinyl, 1,2,3-triazinyl, indolyl, isoindolyl, benzimidazolyl, naphthoimidazolyl, phenanthroimidazolyl, benzotriazolyl, purinyl, benzoxazolyl, naphthoxazolyl, phenanthroxazolyl, benzothiadiazolyl, benzotriazolyl, quinolyl, isoquinolyl, benzopyrazinyl, benzothienyl, benzofuryl, benzopyrrolyl, carbazolyl, acridinyl, dibenzothienyl, dibenzofuryl, dibenzothiophene-5,5-dioxo, naphthothiadiazolyl, naphthoselenadiazolyl and 10,15-dihydro-5H-diindolo[3,2-a:3′,2′-c]carbazolyl.

Optionally, the organic compounds have the following specific structures, but are not limited to the structures listed:

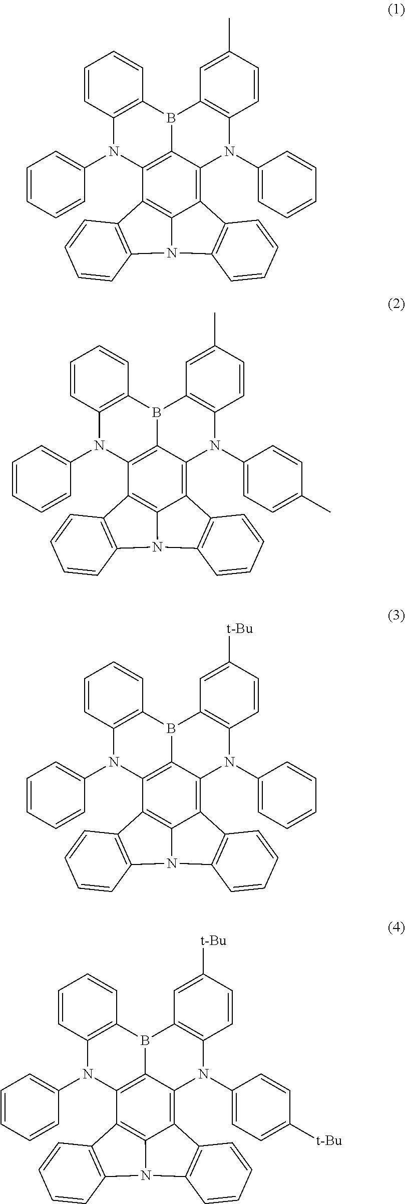

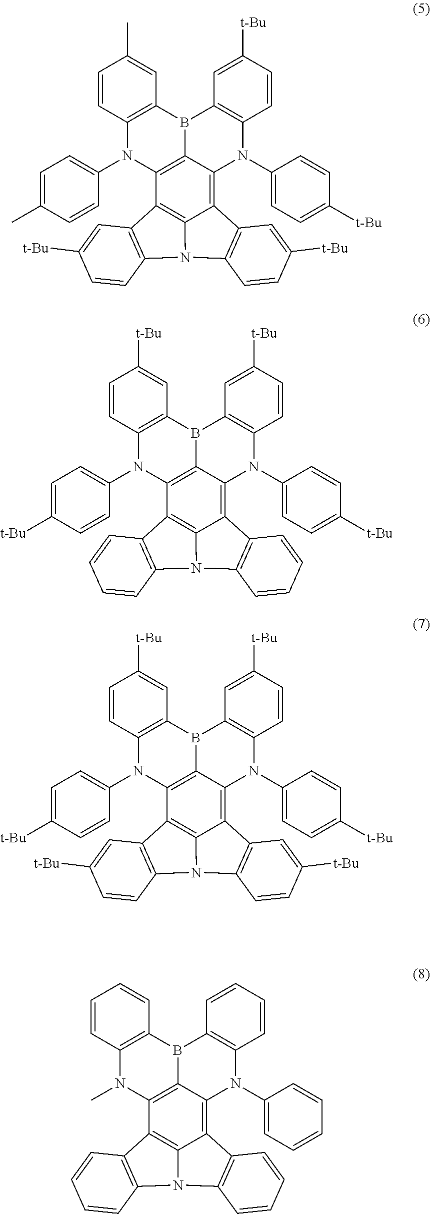

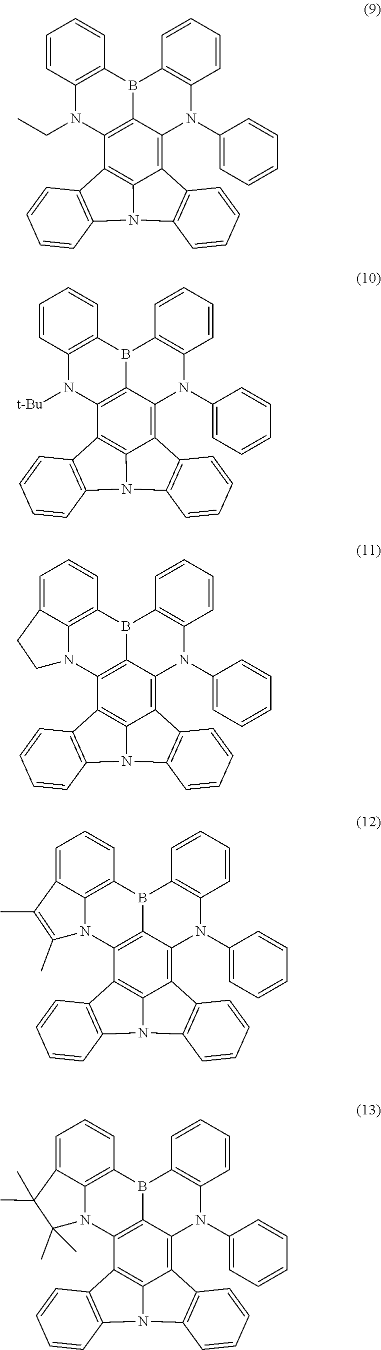

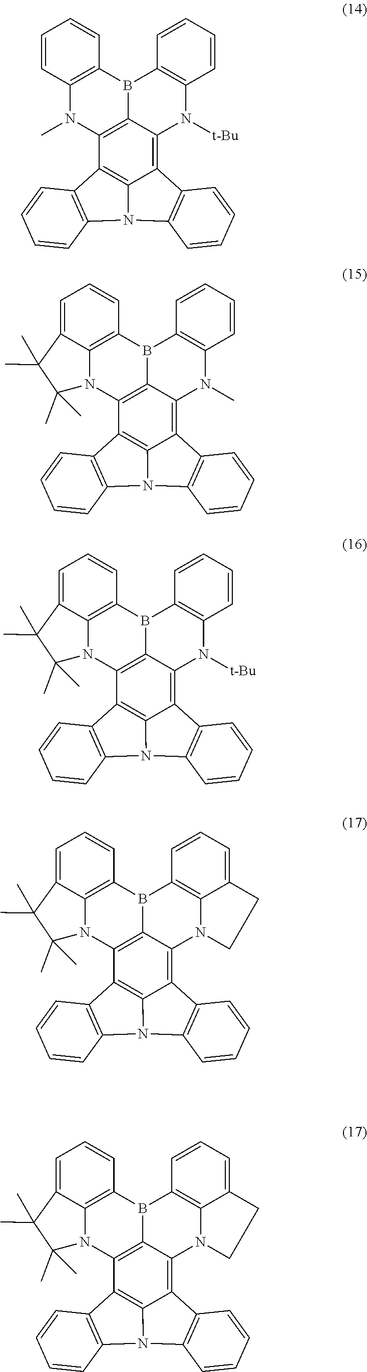

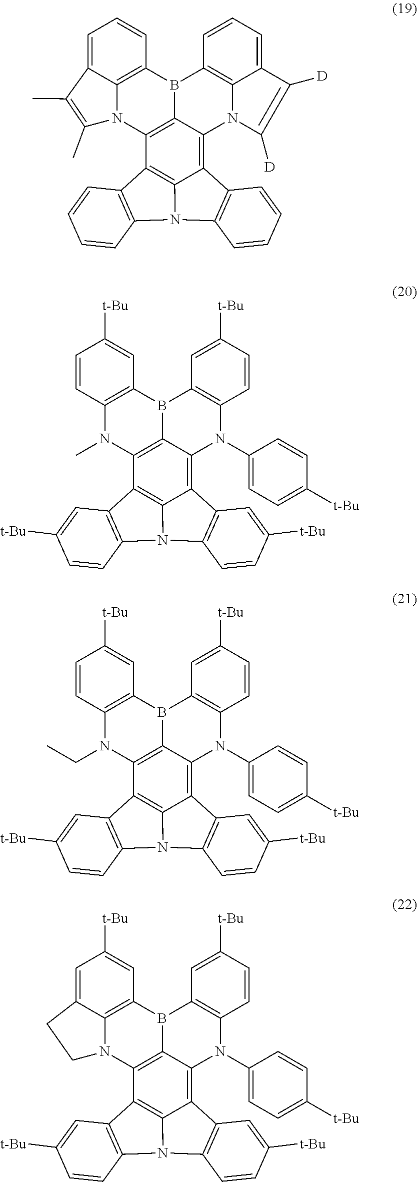

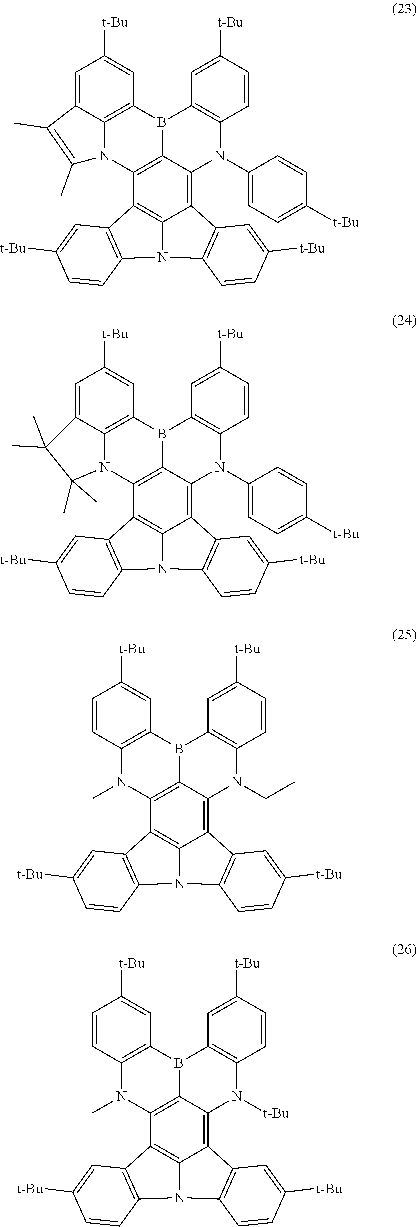 [SMILES: Cc1c(C)n2c3c(cc(C(C)(C)C)cc13)B1c3cc(C(C)(C)C)ccc3N(c3ccc(C(C)(C)C)cc3)c3c1c-2c1c2cc(C(C)(C)C)ccc2n2c4ccc(C(C)(C)C)cc4c3c12 ; CC(C)(C)c1ccc(N2c3ccc(C(C)(C)C)cc3B3c4cc(C(C)(C)C)cc5c4N(c4c3c2c2c3cc(C(C)(C)C)ccc3n3c6ccc(C(C)(C)C)cc6c4c23)C(C)(C)C5(C)C)cc1 ; CCN1c2ccc(C(C)(C)C)cc2B2c3cc(C(C)(C)C)ccc3N(C)c3c2c1c1c2cc(C(C)(C)C)ccc2n2c4ccc(C(C)(C)C)cc4c3c12 ; CN1c2ccc(C(C)(C)C)cc2B2c3cc(C(C)(C)C)ccc3N(C(C)(C)C)c3c2c1c1c2cc(C(C)(C)C)ccc2n2c4ccc(C(C)(C)C)cc4c3c12]

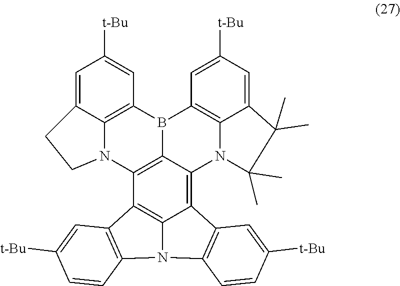 [SMILES: CC(C)(C)c1cc2c3c(c1)B1c4cc(C(C)(C)C)cc5c4N(c4c1c(c1c6cc(C(C)(C)C)ccc6n6c7ccc(C(C)(C)C)cc7c4c16)N3CC2)C(C)(C)C5(C)C]

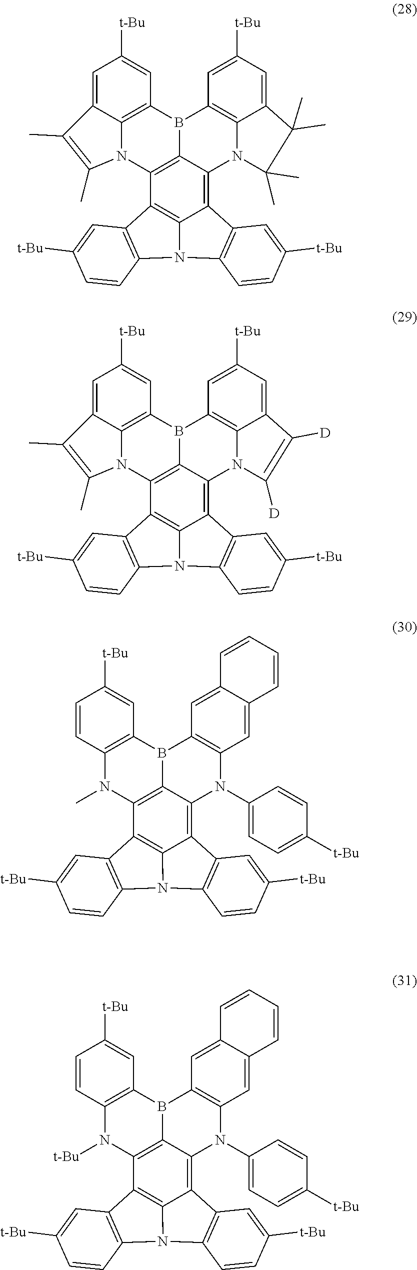

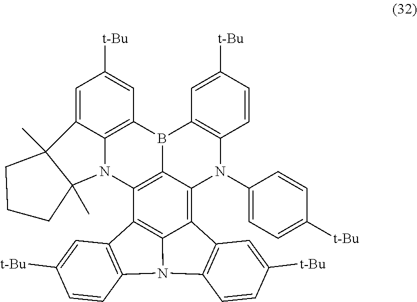 [SMILES: CC(C)(C)c1ccc(N2c3ccc(C(C)(C)C)cc3B3c4cc(C(C)(C)C)cc5c4N(c4c3c2c2c3cc(C(C)(C)C)ccc3n3c6ccc(C(C)(C)C)cc6c4c23)C2(C)CCCC52C)cc1]

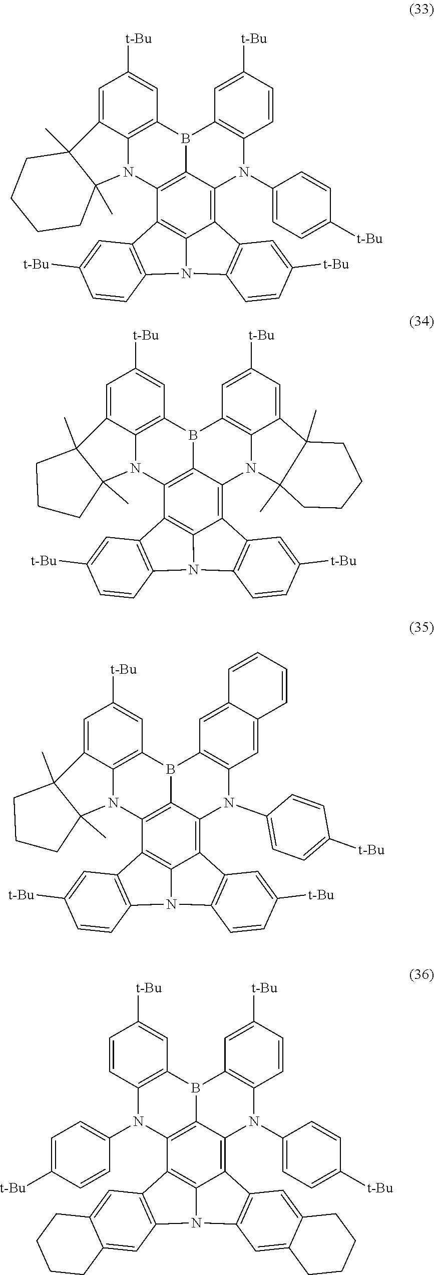

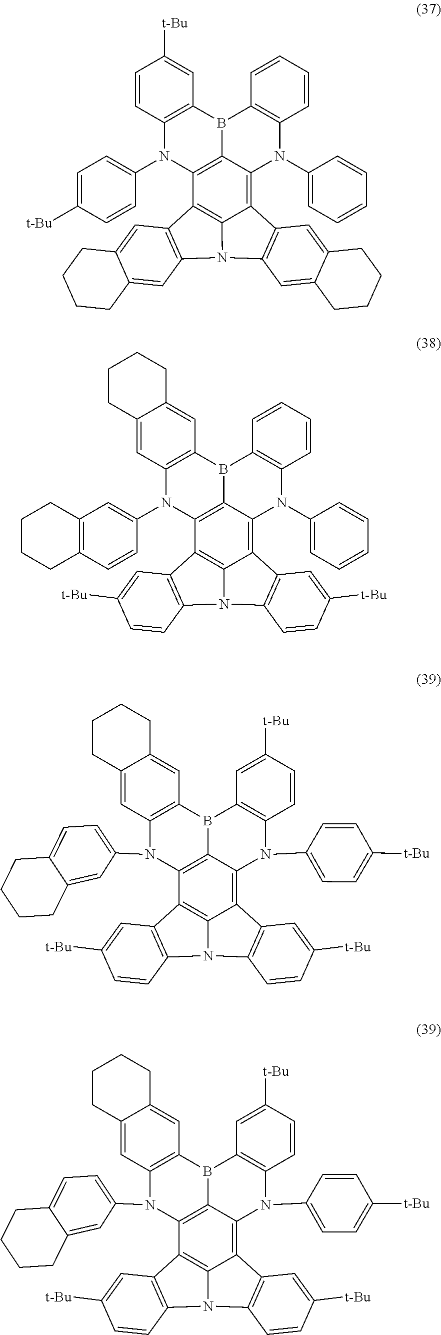 [SMILES: CC(C)(C)c1ccc(N2c3ccc(C(C)(C)C)cc3B3c4ccccc4N(c4ccccc4)c4c3c2c2c3cc5c(cc3n3c6cc7c(cc6c4c23)CCCC7)CCCC5)cc1 ; CC(C)(C)c1ccc2c(c1)c1c3c4c(c5c6cc(C(C)(C)C)ccc6n2c15)N(c1ccc2c(c1)CCCC2)c1cc2c(cc1B4c1ccccc1N3c1ccccc1)CCCC2 ; CC(C)(C)c1ccc(N2c3ccc(C(C)(C)C)cc3B3c4cc5c(cc4N(c4ccc6c(c4)CCCC6)c4c3c2c2c3cc(C(C)(C)C)ccc3n3c6ccc(C(C)(C)C)cc6c4c23)CCCC5)cc1 ; CC(C)(C)c1ccc(N2c3ccc(C(C)(C)C)cc3B3c4cc5c(cc4N(c4ccc6c(c4)CCCC6)c4c3c2c2c3cc(C(C)(C)C)ccc3n3c6ccc(C(C)(C)C)cc6c4c23)CCCC5)cc1]

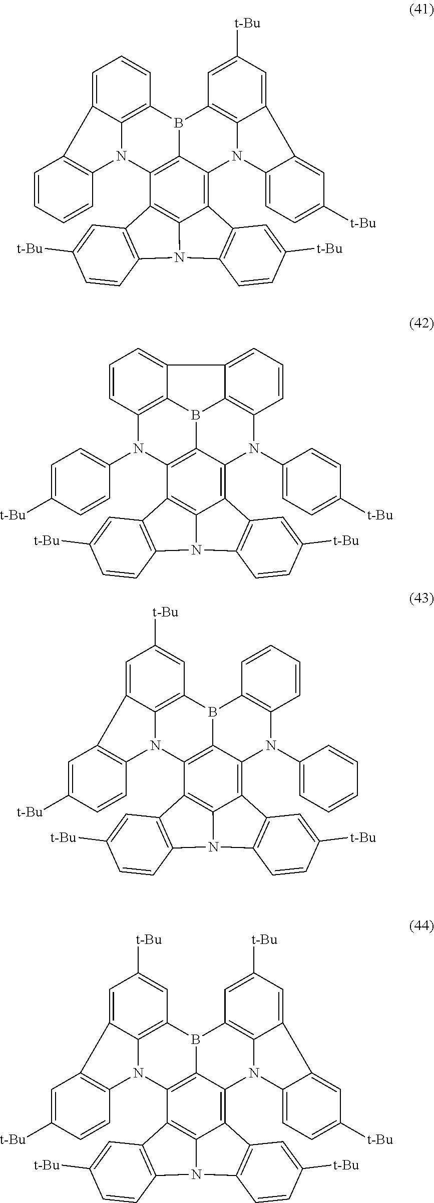

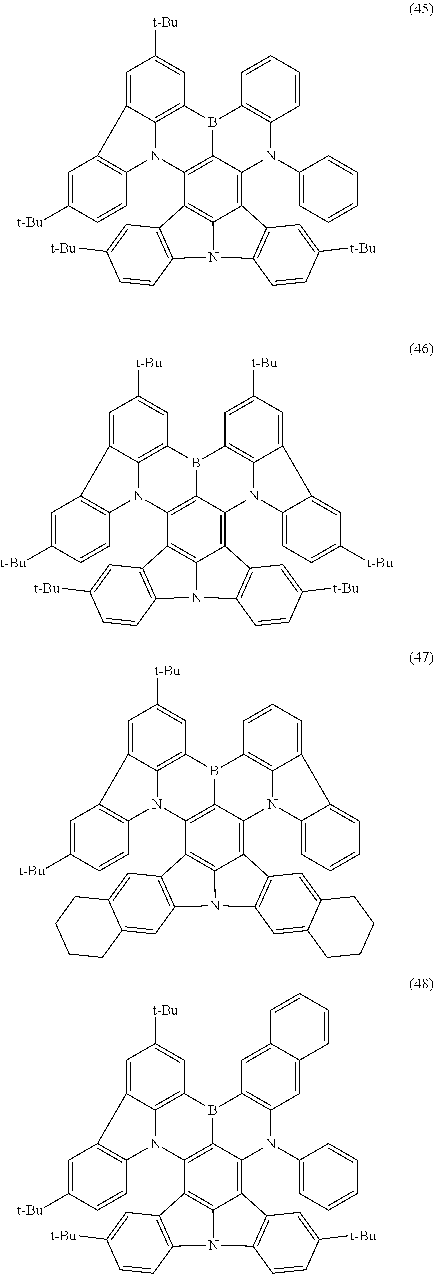

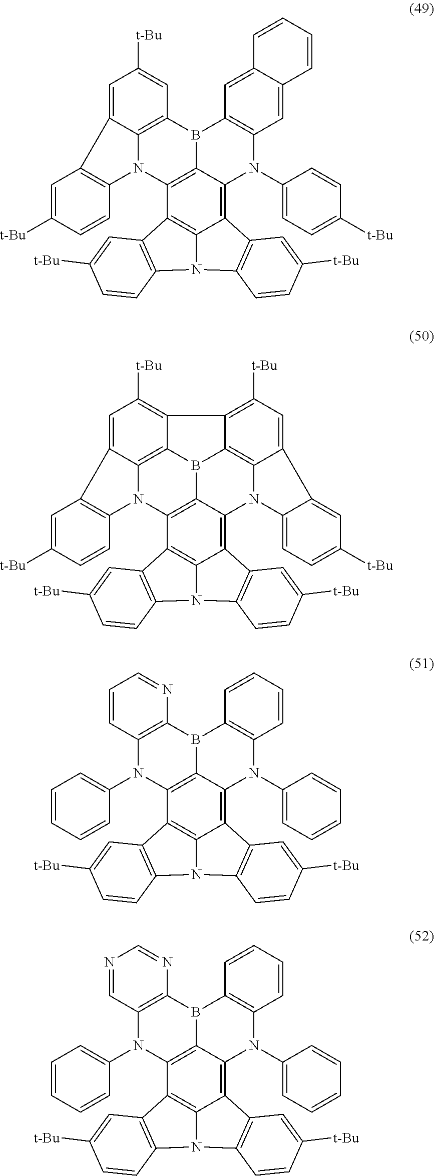

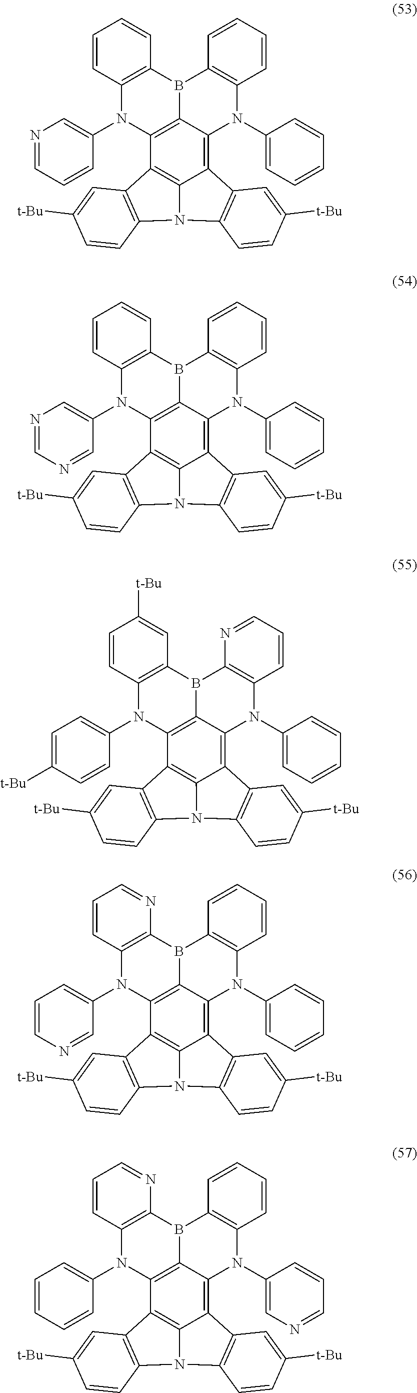

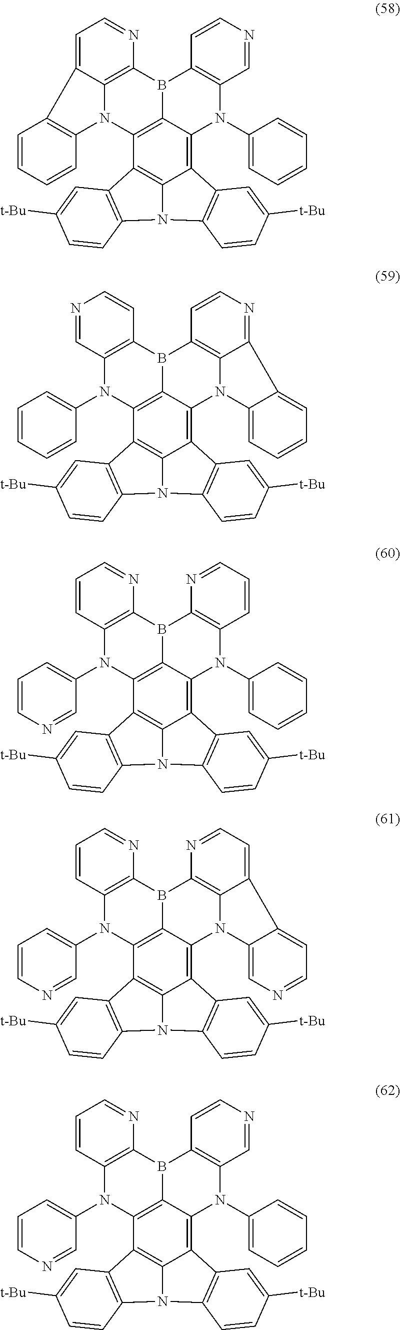

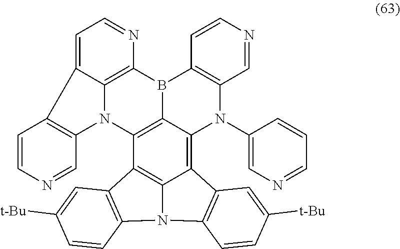 [SMILES: CC(C)(C)c1ccc2c(c1)c1c3c4c(c5c6cc(C(C)(C)C)ccc6n2c15)-n1c2cnccc2c2ccnc(c21)B4c1ccncc1N3c1cccnc1]

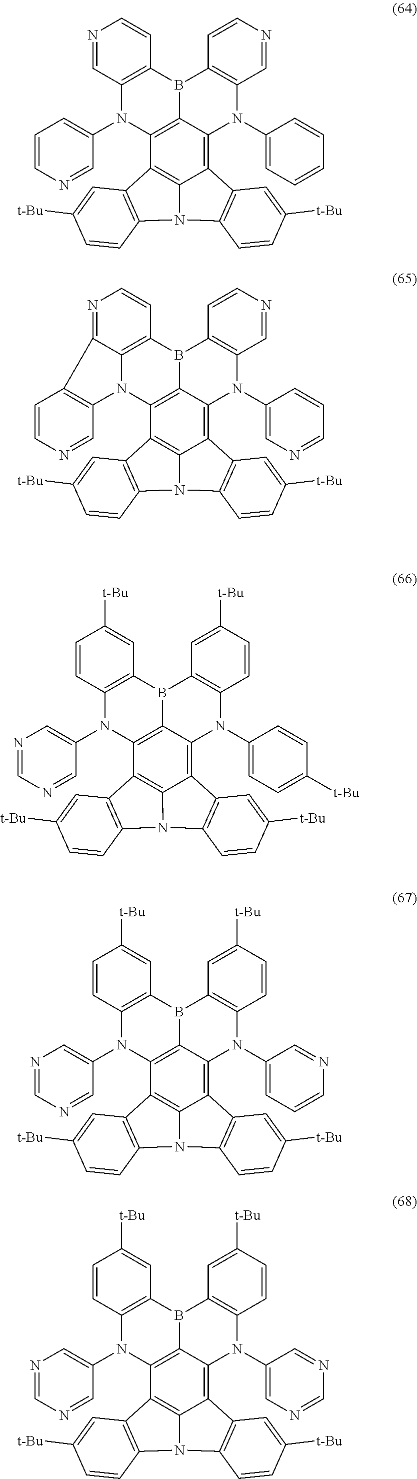

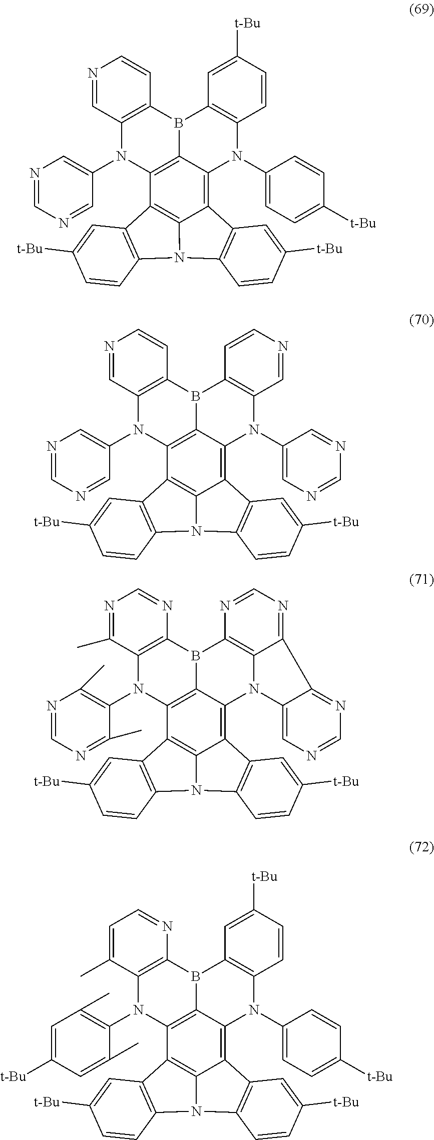

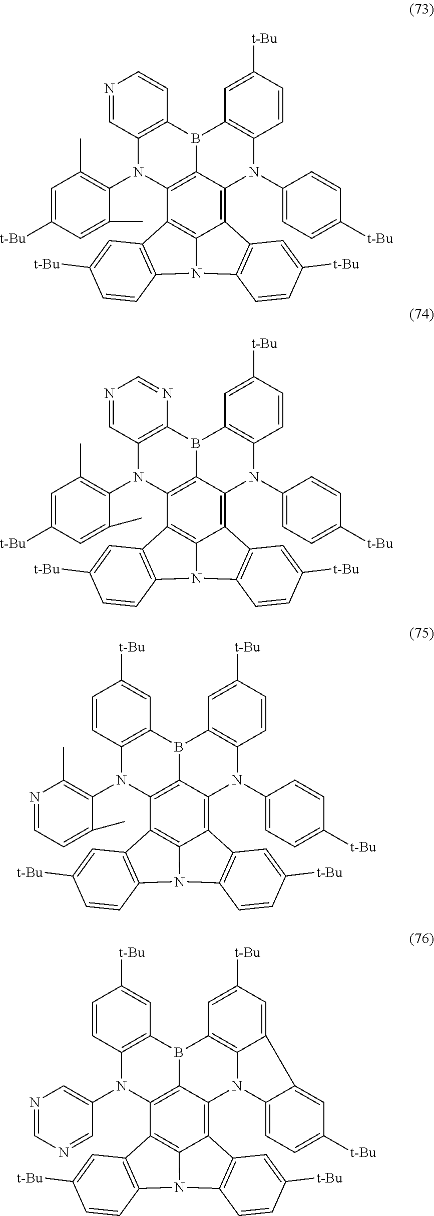

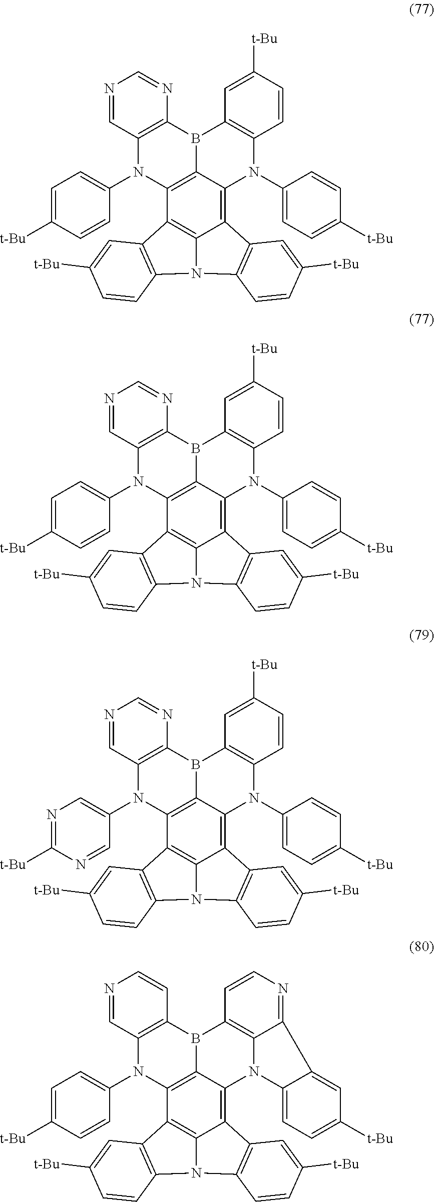

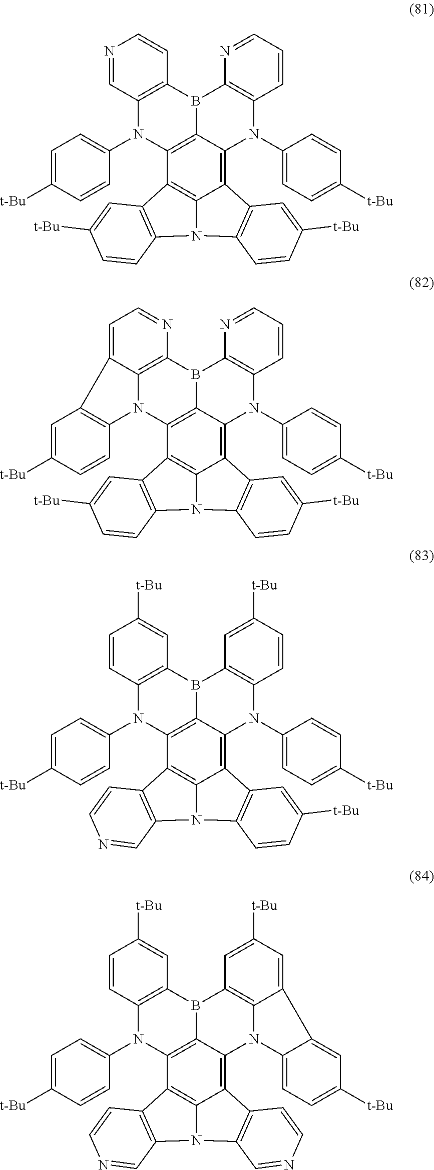

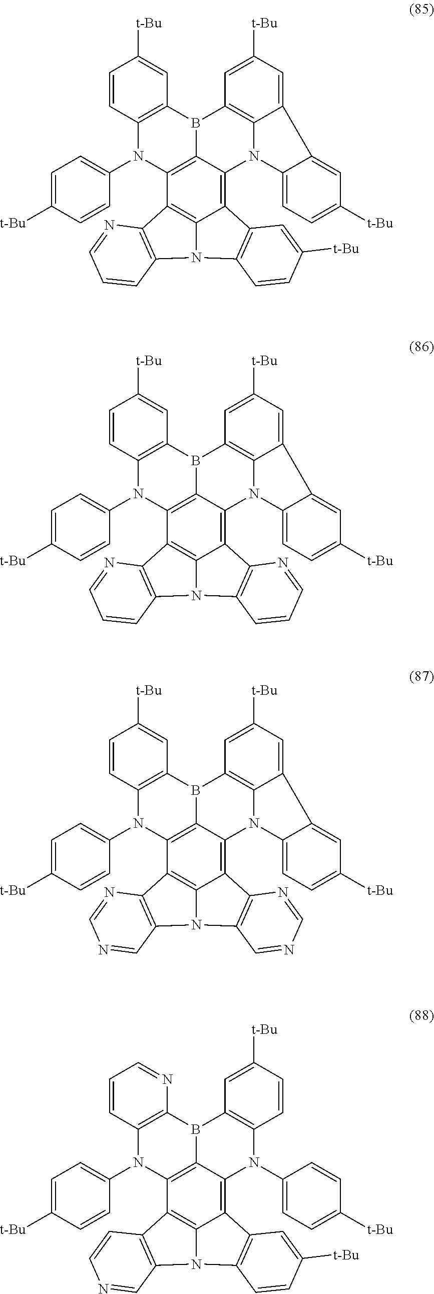 [SMILES: CC(C)(C)c1ccc(N2c3ccc(C(C)(C)C)cc3B3c4c(c5c6cc(C(C)(C)C)ccc6n6c7cccnc7c(c42)c56)-n2c4ccc(C(C)(C)C)cc4c4cc(C(C)(C)C)cc3c42)cc1 ; CC(C)(C)c1ccc(N2c3ccc(C(C)(C)C)cc3B3c4c2c2c5ncccc5n5c6cccnc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5ncncc5n5c6cncnc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4ncccc4N(c4ccc(C(C)(C)C)cc4)c4c3c2c2c3cc(C(C)(C)C)ccc3n3c5cnccc5c4c23)cc1]

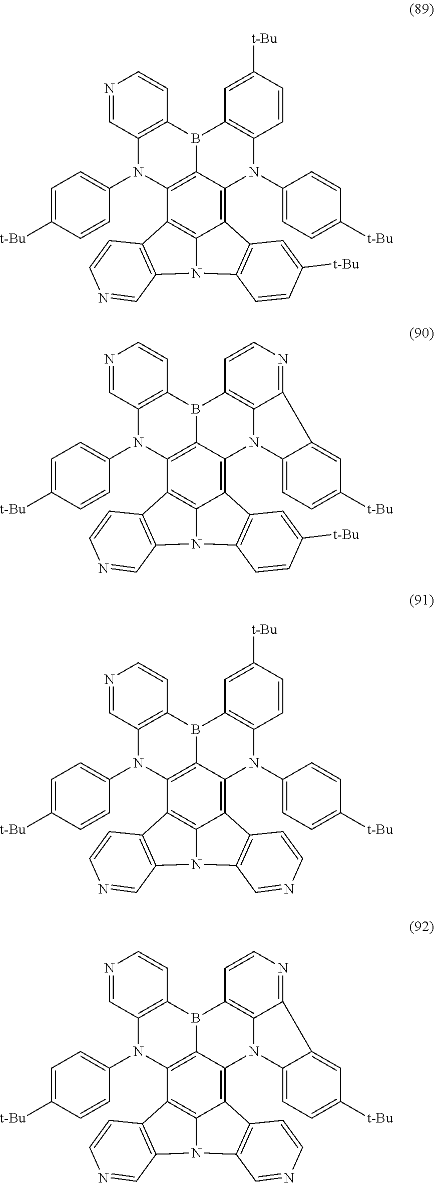

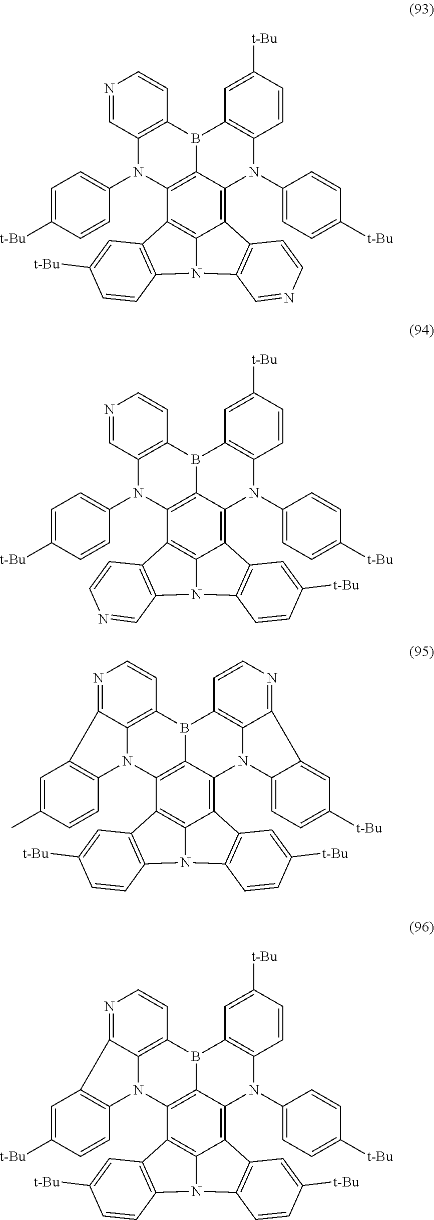

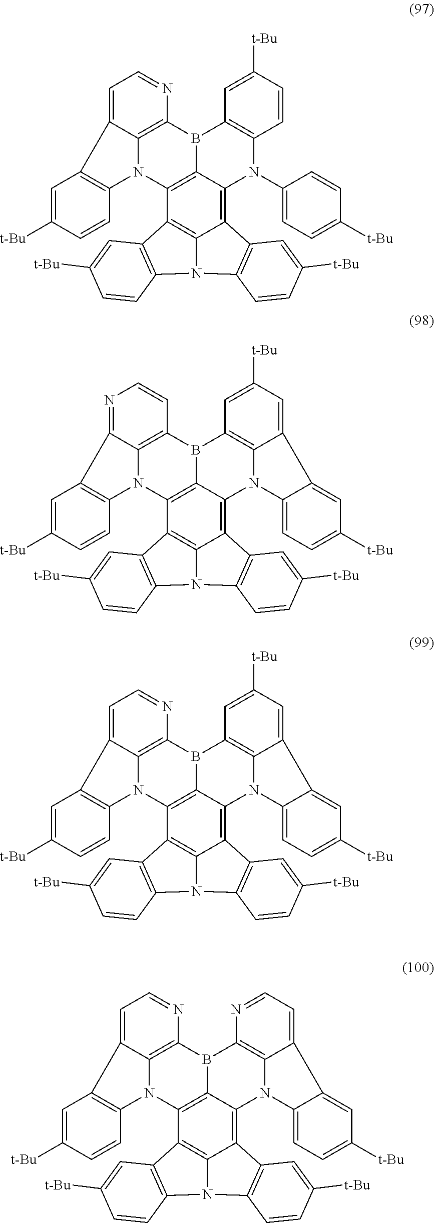

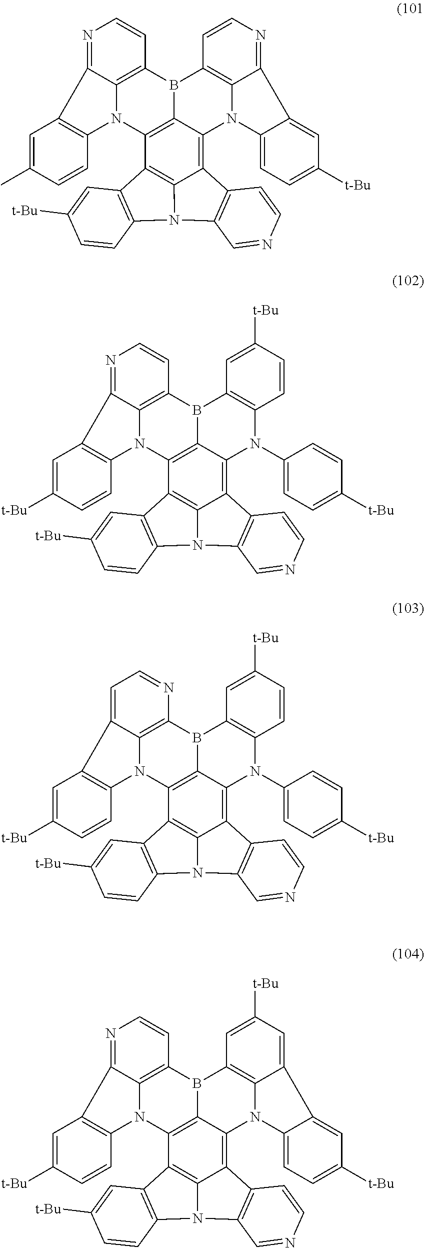 [SMILES: Cc1ccc2c(c1)c1nccc3c1n2-c1c2c(c4c5ccncc5n5c6ccc(C(C)(C)C)cc6c1c45)-n1c4ccc(C(C)(C)C)cc4c4nccc(c41)B23 ; CC(C)(C)c1ccc(N2c3ccc(C(C)(C)C)cc3B3c4c2c2c5ccncc5n5c6ccc(C(C)(C)C)cc6c(c4-n4c6ccc(C(C)(C)C)cc6c6nccc3c64)c25)cc1 ; CC(C)(C)c1ccc(N2c3ccc(C(C)(C)C)cc3B3c4c2c2c5ccncc5n5c6ccc(C(C)(C)C)cc6c(c4-n4c6ccc(C(C)(C)C)cc6c6ccnc3c64)c25)cc1 ; CC(C)(C)c1ccc2c(c1)c1cc(C(C)(C)C)cc3c1n2-c1c2c(c4c5cc(C(C)(C)C)ccc5n5c6cnccc6c1c45)-n1c4ccc(C(C)(C)C)cc4c4nccc(c41)B23]

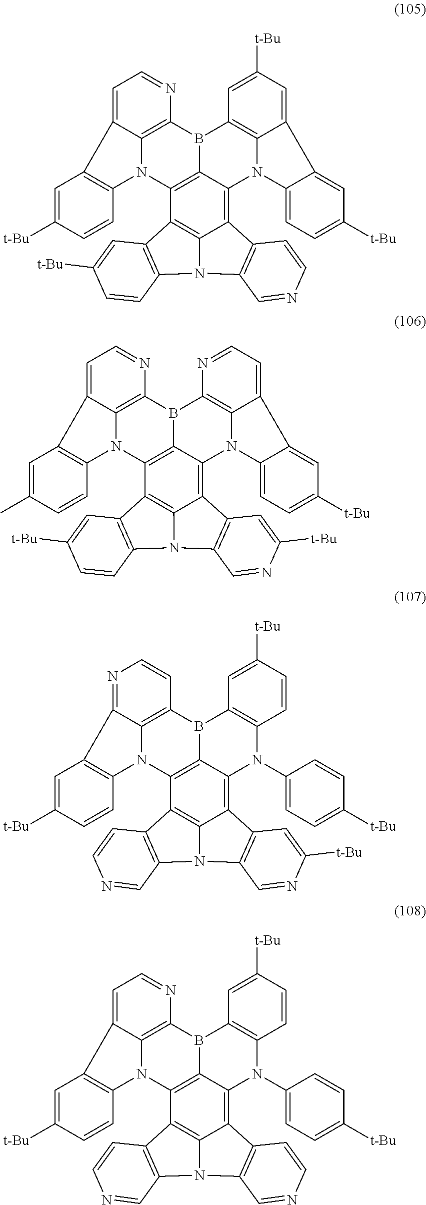 [SMILES: CC(C)(C)c1ccc2c(c1)c1cc(C(C)(C)C)cc3c1n2-c1c2c(c4c5cc(C(C)(C)C)ccc5n5c6cnccc6c1c45)-n1c4ccc(C(C)(C)C)cc4c4ccnc(c41)B23 ; Cc1ccc2c(c1)c1ccnc3c1n2-c1c2c(c4c5cc(C(C)(C)C)ncc5n5c6ccc(C(C)(C)C)cc6c1c45)-n1c4ccc(C(C)(C)C)cc4c4ccnc(c41)B23 ; CC(C)(C)c1ccc(N2c3ccc(C(C)(C)C)cc3B3c4c2c2c5cc(C(C)(C)C)ncc5n5c6cnccc6c(c4-n4c6ccc(C(C)(C)C)cc6c6nccc3c64)c25)cc1 ; CC(C)(C)c1ccc(N2c3ccc(C(C)(C)C)cc3B3c4c2c2c5ccncc5n5c6cnccc6c(c4-n4c6ccc(C(C)(C)C)cc6c6ccnc3c64)c25)cc1]

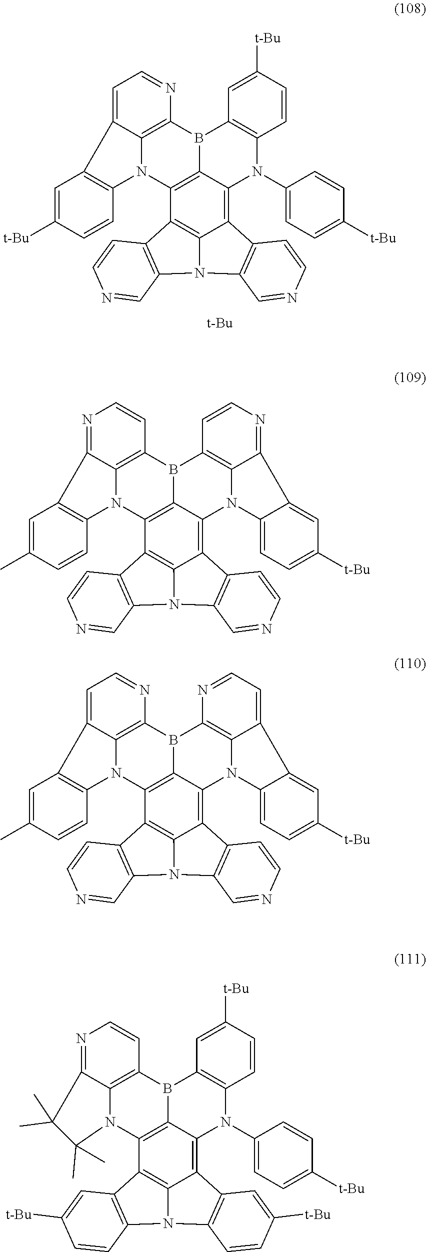

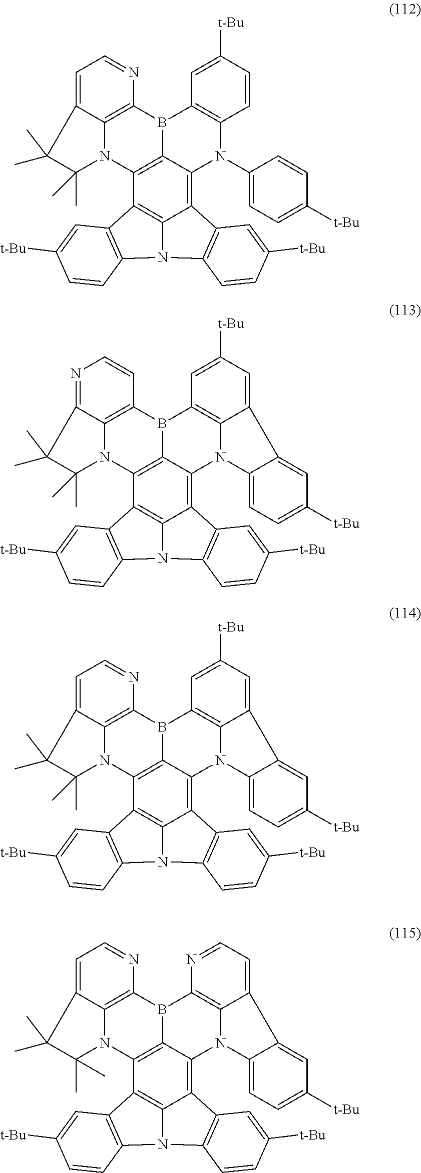

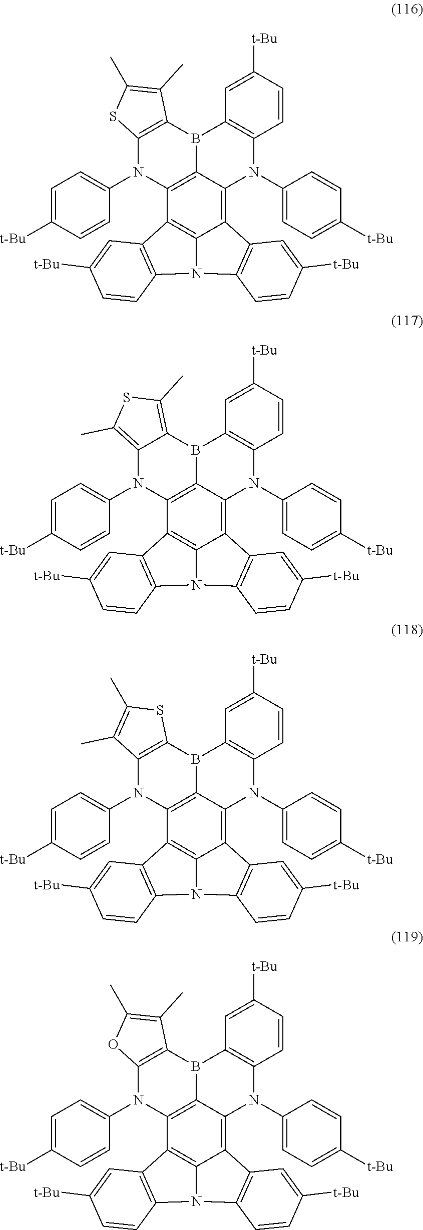

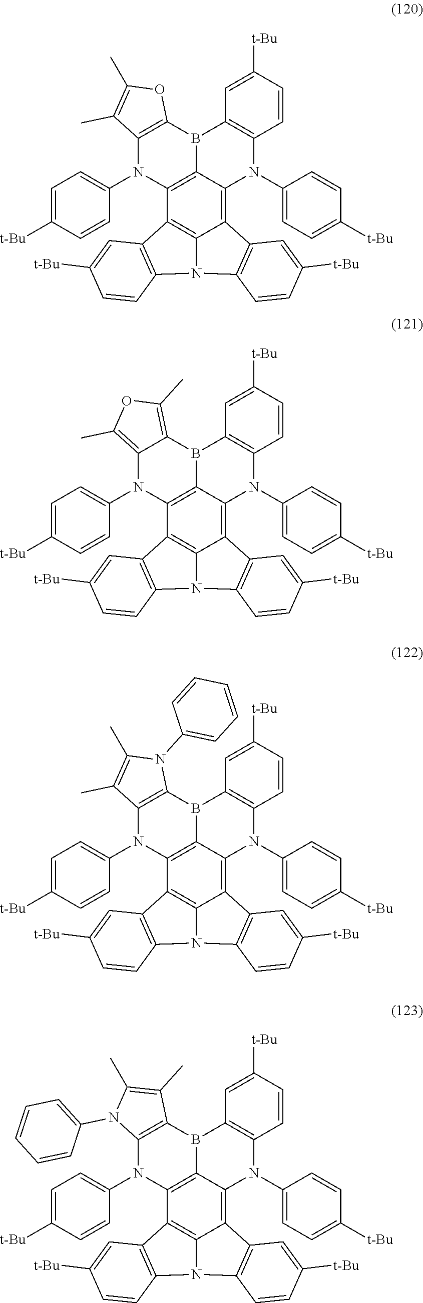

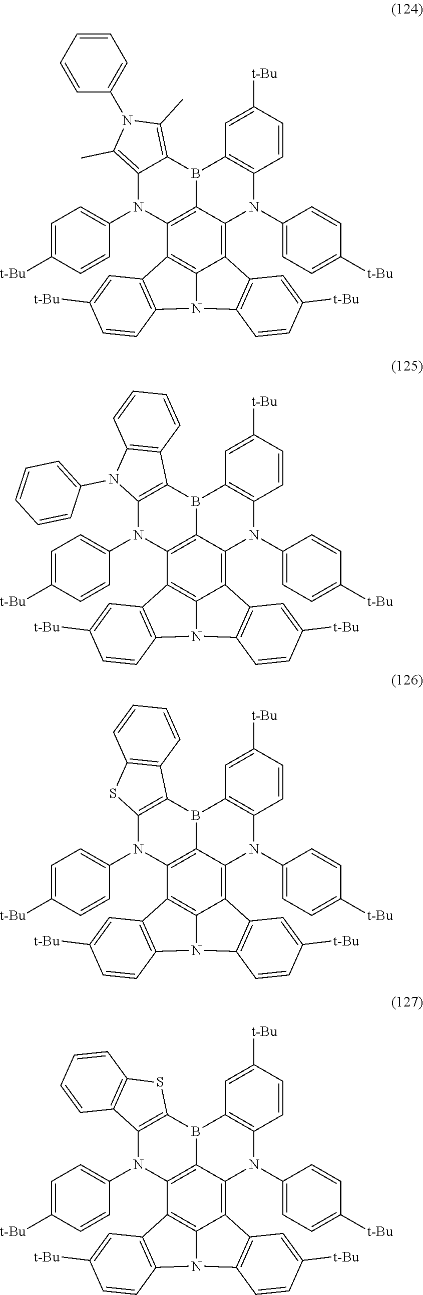

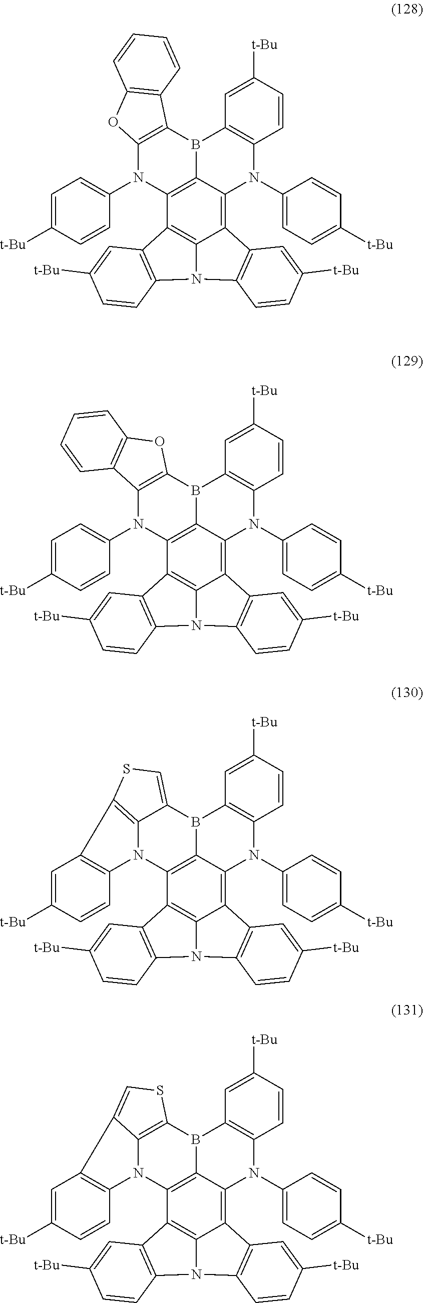

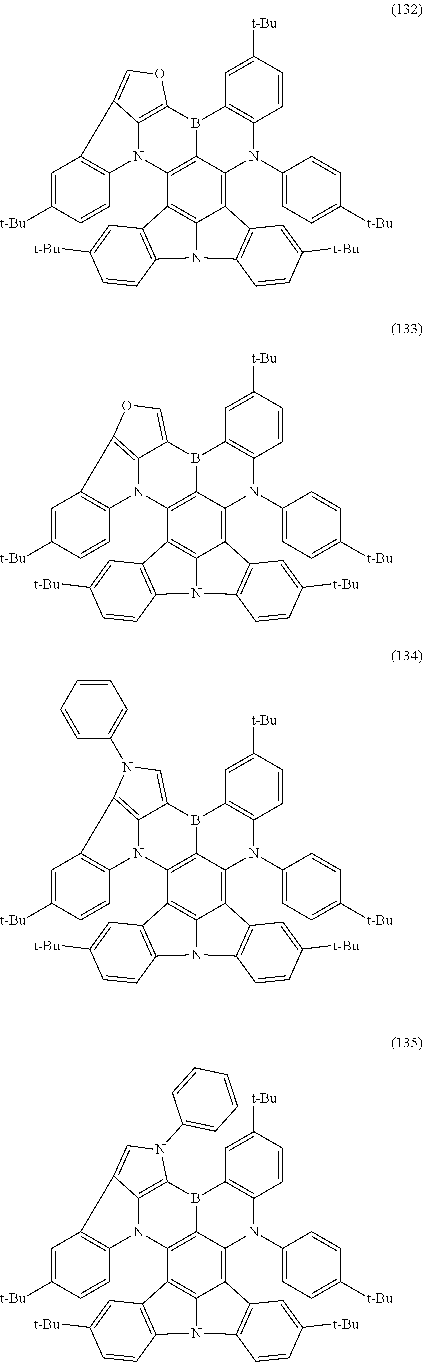

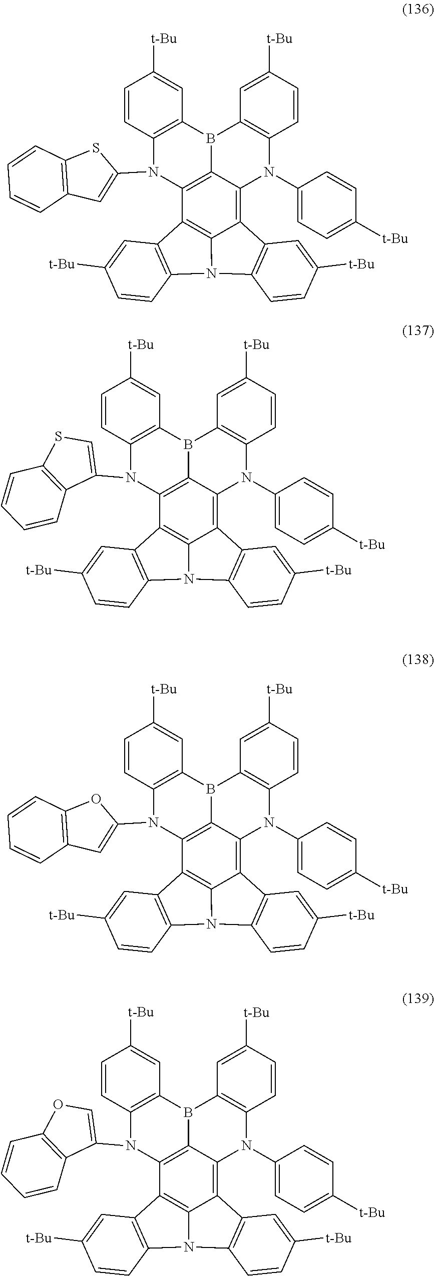

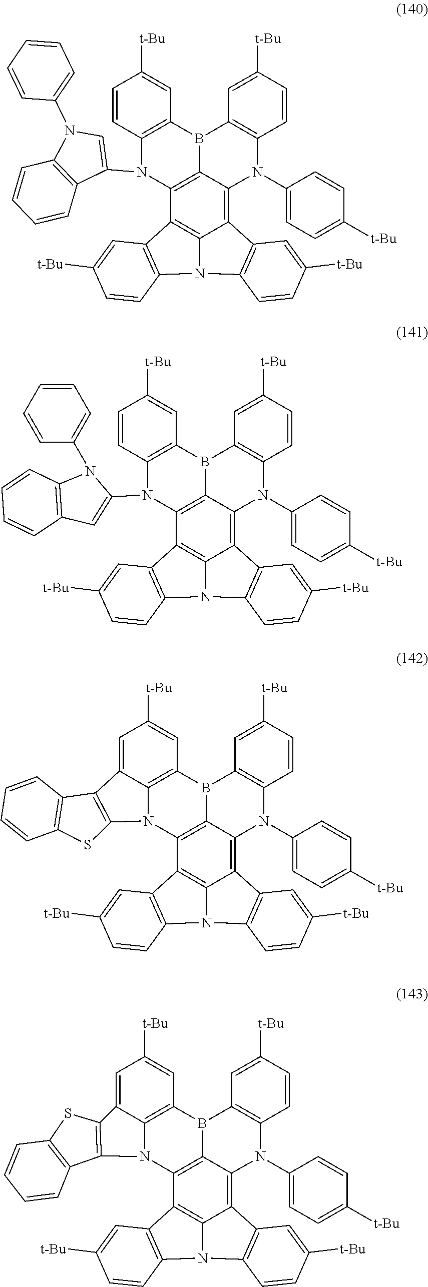

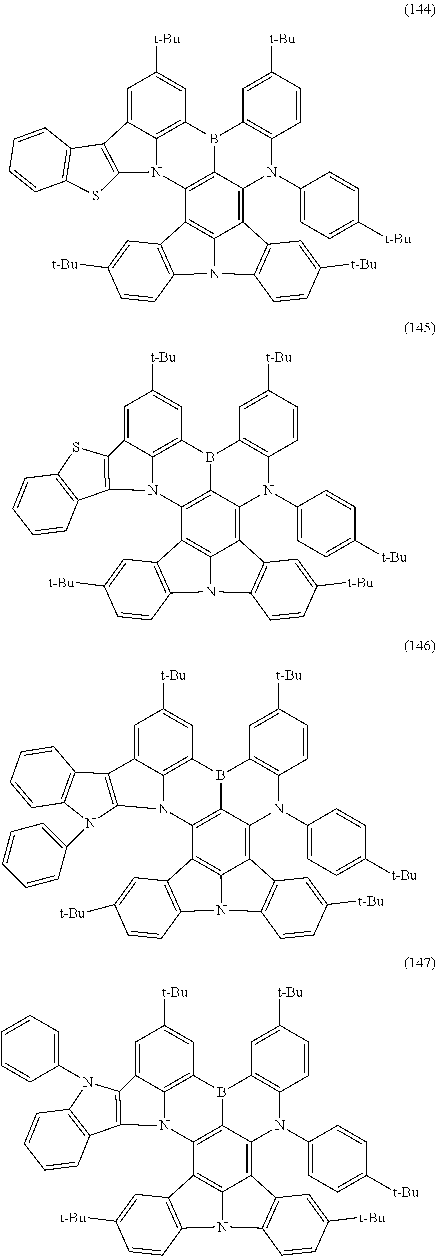

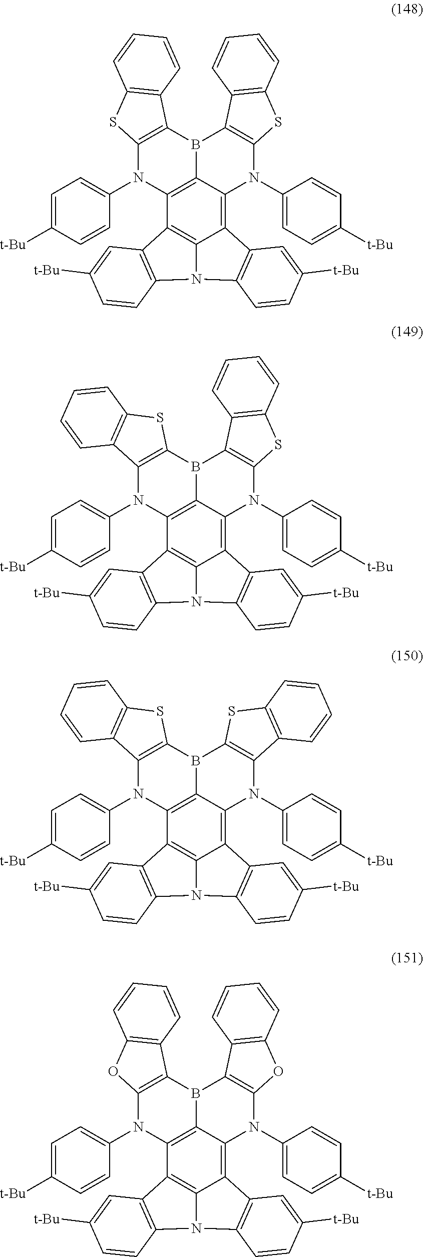 [SMILES: CC(C)(C)c1ccc(N2c3sc4ccccc4c3B3c4c2c2c5cc(C(C)(C)C)ccc5n5c6ccc(C(C)(C)C)cc6c(c4N(c4ccc(C(C)(C)C)cc4)c4sc6ccccc6c43)c25)cc1 ; CC(C)(C)c1ccc(N2c3sc4ccccc4c3B3c4sc5ccccc5c4N(c4ccc(C(C)(C)C)cc4)c4c3c2c2c3cc(C(C)(C)C)ccc3n3c5ccc(C(C)(C)C)cc5c4c23)cc1 ; CC(C)(C)c1ccc(N2c3c(sc4ccccc34)B3c4sc5ccccc5c4N(c4ccc(C(C)(C)C)cc4)c4c3c2c2c3cc(C(C)(C)C)ccc3n3c5ccc(C(C)(C)C)cc5c4c23)cc1 ; CC(C)(C)c1ccc(N2c3oc4ccccc4c3B3c4c2c2c5cc(C(C)(C)C)ccc5n5c6ccc(C(C)(C)C)cc6c(c4N(c4ccc(C(C)(C)C)cc4)c4oc6ccccc6c43)c25)cc1]

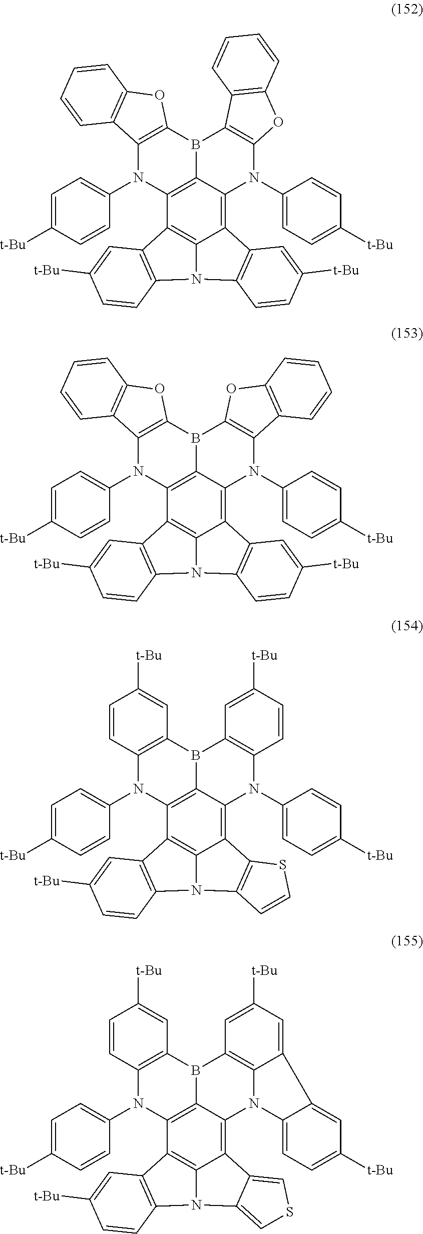 [SMILES: CC(C)(C)c1ccc(N2c3oc4ccccc4c3B3c4oc5ccccc5c4N(c4ccc(C(C)(C)C)cc4)c4c3c2c2c3cc(C(C)(C)C)ccc3n3c5ccc(C(C)(C)C)cc5c4c23)cc1 ; CC(C)(C)c1ccc(N2c3c(oc4ccccc34)B3c4oc5ccccc5c4N(c4ccc(C(C)(C)C)cc4)c4c3c2c2c3cc(C(C)(C)C)ccc3n3c5ccc(C(C)(C)C)cc5c4c23)cc1 ; CC(C)(C)c1ccc(N2c3ccc(C(C)(C)C)cc3B3c4cc(C(C)(C)C)ccc4N(c4ccc(C(C)(C)C)cc4)c4c3c2c2c3cc(C(C)(C)C)ccc3n3c5ccsc5c4c23)cc1 ; CC(C)(C)c1ccc(N2c3ccc(C(C)(C)C)cc3B3c4c2c2c5cc(C(C)(C)C)ccc5n5c6cscc6c(c4-n4c6ccc(C(C)(C)C)cc6c6cc(C(C)(C)C)cc3c64)c25)cc1]

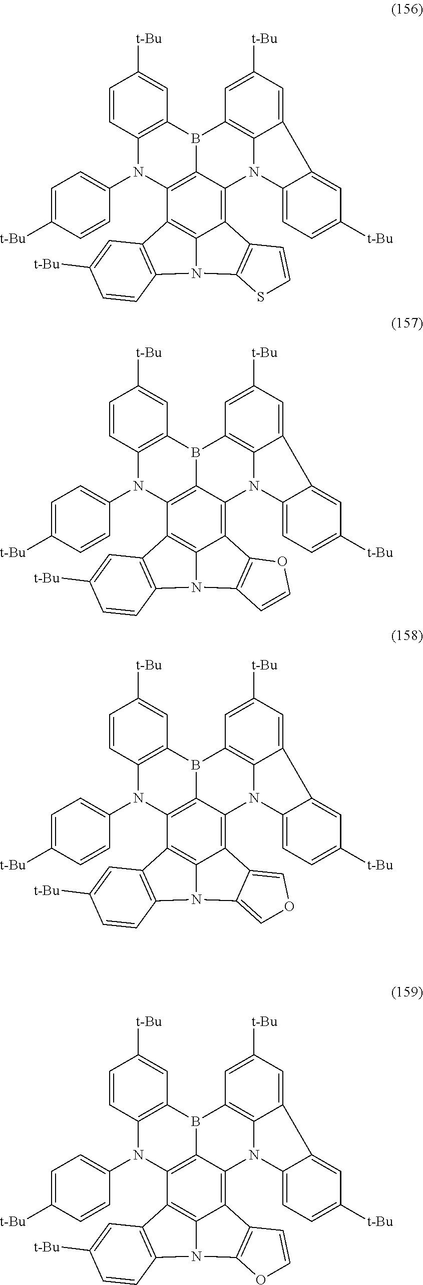 [SMILES: CC(C)(C)c1ccc(N2c3ccc(C(C)(C)C)cc3B3c4c2c2c5cc(C(C)(C)C)ccc5n5c6sccc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5cc(C(C)(C)C)ccc5n5c6ccoc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5cc(C(C)(C)C)ccc5n5c6cocc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5cc(C(C)(C)C)ccc5n5c6occc6c(c4-n4c6ccc(C(C)(C)C)cc6c6cc(C(C)(C)C)cc3c64)c25)cc1]

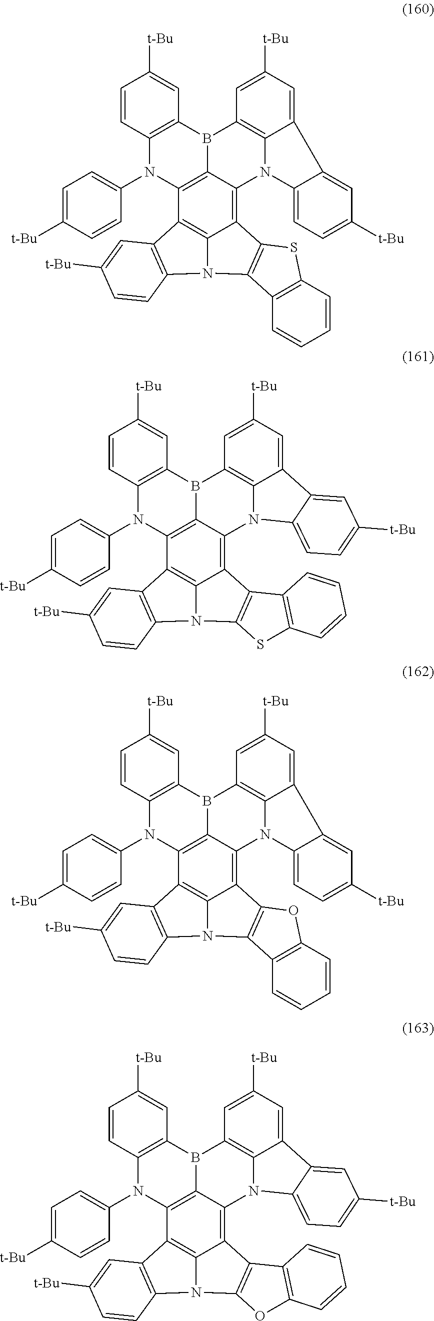

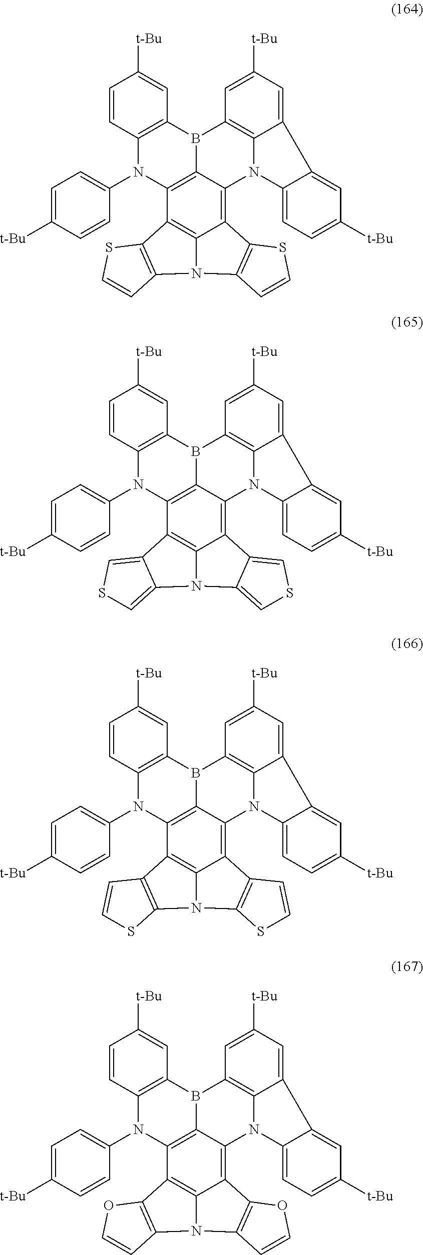 [SMILES: CC(C)(C)c1ccc(N2c3ccc(C(C)(C)C)cc3B3c4c2c2c5sccc5n5c6ccsc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5cscc5n5c6cscc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5ccsc5n5c6sccc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5occc5n5c6ccoc6c(c4-n4c6ccc(C(C)(C)C)cc6c6cc(C(C)(C)C)cc3c64)c25)cc1]

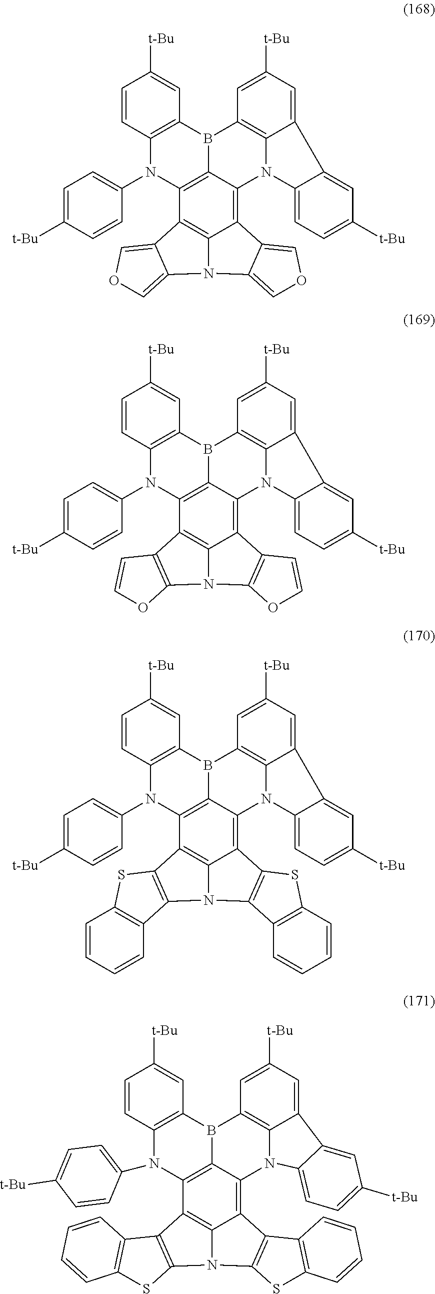 [SMILES: CC(C)(C)c1ccc(N2c3ccc(C(C)(C)C)cc3B3c4c2c2c5cocc5n5c6cocc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5ccoc5n5c6occc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5sc6ccccc6c5n5c6c7ccccc7sc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5c6ccccc6sc5n5c6sc7ccccc7c6c(c4-n4c6ccc(C(C)(C)C)cc6c6cc(C(C)(C)C)cc3c64)c25)cc1]

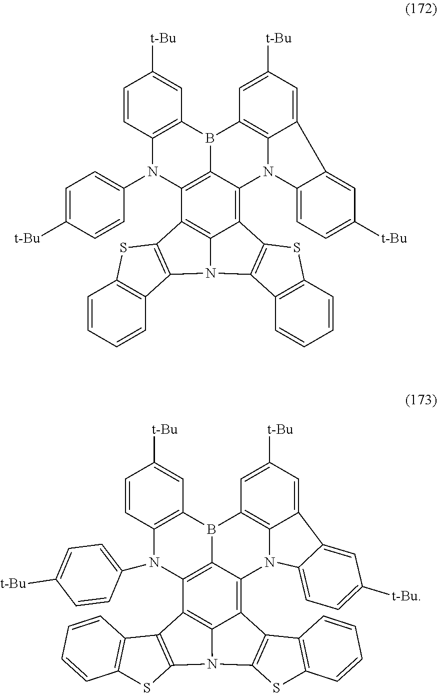 [SMILES: CC(C)(C)c1ccc(N2c3ccc(C(C)(C)C)cc3B3c4c2c2c5sc6ccccc6c5n5c6c7ccccc7sc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5c6ccccc6sc5n5c6sc7ccccc7c6c(c4-n4c6ccc(C(C)(C)C)cc6c6cc(C(C)(C)C)cc3c64)c25)cc1]

A second invention of the present invention is to provide an organic electroluminescent device. The organic electroluminescent device includes at least one functional layer containing an organic electroluminescent material containing B—N fused rings.

Optionally, the organic electroluminescent material containing B—N fused rings is used as a material for a light-emitting layer.

Optionally, the organic electroluminescent material containing B—N fused rings is used as a doping material for the light-emitting layer.

Based on the principle of TADF, the series of organic electroluminescent materials containing B—N fused rings disclosed by the present invention have internal quantum efficiency of 100%. In addition, by utilizing a multiple resonance effect between B—N, the materials have small half-wave width and good color purity. With introduction of indolo[3,2,1-JK]carbazole and derivatives thereof, the multiple resonance effect is further enhanced, and the luminous efficiency and the color purity are significantly improved. Moreover, such compounds have good thermal stability and meet requirements of OLED panels for luminescent materials.

### BRIEF DESCRIPTION OF DRAWINGS

FIG. 1 is a structure diagram of an electroluminescent device of the present invention, in which 10 represents a glass substrate, 20 represents an anode, 30 represents a hole injection layer, 40 represents a hole transport layer, 50 represents an electron blocking layer, 60 represents a light-emitting layer, 70 represents an electron transport layer, 80 represents an electron injection layer, and 90 represents a cathode.

### DETAILED DESCRIPTION OF EMBODIMENTS

The present invention has no requirements on synthetic methods for materials. In order to describe the present invention in more detail, the following examples are provided, but the present invention is not limited thereto. Unless otherwise specified, all raw materials used in the following synthesis processes are commercially available products.

### Example 1

### Synthesis of a Compound Structure 7

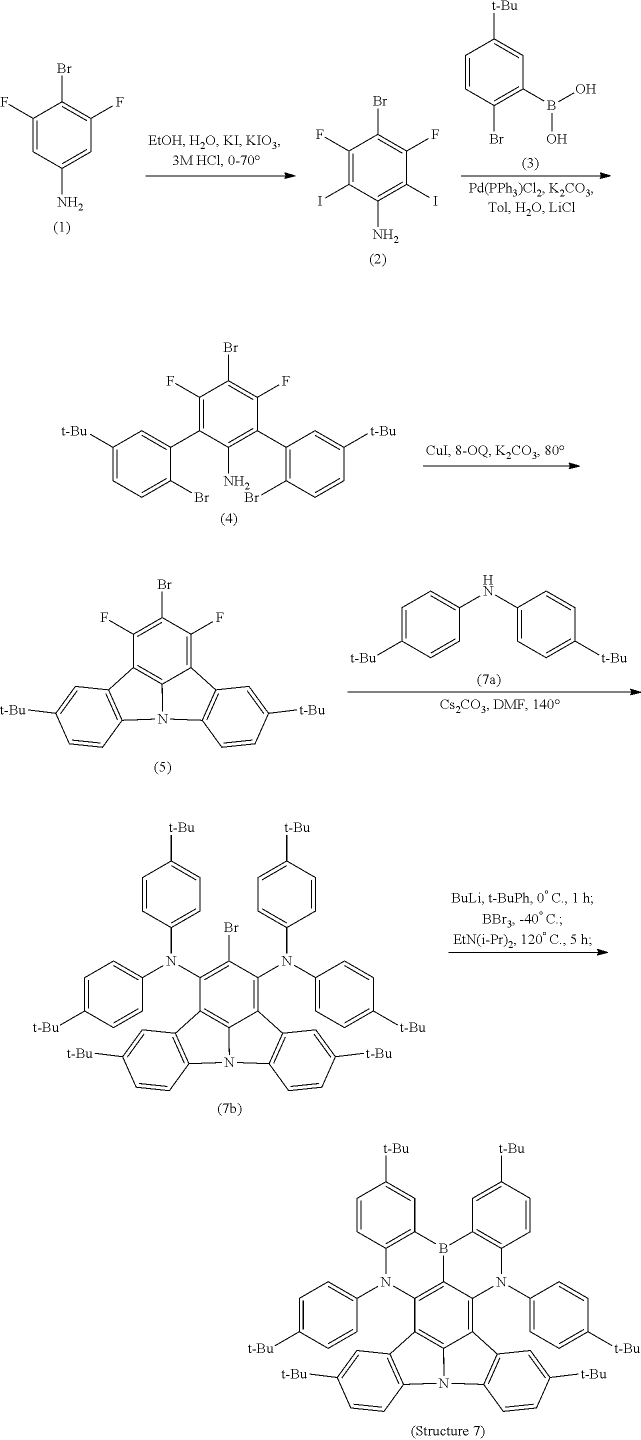

### Synthesis of a Compound (2)

After magnetons, a compound (1) (5.0 g, 24 mmol) and KI (5.9 g, 36 mmol) were added into a 1 L one-necked flask, 50 mL of methanol and 250 mL of deionized water were poured to dissolve most of the compounds, and KIO₃ (3.6 g, 16.8 mmol) was added and stirred for 0.5 hour. 40 mL of a 1.5 M HCl solution was added into a dropping funnel and then added dropwise into a reaction solution, and a resulting mixture was heated to 60° C. to carry out a reaction for 12 hours. Cooling was performed to room temperature, and 400 mL of deionized water was added. Then, suction filtration was performed, and a filter cake was dried in a vacuum oven at 80° C. for 10 hours, followed by column separation with polyethylene (PE) and dichloromethane (DCM) at a ratio of 50:1 to obtain 10.54 g of a white powdered solid with a yield of 95%. ESI-MS (m/z): 460 (M); 458 (M−1).

### Synthesis of a Compound (4)

Magnetons were added into a 250 mL one-necked flask, the compound (2) (1.0 g, 2 mmol), a compound (3) (2.3 g, 8 mmol), pd(PPh₃)₂Cl₂ (0.15 g, 0.2 mmol), K₂CO₃ (2.4 g, 16 mmol) and LiCl (0.1 g, 2 mmol) were weighed and added, then vacuumization was performed for gas replacement, 50 mL of toluene and 20 mL of deionized water were rapidly added separately, and vacuumization was performed again for gas replacement for three times. The above mixture was stirred and heated to 100° C. to carry out a reaction for 4 hours under the atmosphere of nitrogen. Then, cooling was performed to room temperature, extraction was performed with DCM, and an organic phase was spin-dried and mixed with silica gel, followed by column separation with a mixed solvent including PE and DCM at a ratio of 10:1 to obtain 0.47 g of a white powdered solid with a yield of 35%. ¹H NMR (400 MHz, Chloroform-d) δ 7.64 (dd, J=8.4, 1.5 Hz, 2H), 7.34 (m, 2H), 3.61 (d, J=7.4 Hz, 2H), 1.32 (s, 18H). ESI-MS (m/z): 630 (M+1).

### Synthesis of a Compound (5)

Magnetons, the compound (4) (3.3 g, 5.2 mmol), CuI (0.22 g, 1.2 mmol), 8-OQ (0.33 g, 2.2 mmol), K₂CO₃ (3.2 g, 2.3 mmol) and N,N-dimethylformamide (DMF, 100 mL) were added into a 250 mL one-necked flask and stirred, vacuumization was performed for nitrogen replacement for three times, and then the above compounds were heated to 80° C. to carry out a reaction for 12 hours. Then, cooling was performed to room temperature, extraction was performed with DCM for three times, and an organic phase was spin-dried and mixed with silica gel, followed by column separation with a mixed solvent including PE and DCM at a ratio of 50:1 to obtain 1.3 g of a light brown solid with a yield of 53%. ¹H NMR (400 MHz, Chloroform-d) δ 8.10 (d, J=2.5 Hz, 2H), 7.72 (dt, J=8.7, 3.1 Hz, 2H), 7.61 (dt, J=8.5, 2.7 Hz, 2H), 1.53-1.42 (s, 18H). ESI-MS (m/z): 468 (M), 959(2M+23).

### Synthesis of a Compound (7b)

Magnetons, the compound (5) (0.9 g, 2.0 mmol), a compound (7a) (1.2 g, 4.4 mmol), Cs₂CO₃ (2.6 g, 8 mmol) and DMF (50 mL) were added into a 250 mL one-necked flask and stirred, vacuumization was performed for nitrogen replacement, and then the above compounds were heated to 140° C. to carry out a reaction for 36 hours. Then, cooling was performed to room temperature, extraction was performed with DCM for three times, and an organic phase was spin-dried and mixed with silica gel, followed by column separation with PE to obtain 0.8 g of a light green oily compound with a yield of 42%. ¹H NMR (400 MHz, Chloroform-d) δ 8.18 (d, J=2.0, 2H), 7.45-7.37 (m, 4H), 7.28-7.20 (m, 8H), 7.08-7.01 (m, 8H), 1.52-1.39 (s, 18H), 1.39-1.28 (s, 36H). ESI-MS (m/z): 1014 (M+23).

### Synthesis of a Compound Structure (7)

A 100 mL three-necked flask was dried in an oven at 100° C. for 2 hours and taken out, followed by vacuumization for 0.5 hour immediately. Under the atmosphere of nitrogen, magnetons, the compound (7b) (2.0 g, 2.0 mmol) and 20 mL of dry tert-butylbenzene were added, the reaction flask was cooled to −40° C. by a mixture of liquid nitrogen, ethanol and water, t-BuLi (2 ml, 5 mmol) was added dropwise and stirred for 0.5 hour, and a resulting mixture was heated to 70° C. to carry out a reaction for 2 hours. Then, the temperature was lowered to −30° C., BBr₃ (0.4 mL, 5 mmol) was added dropwise, and a resulting mixture was slowly heated to room temperature to carry out a reaction for 0.5 hour. Then, the temperature was lowered to 0° C., diisopropylethylamine (0.9 mL, 5 mmol) was added dropwise, and a resulting mixture was heated to 120° C. to carry out a reaction for 18 hours. After the last reaction was completed, the tert-butylbenzene was removed by distillation under reduced pressure, extraction was performed with DCM for three times, and column separation was performed with a mixed solvent including PE and ethyl acetate (EA) at a ratio of 50:1 to obtain 0.63 g of a light yellow powder with a yield of 34%. ¹H NMR (400 MHz, Chloroform-d) δ 8.19 (d, J=2.3 Hz, 2H), 7.40-7.39 (m, 2H), 7.35 (d, J=2.1 Hz, 2H), 7.33-7.32 (m, 2H), 7.29-7.24 (m, 4H), 7.22 (dd, J=6.3, 2.1 Hz, 2H), 7.05-7.01 (m, 4H), 7.00 (d, J=6.3 Hz, 2H), 1.43-1.35 (s, 18H), 1.35-1.26 (d, J=0.7 Hz, 36H). ESI-MS (m/z): 921(M+1), 943 (M+23).

### Example 2

### Synthesis of a Compound Structure 13

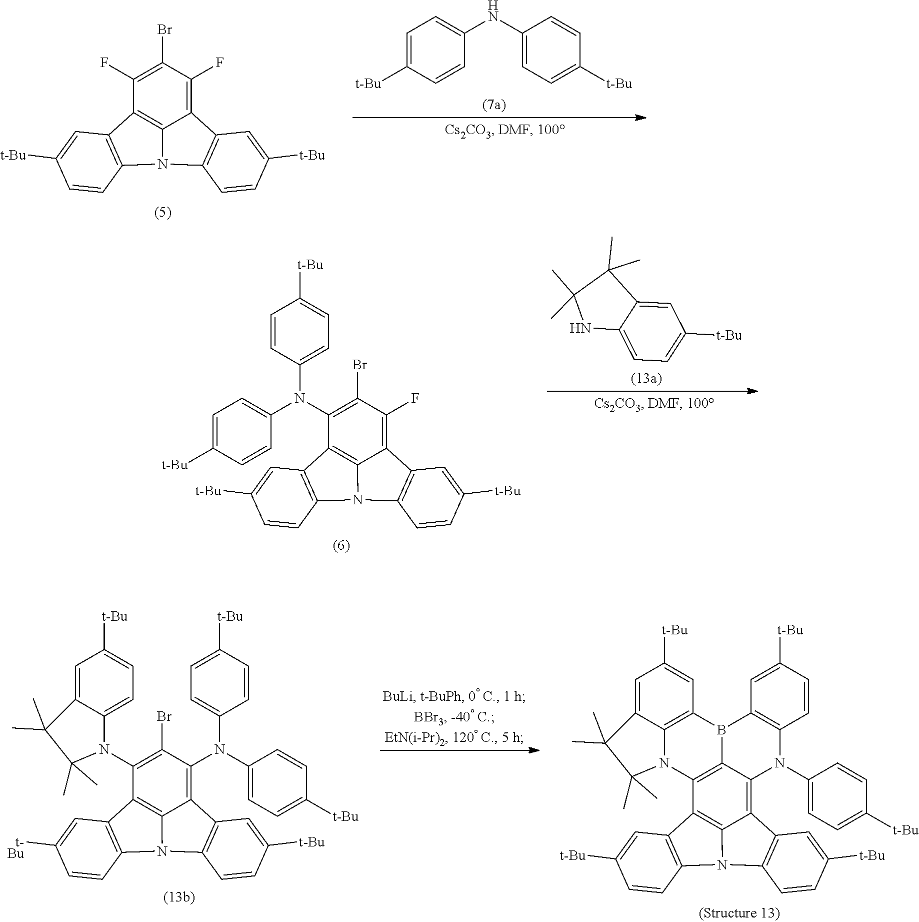 [SMILES: CC(C)(C)c1ccc2c(c1)c1c(F)c(Br)c(F)c3c4cc(C(C)(C)C)ccc4n2c13 ; CC(C)(C)c1ccc(Nc2ccc(C(C)(C)C)cc2)cc1 ; CC(C)(C)c1ccc(N(c2ccc(C(C)(C)C)cc2)c2c(Br)c(F)c3c4cc(C(C)(C)C)ccc4n4c5ccc(C(C)(C)C)cc5c2c34)cc1 ; CC(C)(C)c1ccc2c(c1)C(C)(C)C(C)(C)N2 ; CC(C)(C)c1ccc(N(c2ccc(C(C)(C)C)cc2)c2c(Br)c(N3c4ccc(C(C)(C)C)cc4C(C)(C)C3(C)C)c3c4cc(C(C)(C)C)ccc4n4c5ccc(C(C)(C)C)cc5c2c34)cc1 ; CC(C)(C)c1ccc(N2c3ccc(C(C)(C)C)cc3B3c4cc(C(C)(C)C)cc5c4N(c4c3c2c2c3cc(C(C)(C)C)ccc3n3c6ccc(C(C)(C)C)cc6c4c23)C(C)(C)C5(C)C)cc1]

### Synthesis of a Compound (6)

Magnetons, the compound (5) (0.9 g, 2.0 mmol), a compound (7a) (0.6 g, 2.4 mmol), Cs₂CO₃ (1.3 g, 4 mmol) and DMF (50 mL) were added into a 250 mL one-necked flask and stirred, vacuumization was performed for nitrogen replacement, and then the above compounds were heated to 140° C. to carry out a reaction for 36 hours. Then, cooling was performed to room temperature, extraction was performed with DCM for three times, and an organic phase was spin-dried and mixed with silica gel, followed by column separation with PE to obtain 0.8 g of a light green oily compound with a yield of 45%.d) δ 8.21 (dd, J=19.4, 2.1 Hz, 2H), 7.47-7.37 (m, 4H), 7.27-7.23 (m, 4H), 7.08-7.03 (m, 4H), 1.35 (s, 18H), 1.34 (s, 18H). ESI-MS (m/z): 731 (M+1).

### Synthesis of a Compound (13b)

Magnetons, the compound (6) (1.5 g, 2.0 mmol), a compound (13a) (0.6 g, 2.2 mmol), Cs₂CO₃ (1.3 g, 4 mmol) and DMF (50 mL) were added into a 250 mL one-necked flask and stirred, vacuumization was performed for nitrogen replacement, and then the above compounds were heated to 100° C. to carry out a reaction for 36 hours. Then, cooling was performed to room temperature, extraction was performed with DCM for three times, and an organic phase was spin-dried and mixed with silica gel, followed by column separation with PE to obtain 1.0 g of a light green oily compound with a yield of 52%. ¹H NMR (400 MHz, Chloroform-d) δ 8.20-8.15 (m, 2H), 7.44-7.36 (m, 3H), 7.27-7.20 (m, 6H), 7.11 (dd, J=5.1, 2.2 Hz, 1H), 7.07-7.01 (m, 4H), 6.71 (d, J=5.1 Hz, 1H), 1.46-1.43 (s, 6H), 1.36-1.32 (s, 6H), 1.35 (m, 36H), 1.31-1.28 (s, 9H). ESI-MS (m/z): 942 (M+1).

### Synthesis of a Compound Structure (13)

Based on the same synthesis method of the structure (7), raw materials were put as follows: the compound (13b) (1.9 g, 2.0 mmol), t-BuLi (2 mL, 5 mmol), BBr₃ (0.4 mL, 5 mmol) and diisopropylethylamine (0.9 mL, 5 mmol). 0.47 g of a light yellow powder with a yield of 27% was obtained. ¹H NMR (400 MHz, Chloroform-d) δ 8.19 (dt, J=1.9, 1.0 Hz, 2H), 7.42-7.34 (m, 3H), 7.34-7.30 (m, 2H), 7.29-7.24 (m, 4H), 7.22 (dd, J=6.3, 2.3 Hz, 1H), 7.05-6.97 (m, 3H), 1.45 (s, 6H), 1.40 (s, 6H), 1.36-1.32 (m, 45H). ESI-MS (m/z): 871(M+1).

### Example 3

### Synthesis of a Compound Structure 41

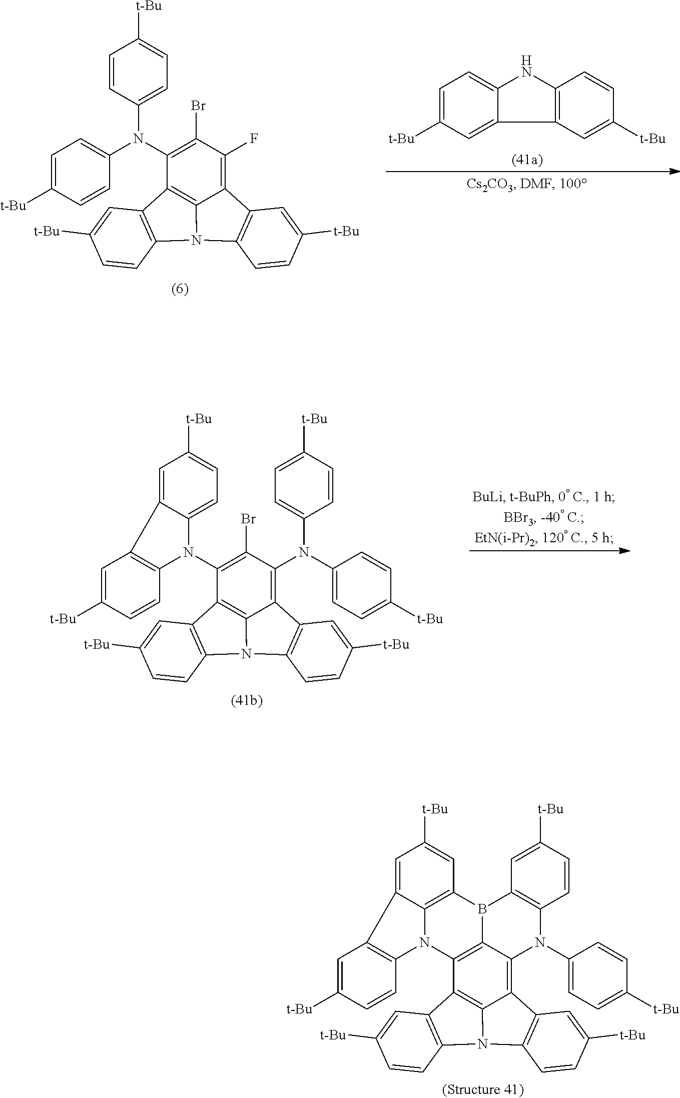

### Synthesis of a Compound (41b)

Based on the same synthesis method of the structure (13b), raw materials were put as follows: the compound (6) (1.5 g, 2.0 mmol), a compound (41a) (0.6 g, 2.2 mmol), Cs₂CO₃ (1.3 g, 4 mmol) and DMF (50 mL). 1.2 g of a light green oily compound with a yield of 61% was obtained. ¹H NMR (400 MHz, Chloroform-d) δ 8.22-8.17 (m, 2H), 8.06 (d, J=2.2 Hz, 1H), 7.93 (d, J=2.4 Hz, 1H), 7.65 (d, J=7.7 Hz, 1H), 7.44-7.35 (m, 5H), 7.30-7.22 (m, 6H), 7.08-7.02 (m, 4H), 1.35 (m, 54H). ESI-MS (m/z): 990 (M+1).

### Synthesis of a Compound Structure (41)

Based on the same synthesis method of the structure (7), raw materials were put as follows: the compound (13b) (2.0 g, 2.0 mmol), t-BuLi (2 mL, 5 mmol), BBr₃ (0.4 mL, 5 mmol) and diisopropylethylamine (0.9 mL, 5 mmol). 0.72 g of a light yellow powder with a yield of 39% was obtained. ¹H NMR (400 MHz, Chloroform-d) δ 8.75 (d, J=2.3 Hz, 1H), 8.21 (d, J=1.9 Hz, 2H), 8.11 (d, J=1.8 Hz, 1H), 7.53 (d, J=7.7 Hz, 1H), 7.45-7.37 (m, 3H), 7.37-7.31 (m, 3H), 7.30-7.25 (m, 2H), 7.24-7.17 (m, 2H), 7.06-6.97 (m, 3H), 1.36-1.33 (m, 54H). ESI-MS (m/z): 919(M+1).

### Example 4

### Synthesis of a Compound Structure 72

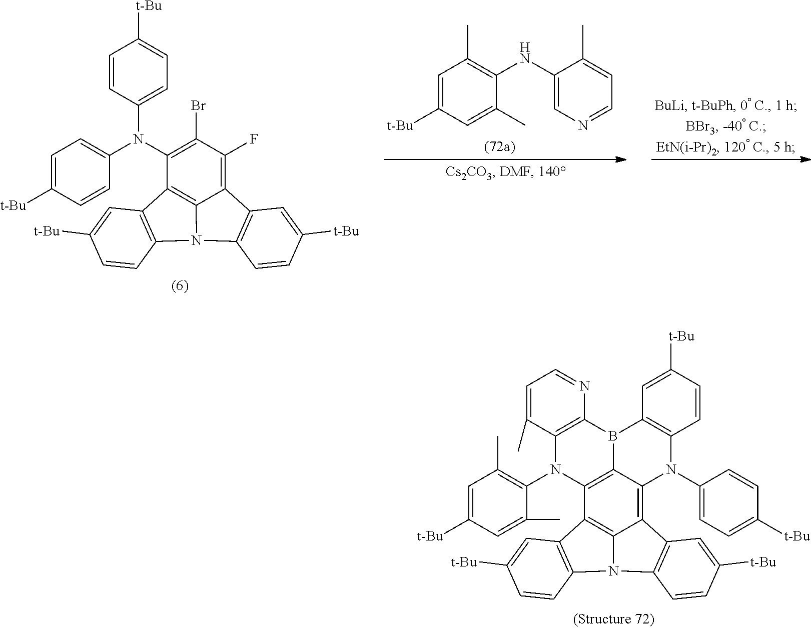 [SMILES: CC(C)(C)c1ccc(N(c2ccc(C(C)(C)C)cc2)c2c(Br)c(F)c3c4cc(C(C)(C)C)ccc4n4c5ccc(C(C)(C)C)cc5c2c34)cc1 ; Cc1ccncc1Nc1c(C)cc(C(C)(C)C)cc1C ; Cc1cc(C(C)(C)C)cc(C)c1N1c2c(C)ccnc2B2c3cc(C(C)(C)C)ccc3N(c3ccc(C(C)(C)C)cc3)c3c2c1c1c2cc(C(C)(C)C)ccc2n2c4ccc(C(C)(C)C)cc4c3c12]

Based on the same synthesis method in Example 3, a compound structure (72) was obtained. ¹H NMR (400 MHz, Chloroform-d) δ 8.19 (d, J=2.1 Hz, 2H), 7.92 (d, J=4.6 Hz, 1H), 7.39 (dd, J=7.7, 2.2 Hz, 2H), 7.32 (d, J=7.7 Hz, 2H), 7.30-7.24 (m, 4H), 7.21 (dd, J=6.2, 2.2 Hz, 1H), 7.19-7.15 (m, 1H), 7.06-6.97 (m, 4H), 2.27 (d, J=0.7 Hz, 3H), 2.14 (s, 6H), 1.37-1.30 (m, 54H). ESI-MS (m/z): 908(M+1).

### Example 5

### Synthesis of a Compound Structure 126

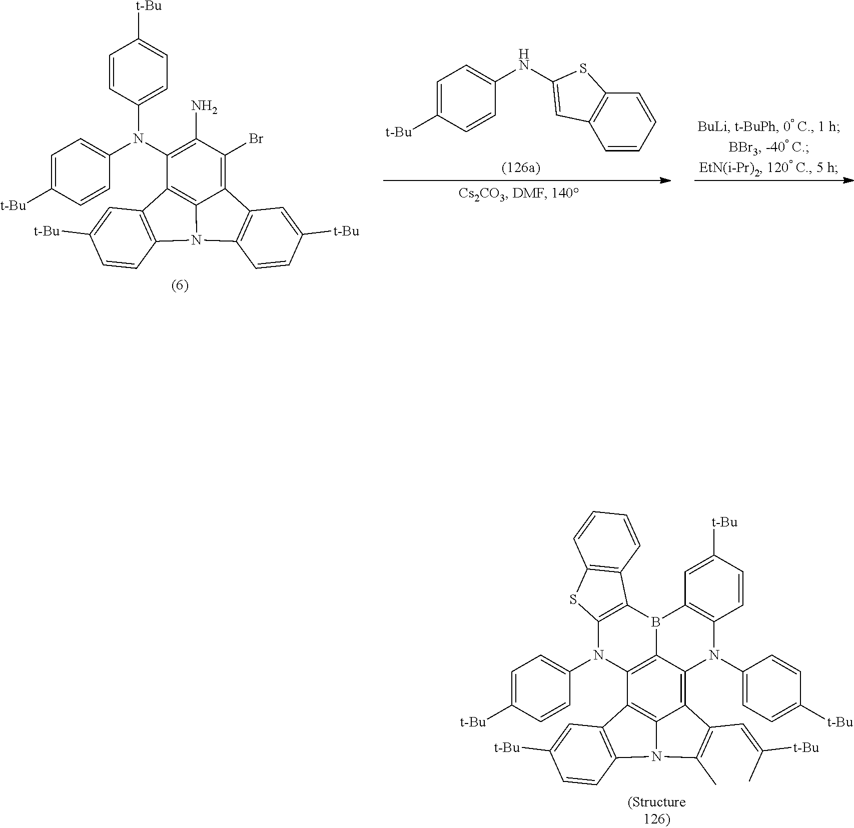 [SMILES: CC(C)(C)c1ccc(N(c2ccc(C(C)(C)C)cc2)c2c(N)c(Br)c3c4cc(C(C)(C)C)ccc4n4c5ccc(C(C)(C)C)cc5c2c34)cc1 ; CC(C)(C)c1ccc(Nc2cc3ccccc3s2)cc1 ; C/C(=C\c1c(C)n2c3ccc(C(C)(C)C)cc3c3c4c5c(c1c32)N(c1ccc(C(C)(C)C)cc1)c1ccc(C(C)(C)C)cc1B5c1c(sc2ccccc12)N4c1ccc(C(C)(C)C)cc1)C(C)(C)C]

Based on the same synthesis method in Example 3, a compound structure (126) was obtained. ¹H NMR (400 MHz, Chloroform-d) δ 8.19 (d, J=2.1 Hz, 2H), 7.83 (dd, J=6.9, 1.3 Hz, 1H), 7.75 (dd, J=6.6, 1.6 Hz, 1H), 7.47 (ddd, J=7.6, 6.5, 1.2 Hz, 1H), 7.39 (dd, J=7.8, 2.2 Hz, 3H), 7.36-7.31 (m, 3H), 7.29-7.24 (m, 4H), 7.22 (dd, J=6.3, 2.3 Hz, 1H), 7.07-6.96 (m, 5H), 1.37-1.32 (m, 45H). ESI-MS (m/z): 921(M+1), 943(M+23).

### Example 6

### Synthesis of a Compound Structure 127

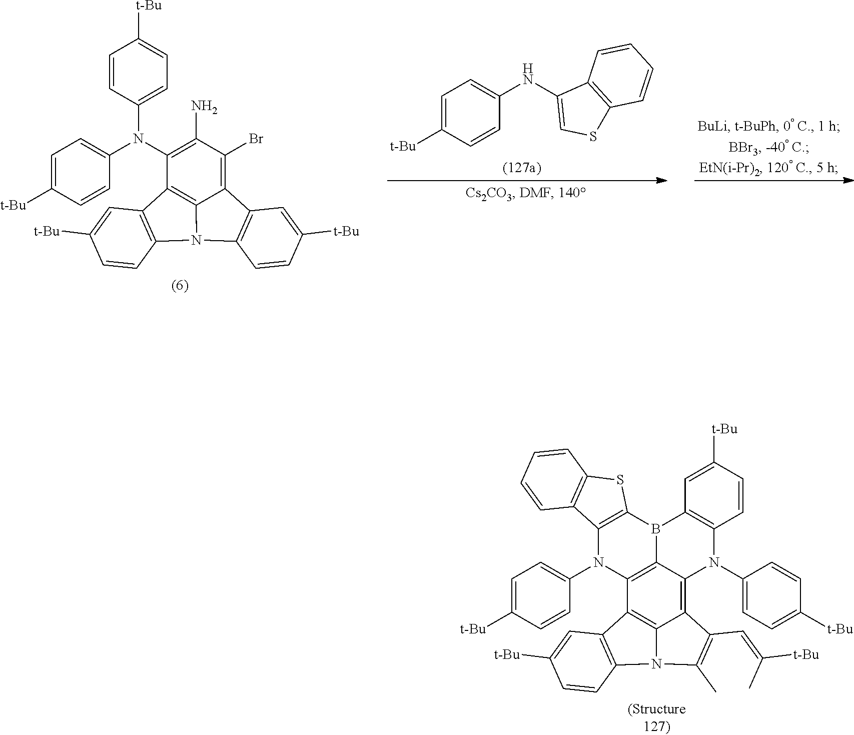 [SMILES: CC(C)(C)c1ccc(N(c2ccc(C(C)(C)C)cc2)c2c(N)c(Br)c3c4cc(C(C)(C)C)ccc4n4c5ccc(C(C)(C)C)cc5c2c34)cc1 ; CC(C)(C)c1ccc(Nc2csc3ccccc23)cc1 ; C/C(=C\c1c(C)n2c3ccc(C(C)(C)C)cc3c3c4c5c(c1c32)N(c1ccc(C(C)(C)C)cc1)c1ccc(C(C)(C)C)cc1B5c1sc2ccccc2c1N4c1ccc(C(C)(C)C)cc1)C(C)(C)C]

Based on the same synthesis method in Example 3, a compound structure (127) was obtained. ¹H NMR (400 MHz, Chloroform-d) δ 8.19 (d, J=2.1 Hz, 2H), 8.00 (dd, J=7.8, 1.4 Hz, 1H), 7.75 (dd, J=6.5, 1.6 Hz, 1H), 7.48 (ddd, J=7.6, 6.5, 1.3 Hz, 1H), 7.39 (dd, J=7.7, 2.2 Hz, 2H), 7.34-7.30 (m, 4H), 7.29-7.25 (m, 4H), 7.22 (dd, J=6.3, 2.3 Hz, 1H), 7.07-6.97 (m, 5H), 1.36-1.33 (m, 45H). ESI-MS (m/z): 921(M+1).

### Example 7

### Synthesis of a Compound Structure 129

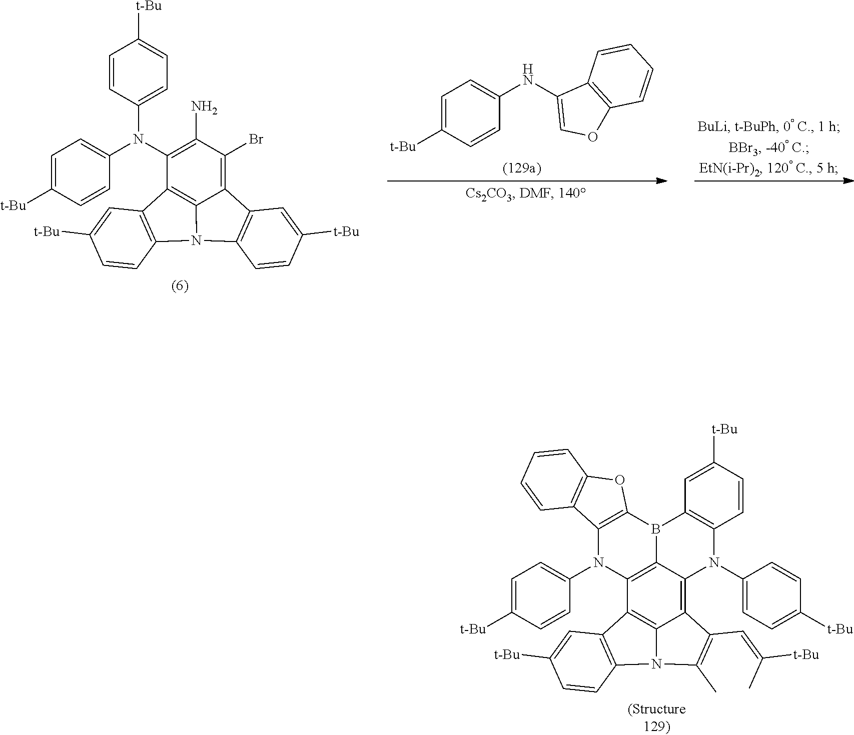 [SMILES: CC(C)(C)c1ccc(N(c2ccc(C(C)(C)C)cc2)c2c(N)c(Br)c3c4cc(C(C)(C)C)ccc4n4c5ccc(C(C)(C)C)cc5c2c34)cc1 ; CC(C)(C)c1ccc(Nc2coc3ccccc23)cc1 ; C/C(=C\c1c(C)n2c3ccc(C(C)(C)C)cc3c3c4c5c(c1c32)N(c1ccc(C(C)(C)C)cc1)c1ccc(C(C)(C)C)cc1B5c1oc2ccccc2c1N4c1ccc(C(C)(C)C)cc1)C(C)(C)C]

Based on the same synthesis method in Example 3, a compound structure (129) was obtained. ¹H NMR (400 MHz, Chloroform-d) δ 8.19 (d, J=2.1 Hz, 2H), 7.86-7.79 (m, 1H), 7.54 (d, J=2.2 Hz, 1H), 7.47-7.36 (m, 3H), 7.35-7.24 (m, 8H), 7.22 (dd, J=6.3, 2.3 Hz, 1H), 7.06-6.98 (m, 5H), 1.38-1.31 (m, 45H). ESI-MS (m/z): 905(M+1).

Persons skilled in the art shall know that the above preparation method is only an exemplary example, and for persons skilled in the art, other compound structures of the present invention can be obtained by improvement of the method.

### Example 8

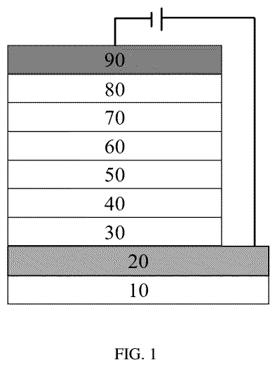

An organic electroluminescent low-emission device was prepared by using an organic electroluminescent material containing B—N fused rings of the present invention. The structure of the device is as shown in FIG. 1.

First, a transparent conductive indium tin oxide (ITO) glass substrate 10 (with an anode 20) was sequentially washed with deionized water, ethanol, acetone and deionized water, dried at 80° C., and then treated with oxygen plasma for 30 minutes. Then, HATCN with a thickness of 10 nm was evaporated by an evaporator under a vacuum of less than 4*10⁻⁴ pa to serve as a hole injection layer 30. A compound HTL was evaporated to form a hole transport layer 40 with a thickness of 40 nm. An electron blocking layer (EBL) 50 with a thickness of 10 nm was evaporated on the hole transport layer. Then, a light-emitting layer (including a host material (Host) and 3% of a guest material, EML) 60 with a thickness of 20 nm was evaporated, where the light-emitting layer was formed by doping of an organic electroluminescent material containing B—N fused rings (structure 7, 3%) and the host material. An electron transport layer (ETL) 70 with a thickness of 40 nm was evaporated on the light-emitting layer, where the electron transport layer was composed of two materials including ETL1 and LiQ.Metal ytterbium with a thickness of 1 nm and Ag with a thickness of 100 nm were evaporated to serve as an electron injection layer 80 and a device cathode 90, respectively.

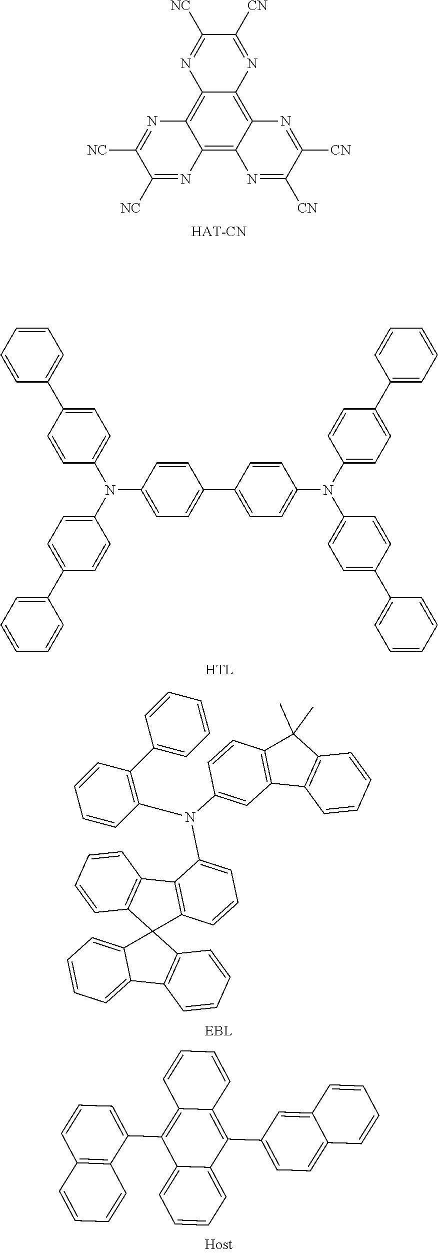

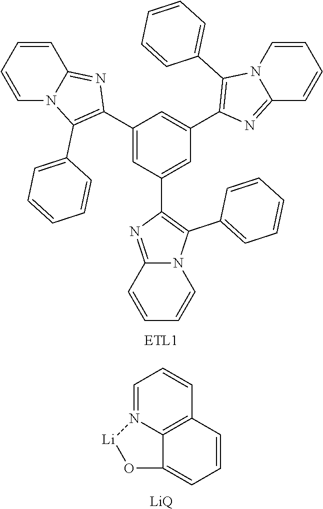

### Example 9-Example 14, Comparative Example 1 and Comparative Example 2

Organic electroluminescent devices in Example 9-Example 14, Comparative Example 1 and Comparative Example 2 were manufactured by the same method as that in Example 8, but had the difference that a structure 13, a structure 41, a structure 72, a structure 126, a structure 127, a structure 129, a material in Comparative Example 1 and a material in Comparative Example 2 were used as the guest material in the light-emitting layer, respectively. Chemical structures of the materials in comparative examples are shown as follows:

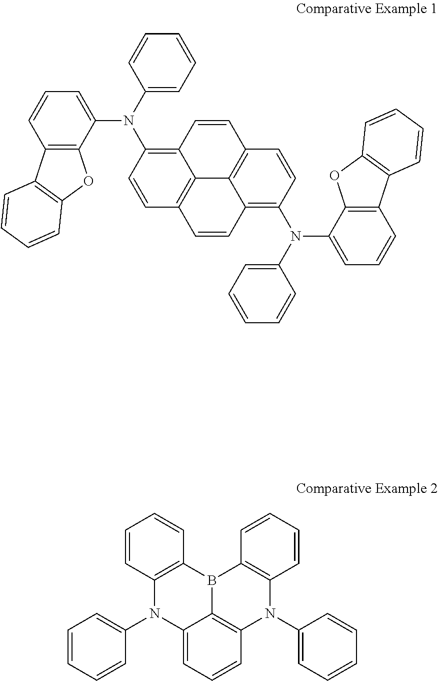 [SMILES: c1ccc(N(c2ccc3ccc4c(N(c5ccccc5)c5cccc6c5oc5ccccc56)ccc5ccc2c3c54)c2cccc3c2oc2ccccc23)cc1 ; c1ccc(N2c3ccccc3B3c4ccccc4N(c4ccccc4)c4cccc2c43)cc1]

Electrical and optical properties of the organic electroluminescent devices in Example 9-Example 14, Comparative Example 1 and Comparative Example 2 were determined at 0.4 mA, as shown in Table 1.

TABLE 1

| | | Current | | |
|---|---|---|---|---|
| | Voltage | efficiency | Light-emitting | Half-wave |
| Number | (V) | (cd/A) | wavelength (nm) | width (nm) |
| Example 8 | 3.6 | 5.1 | 462 | 32 |
| Example 9 | 3.5 | 5.3 | 458 | 28 |
| Example 10 | 3.6 | 5.4 | 468 | 30 |
| Example 11 | 3.8 | 5.9 | 470 | 33 |
| Example 12 | 3.7 | 5.2 | 461 | 28 |
| Example 13 | 3.7 | 5.5 | 461 | 27 |
| Example 14 | 3.5 | 5.1 | 465 | 29 |
| Comparative | 3.8 | 6.5 | 458 | 55 |
| Example 1 | | | | |
| Comparative | 3.7 | 5.1 | 459 | 33 |
| Example 2 | | | | |

It can be seen from the data in Table 1 that under same conditions, the organic electroluminescent materials containing B—N fused rings of the present invention applied to organic electroluminescent devices have small half-wave width and higher color purity (compared with that in Comparative Example 1), so as to achieve a better display effect. Under same conditions, the organic electroluminescent materials containing B—N fused rings of the present invention applied to organic electroluminescent devices have small half-wave width and improved current efficiency compared with a more similar structure in Comparative Example 2, thus having better properties.

1. Organic electroluminescent materials containing B—N fused ring structures, having a structure represented by General Formula (I): 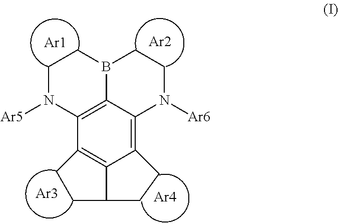
wherein
Ar1 to Ar4 are independently selected from substituted or unsubstituted aryl containing 6-30 carbon atoms, and substituted or unsubstituted heteroaryl containing 5-30 carbon atoms;
Ar5 and Ar6 are independently selected from substituted or unsubstituted C₁-C₆₀ alkyl, substituted or unsubstituted C₂-C₆₀ alkenyl, substituted or unsubstituted C₂-C₆₀alkynyl, substituted or unsubstituted C₁-C₆₀alkoxyl, substituted or unsubstituted C₃-C₁₀cycloalkyl, substituted or unsubstituted C₁-C₁₀ heterocyclic alkyl, substituted or unsubstituted C₃-C₁₀cycloalkenyl, substituted or unsubstituted C₁-C₁₀ heterocyclic alkenyl, substituted or unsubstituted C₆-C₆₀ aryl, substituted or unsubstituted C₆-C₆₀aryloxyl, substituted or unsubstituted C₆-C₆₀arylthio, substituted or unsubstituted C₁-C₆₀heteroaryl, a substituted or unsubstituted non-aromatic fused polycyclic ring, and a substituted or unsubstituted non-aromatic fused heteropolycyclic ring, or one or more of the Ar1 to Ar6 are bonded to the adjacent group Ar1 or Ar2 by any one or more of a single bond, —C—C—, —C═C—, —C═N—, —C═P—, —C≡C—, 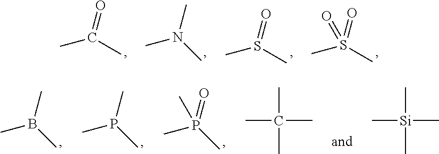
to form a ring structure, respectively;
at least one group of the Ar1 and the Ar2, and the Ar5 and the Ar6 are different;
the “substituted” refers to substitution with one or more of deuterium, cyano, nitro, halogen, hydroxyl, alkylthio containing 1 to 4 carbon atoms, substituted or unsubstituted alkyl containing 1 to 30 carbon atoms, substituted or unsubstituted cycloalkyl containing 1 to 20 carbon atoms, aryloxyl containing 6 to 30 carbon atoms, alkoxyl containing 1 to 30 carbon atoms, alkyl amino containing 1 to 30 carbon atoms, aryl amino containing 6 to 30 carbon atoms, aralkyl amino containing 6 to 30 carbon atoms, heteroaryl amino containing 2 to 24 carbon atoms, alkyl silyl containing 1 to 30 carbon atoms, aryl silyl containing 6 to 30 carbon atoms, alkyl containing 1 to 30 carbon atoms, alkenyl containing 2 to 30 carbon atoms, alkynyl containing 2 to 24 carbon atoms, aralkyl containing 7 to 30 carbon atoms, aryl containing 6 to 30 carbon atoms, heteroaryl containing 5 to 60 carbon atoms, and heteroaryl alkyl containing 6 to 30 carbon atoms;
and the heterocyclic alkyl, the heterocyclic alkenyl and the heteroaryl contain one or more heteroatoms of N, S, O, P, B and Si.

2. The organic electroluminescent materials according to claim 1, wherein the structure is selected from one of structures represented by General Formulas (II-1)-(II-10): 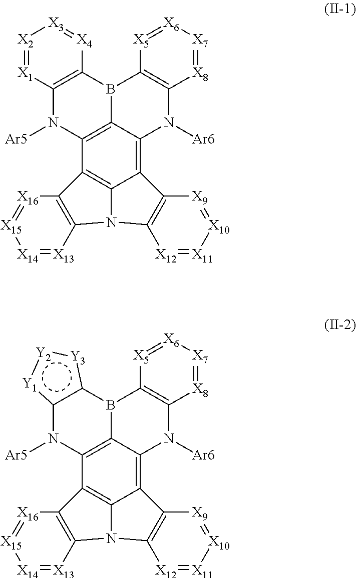 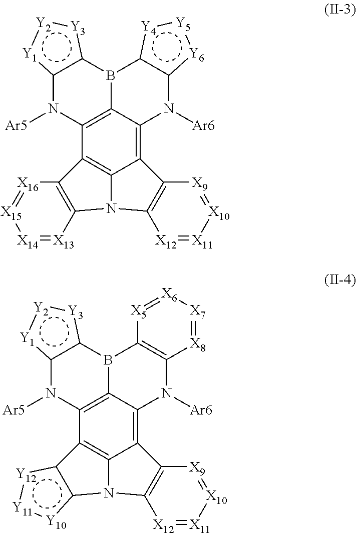 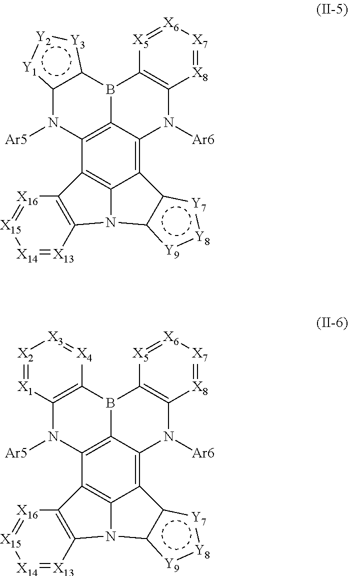 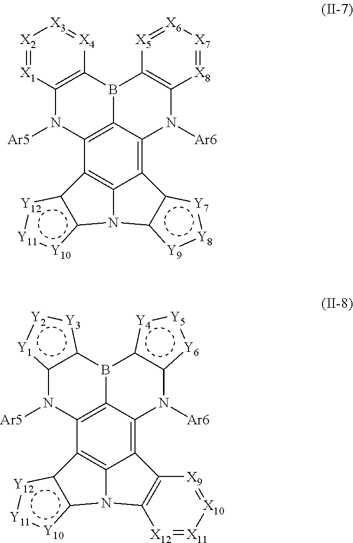 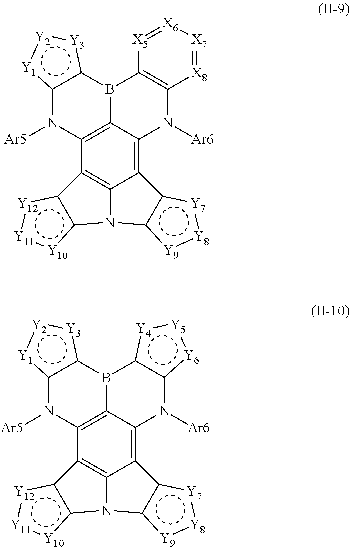
wherein X₁-X₁₆ independently refer to a nitrogen atom or CR1, R1 is equally or unequally independently selected from one of a hydrogen atom, a protium atom, a deuterium atom, a tritium atom, a fluorine atom, cyano, phosphoric acid or salts thereof, linear or branched C₁-C₂₀ alkyl, linear or branched silyl substituted with C₁-C₂₀ alkyl, substituted or unsubstituted C₆-C₃₀ aryl, and substituted or unsubstituted C₅-C₃₀heteroaryl, or two or more R1 are connected to each other to form an alkyl ring, a heteroalkyl ring, an aromatic ring, or a heteroaromatic ring;
one of Y₁-Y₃, Y₄-Y₆, Y₇-Y₉ and Y₁₀-Y₁₂ independently refers to an oxygen atom, a sulfur atom, N—R2, R3-C—R4, C═O, C═S, R5-Si—R6, P—R7, P═O, or O═P═O, other groups are independently selected from a nitrogen atom or C—R8, R2 to R8 are equally or unequally independently selected from one of a hydrogen atom, a protium atom, a deuterium atom, a tritium atom, a fluorine atom, cyano, phosphoric acid or salts thereof, linear or branched C₁-C₂₀ alkyl, linear or branched silyl substituted with C₁-C₂₀ alkyl, substituted or unsubstituted C₆-C₃₀ aryl, and substituted or unsubstituted C₅-C₃₀heteroaryl, or the R2-R8 are independently or mutually bonded to each other by any one or more of a single bond, —C—C—, —C═C—, —C═N—, —C═P—, —C≡C—, 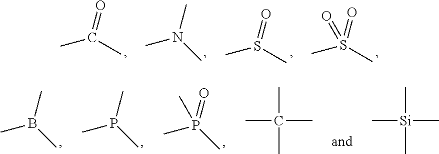
to form a ring structure;
Ar5 and Ar6 are independently selected from a substituted or unsubstituted C₁-C₆₀ alkyl group, a substituted or unsubstituted C₂-C₆₀ alkenyl group, a substituted or unsubstituted C₂-C₆₀alkynyl group, a substituted or unsubstituted C₁-C₆₀alkoxyl group, a substituted or unsubstituted C₃-C₁₀cycloalkyl group, a substituted or unsubstituted C₁-C₁₀ heterocyclic alkyl group, a substituted or unsubstituted C₃-C₁₀cycloalkenyl group, a substituted or unsubstituted C₁-C₁₀ heterocyclic alkenyl group, a substituted or unsubstituted C₆-C₆₀ aryl group, a substituted or unsubstituted C₆-C₆₀aryloxyl group, a substituted or unsubstituted C₆-C₆₀arylthio group, a substituted or unsubstituted C₁-C₆₀heteroaryl group, a substituted or unsubstituted non-aromatic fused polycyclic ring group, and a substituted or unsubstituted non-aromatic fused heteropolycyclic ring group, and one or more of the Ar5 and the Ar6 are connected to the adjacent group Ar1 or Ar2 by any one or more of a single bond, —C—C—, —C═C—, —C═N—, —C═P—, —C≡C—, 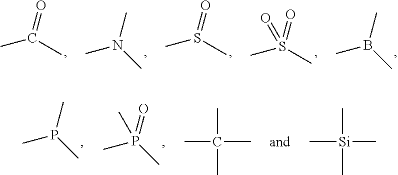
to form a ring, respectively;
the “substituted” refers to substitution with one or more substituents selected from the group consisting of deuterium, cyano, nitro, halogen, hydroxyl, alkylthio containing 1 to 4 carbon atoms, substituted or unsubstituted alkyl containing 1 to 30 carbon atoms, substituted or unsubstituted cycloalkyl containing 1 to 20 carbon atoms, aryloxyl containing 6 to 30 carbon atoms, alkoxyl containing 1 to 30 carbon atoms, alkyl amino containing 1 to 30 carbon atoms, aryl amino containing 6 to 30 carbon atoms, aralkyl amino containing 6 to 30 carbon atoms, heteroaryl amino containing 2 to 24 carbon atoms, alkyl silyl containing 1 to 30 carbon atoms, aryl silyl containing 6 to 30 carbon atoms, alkyl containing 1 to 30 carbon atoms, alkenyl containing 2 to 30 carbon atoms, alkynyl containing 2 to 24 carbon atoms, aralkyl containing 7 to 30 carbon atoms, aryl containing 6 to 30 carbon atoms, heteroaryl containing 5 to 60 carbon atoms, and heteroaryl alkyl containing 6 to 30 carbon atoms;
and the heteroaryl, the heteroalkyl ring and the heteroaromatic ring contain one or more heteroatoms selected from N, O, S, or Si.

3. The organic electroluminescent materials according to claim 2, wherein at least one group of the X1 and the X8, the X2 and the X7, the X3 and the X6, the X4 and the X5, the Y1 and the Y6, the Y2 and the Y5, the Y3 and the Y4, and the Ar5 and the Ar6 are different.

4. The organic electroluminescent materials according to claim 3, wherein the X₁-X₁₆ independently refer to a nitrogen atom or CR1, R1 is equally or unequally independently selected from one of a hydrogen atom, a protium atom, a deuterium atom, a tritium atom, a fluorine atom, cyano, linear or branched C₁-C₈ alkyl, substituted or unsubstituted C₆-C₂₀ aryl, and substituted or unsubstituted C₅-C₂₀heteroaryl, or two or more R1 are connected to each other to form an alkyl ring, a heteroalkyl ring, an aromatic ring, or a heteroaromatic ring;
one of the Y₁-Y₃, the Y₄-Y₆, the Y₇-Y₉ and the Y₁₀-Y₁₂ independently refers to an oxygen atom, a sulfur atom, N—R2, or R3-C—R4, other groups are independently selected from a nitrogen atom or C—R8, the R2 to R8 are equally or unequally independently selected from one of a hydrogen atom, a protium atom, a deuterium atom, a tritium atom, a fluorine atom, cyano, linear or branched C₁-C₂₀ alkyl, substituted or unsubstituted C₆-C₃₀ aryl, and substituted or unsubstituted C₅-C₃₀heteroaryl, or the R2-R8 are independently or mutually bonded to each other by any one or more of a single bond, —C—C—, —C═C—, —C═N—, —C≡C—, 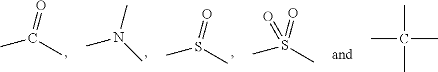
to form an alkyl ring, a heteroalkyl ring, an aromatic ring, or a heteroaromatic ring;
the Ar5 and the Ar6 are independently selected from substituted or unsubstituted C₁-C₈ alkyl, substituted or unsubstituted C₂-C₁₀ alkenyl, substituted or unsubstituted C₂-C₁₀alkynyl, substituted or unsubstituted C₁-C₈₀alkoxyl, substituted or unsubstituted C₃-C₁₀cycloalkyl, substituted or unsubstituted C₁-C₈ heterocyclic alkyl, substituted or unsubstituted C₃-C₁₀cycloalkenyl, substituted or unsubstituted C₁-C₁₀ heterocyclic alkenyl, substituted or unsubstituted C₆-C₂₀ aryl, substituted or unsubstituted C₆-C₂₀aryloxyl, a substituted or unsubstituted C₆-C₂₀arylthio group, substituted or unsubstituted C₁-C₂₀heteroaryl, a substituted or unsubstituted non-aromatic fused polycyclic ring group, and a substituted or unsubstituted non-aromatic fused heteropolycyclic ring group, and one or more of the Ar5 and the Ar6 are connected to the adjacent group Ar1 or Ar2 by any one or more of a single bond, —C—C—, —C═C—, —C═N—, —C≡C—, 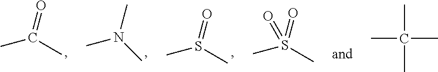
to form a ring, respectively;
the “substituted” refers to substitution with one or more substituents selected from the group consisting of deuterium, cyano, nitro, halogen, hydroxyl, alkylthio containing 1 to 4 carbon atoms, substituted or unsubstituted alkyl containing 1 to 8 carbon atoms, substituted or unsubstituted cycloalkyl containing 1 to 10 carbon atoms, aryloxyl containing 6 to 20 carbon atoms, alkoxyl containing 1 to 10 carbon atoms, alkyl amino containing 1 to 10 carbon atoms, aryl amino containing 6 to 20 carbon atoms, aralkyl amino containing 6 to 20 carbon atoms, heteroaryl amino containing 2 to 10 carbon atoms, alkenyl containing 2 to 10 carbon atoms, alkynyl containing 2 to 10 carbon atoms, aralkyl containing 7 to 20 carbon atoms, aryl containing 6 to 20 carbon atoms, heteroaryl containing 5 to 20 carbon atoms, and heteroaryl alkyl containing 6 to 20 carbon atoms;
and the heteroaryl, the heteroalkyl ring and the heteroaromatic ring contain one or more heteroatoms selected from N, O, S, or Si.

5. The organic electroluminescent materials according to claim 4, wherein the X₁-X₁₆ independently refer to a nitrogen atom or CR1, R1 is equally or unequally independently selected from one of a hydrogen atom, linear or branched C₁-C₈ alkyl, substituted or unsubstituted C₆-C₂₀ aryl, and substituted or unsubstituted C₅-C₂₀heteroaryl, or two or more R1 are connected to each other to form an alkyl ring, a heteroalkyl ring, an aromatic ring, or a heteroaromatic ring;
one of the Y₁-Y₃, the Y₄-Y₆, the Y₇-Y₉ and the Y₁₀-Y₁₂ independently refers to an oxygen atom, a sulfur atom, or N—R2, other groups are independently selected from a nitrogen atom or C—R8, the R2 and the R8 are equally or unequally independently selected from one of a hydrogen atom, linear or branched C₁-C₂₀ alkyl, substituted or unsubstituted C₆-C₂₀ aryl, and substituted or unsubstituted C₅-C₂₀heteroaryl, or the R2 and the R8 are independently or mutually bonded to each other by any one or more of a single bond, —C—C—, —C═C—, —C═N—, 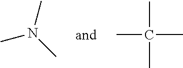
to form an alkyl ring, a heteroalkyl ring, an aromatic ring, or a heteroaromatic ring;
the Ar5 and the Ar6 are independently selected from substituted or unsubstituted C₁-C₈ alkyl, substituted or unsubstituted C₂-C₁₀ alkenyl, substituted or unsubstituted C₁-C₈₀alkoxyl, substituted or unsubstituted C₃-C₁₀cycloalkyl, substituted or unsubstituted C₁-C₈ heterocyclic alkyl, substituted or unsubstituted C₃-C₁₀cycloalkenyl, substituted or unsubstituted C₁-C₁₀ heterocyclic alkenyl, substituted or unsubstituted C₆-C₂₀ aryl, substituted or unsubstituted C₆-C₂₀aryloxyl, a substituted or unsubstituted C₆-C₂₀arylthio group, substituted or unsubstituted C₁-C₂₀heteroaryl, a substituted or unsubstituted non-aromatic fused polycyclic ring group, and a substituted or unsubstituted non-aromatic fused heteropolycyclic ring group, or one or more of the Ar5 and the Ar6 are connected to the adjacent group Ar1 or Ar2 by any one or more of a single bond, —C—C—, —C═C—, —C═N—, 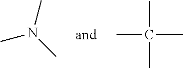
to form a ring, respectively;
the “substituted” refers to substitution with one or more substituents selected from the group consisting of deuterium, alkyl containing 1 to 8 carbon atoms, cycloalkyl containing 1 to 10 carbon atoms, aryl containing 6 to 20 carbon atoms, heteroaryl containing 5 to 20 carbon atoms, and heteroaryl alkyl containing 6 to 20 carbon atoms;
and the heteroaryl, the heteroalkyl ring and the heteroaromatic ring contain one or more heteroatoms selected from N, O, S, or Si.

6. The organic electroluminescent materials according to claim 5, wherein the structure is selected from one of the structures represented by General Formulas (II-1)-(II-3), the X₁-X₁₆ independently refer to a nitrogen atom or CR1, and R1 is equally or unequally independently selected from one of a hydrogen atom, linear or branched C₁-C₈ alkyl, and substituted or unsubstituted C₆-C₂₀ aryl;
one of the Y₁-Y₃, the Y₄-Y₆, the Y₇-Y₉ and the Y₁₀-Y₁₂ independently refers to an oxygen atom, a sulfur atom, or N—R2, other groups are independently selected from C—R8, the R2 and the R8 are equally or unequally independently selected from one of a hydrogen atom, linear or branched C₁-C₂₀ alkyl, and substituted or unsubstituted C₆-C₂₀ aryl, or the R8 is mutually bonded by any one or more of a single bond, —C—C— and —C═C— to form an alkyl ring or a six-membered aromatic ring;
the Ar5 and the Ar6 are independently selected from substituted or unsubstituted C₁-C₈ alkyl, substituted or unsubstituted C₆-C₂₀ aryl, substituted or unsubstituted C₁-C₂₀heteroaryl, a substituted or unsubstituted non-aromatic fused polycyclic ring group, and a substituted or unsubstituted non-aromatic fused heteropolycyclic ring group, or one of the Ar5 and the Ar6 is connected to the adjacent group Ar1 or Ar2 by any one or more of a single bond and —C—C— to form a ring, respectively;
the “substituted” refers to substitution with one or more substituents selected from the group consisting of deuterium, alkyl containing 1 to 8 carbon atoms, cycloalkyl containing 1 to 10 carbon atoms, and aryl containing 6 to 10 carbon atoms;
and the heteroaryl contains one or more heteroatoms selected from N, O, S, or Si.

7. The organic electroluminescent materials according to claim 6, wherein the X₉-X₁₆ independently refer to CR1, and R1 is equally or unequally independently selected from one of a hydrogen atom, linear or branched C₁-C₄ alkyl, and substituted or unsubstituted C₆-C₁₀ aryl.

8. The organic electroluminescent materials according to any one of claims 1-7, wherein the aryl is selected from one or more of phenyl, naphthyl, anthracyl, binaphthyl, phenanthryl, dihydrophenanthryl, pyrenyl, perylenyl, tetracenyl, pentacenyl, benzoperylenyl, benzocyclopentadienyl, spirofluorenyl and fluorenyl; and the heteroaryl is optionally selected from one or more of pyrrolyl, imidazolyl, thienyl, furyl, 1,2-thiazolyl, 1,3-thiazolyl, 1,2,3-oxadiazolyl, 1,2,4-oxadiazolyl, thiadiazolyl, selenadiazolyl, 1,2,3-triazolyl, 1,2,4-triazolyl, pyridinyl, pyrazinyl, pyrimidinyl, 1,3,5-triazinyl, 1,2,4-triazinyl, 1,2,3-triazinyl, indolyl, isoindolyl, benzimidazolyl, naphthoimidazolyl, phenanthroimidazolyl, benzotriazolyl, purinyl, benzoxazolyl, naphthoxazolyl, phenanthroxazolyl, benzothiadiazolyl, benzoselenadiazolyl, benzotriazolyl, quinolyl, isoquinolyl, benzopyrazinyl, benzothienyl, benzofuryl, benzopyrrolyl, carbazolyl, acridinyl, dibenzothienyl, dibenzofuryl, silafluorenyl, dibenzothiophene-5,5-dioxo, naphthothiadiazolyl, naphthoselenadiazolyl and 10,15-dihydro-5H-diindolo[3,2-a:3′,2′-c]carbazolyl.

9. The organic electroluminescent materials according to claim 8, wherein the aryl is selected from one or more of phenyl, naphthyl, anthracyl, phenanthryl, dihydrophenanthryl, tetracenyl, pentacenyl, benzoperylenyl, benzocyclopentadienyl, spirofluorenyl and fluorenyl; and the heteroaryl is selected from one or more of pyrrolyl, imidazolyl, thienyl, furyl, 1,2-thiazolyl, 1,3-thiazolyl, 1,2,3-oxadiazolyl, 1,2,4-oxadiazolyl, thiadiazolyl, selenadiazolyl, 1,2,3-triazolyl, 1,2,4-triazolyl, pyridinyl, pyrazinyl, pyrimidinyl, 1,3,5-triazinyl, 1,2,4-triazinyl, 1,2,3-triazinyl, indolyl, isoindolyl, benzimidazolyl, naphthoimidazolyl, phenanthroimidazolyl, benzotriazolyl, purinyl, benzoxazolyl, naphthoxazolyl, phenanthroxazolyl, benzothiadiazolyl, benzotriazolyl, quinolyl, isoquinolyl, benzopyrazinyl, benzothienyl, benzofuryl, benzopyrrolyl, carbazolyl, acridinyl, dibenzothienyl, dibenzofuryl, dibenzothiophene-5,5-dioxo, naphthothiadiazolyl, naphthoselenadiazolyl and 10,15-dihydro-5H-diindolo[3,2-a:3′,2′-c]carbazolyl.

10. The organic electroluminescent materials according to claim 2, wherein the structure is shown as one of the following structures:

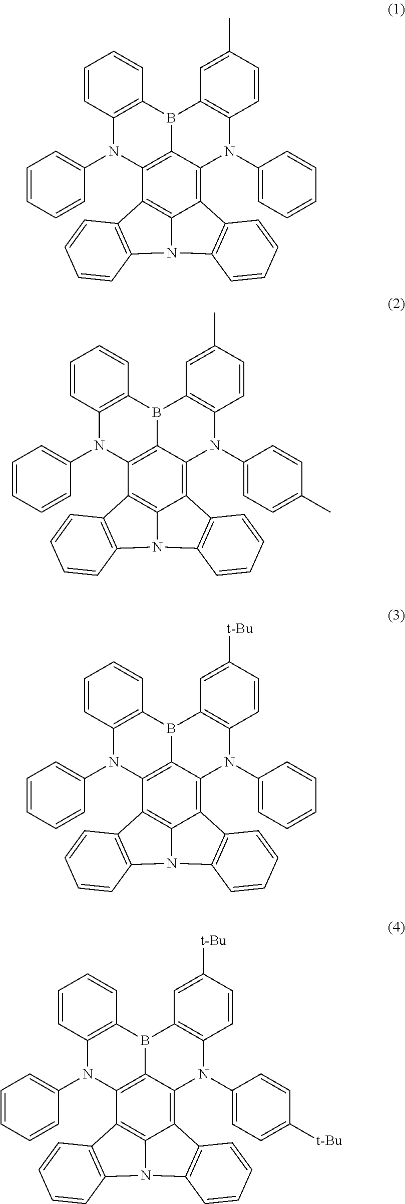

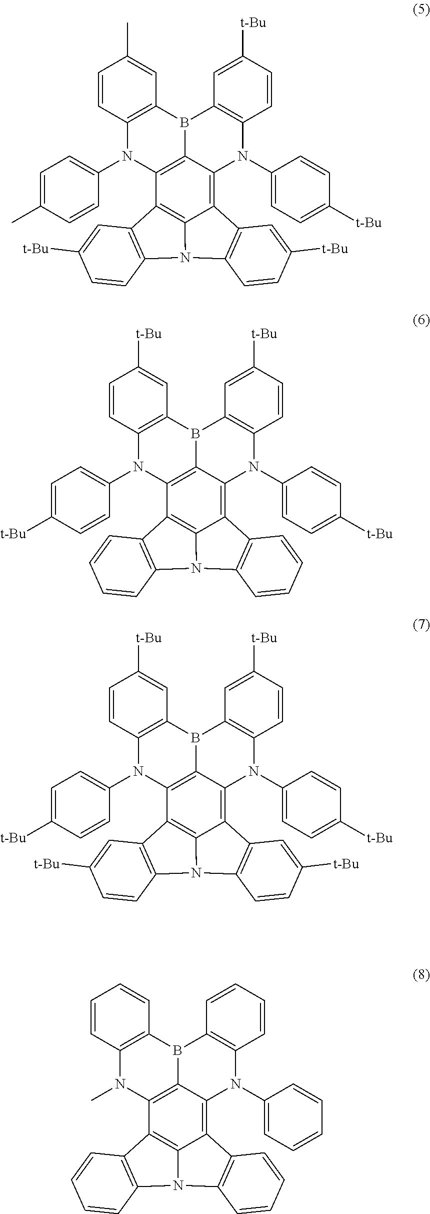

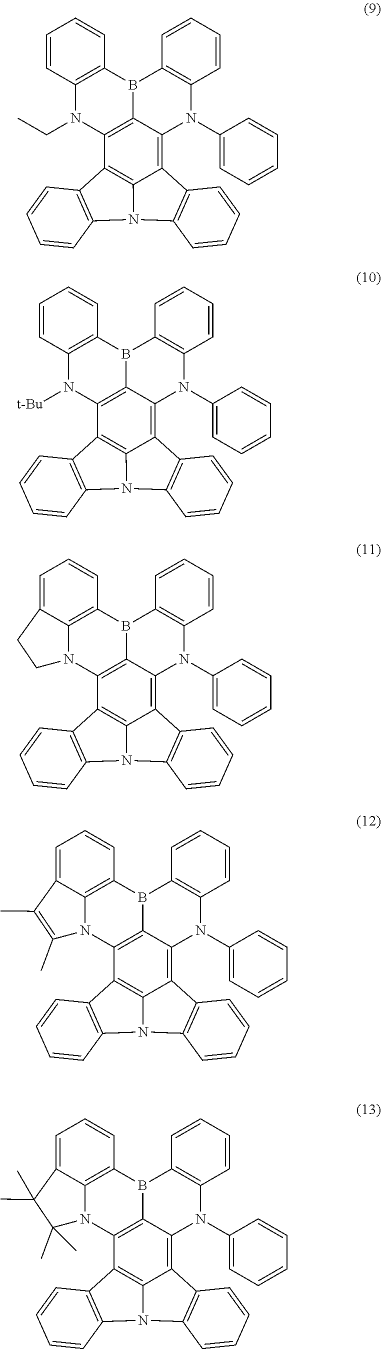

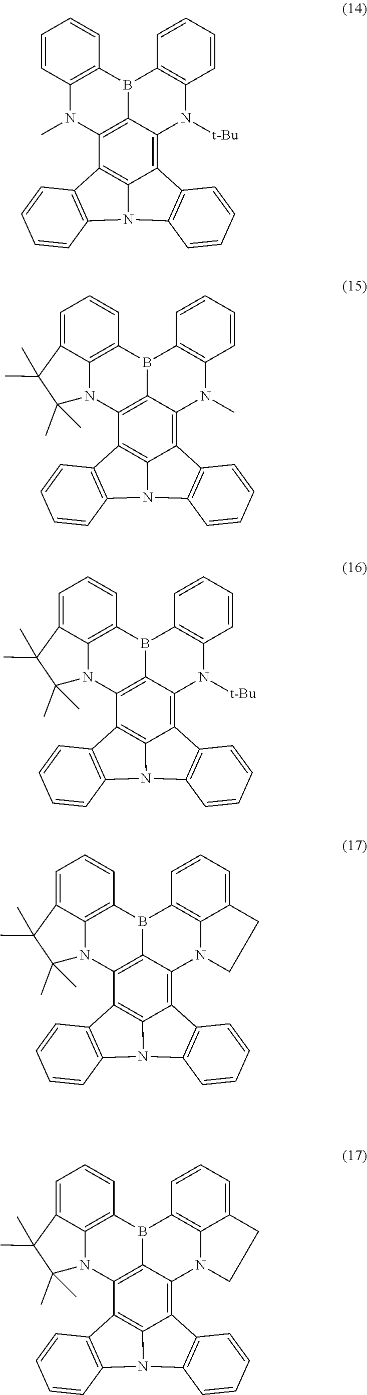 [SMILES: CN1c2ccccc2B2c3ccccc3N(C(C)(C)C)c3c2c1c1c2ccccc2n2c4ccccc4c3c12 ; CN1c2ccccc2B2c3cccc4c3N(c3c2c1c1c2ccccc2n2c5ccccc5c3c12)C(C)(C)C4(C)C ; CC(C)(C)N1c2ccccc2B2c3cccc4c3N(c3c2c1c1c2ccccc2n2c5ccccc5c3c12)C(C)(C)C4(C)C ; CC1(C)c2cccc3c2N(c2c4c(c5c6ccccc6n6c7ccccc7c2c56)N2CCc5cccc(c52)B34)C1(C)C ; CC1(C)c2cccc3c2N(c2c4c(c5c6ccccc6n6c7ccccc7c2c56)N2CCc5cccc(c52)B34)C1(C)C]

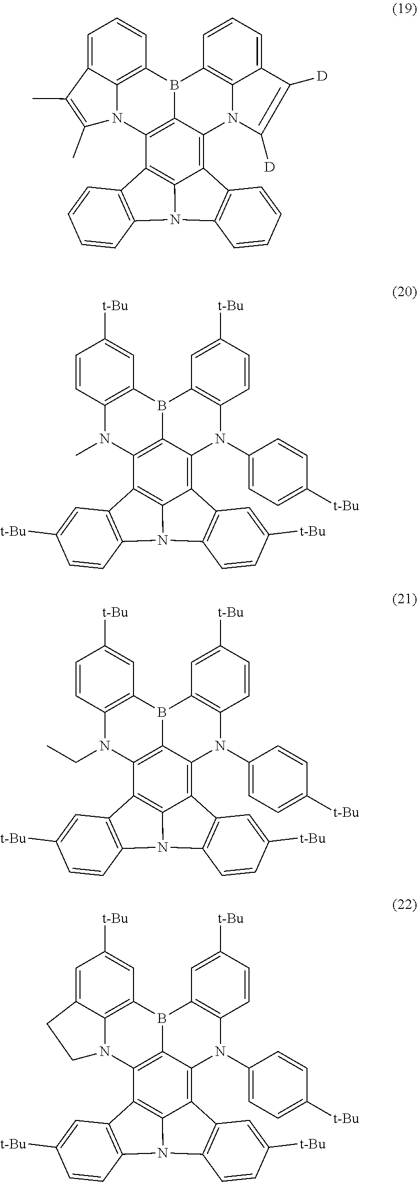

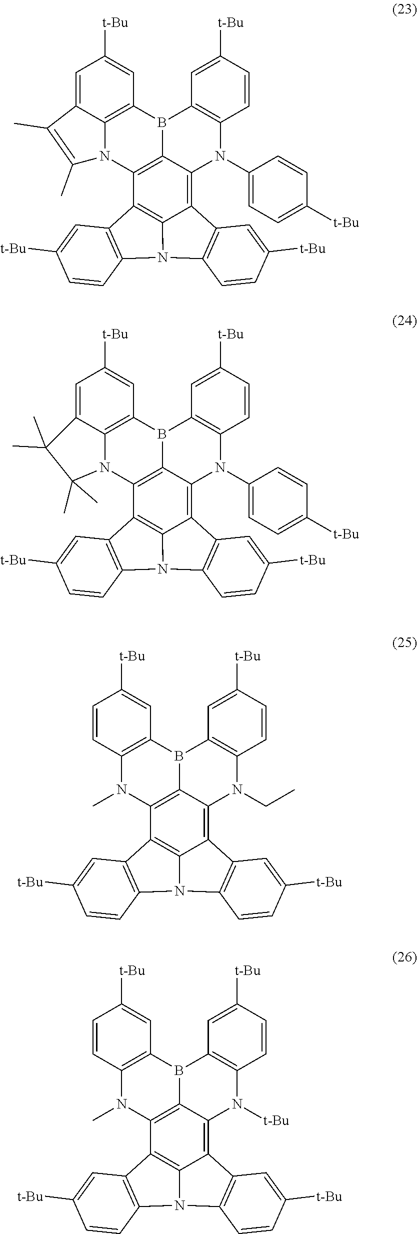 [SMILES: Cc1c(C)n2c3c(cc(C(C)(C)C)cc13)B1c3cc(C(C)(C)C)ccc3N(c3ccc(C(C)(C)C)cc3)c3c1c-2c1c2cc(C(C)(C)C)ccc2n2c4ccc(C(C)(C)C)cc4c3c12 ; CC(C)(C)c1ccc(N2c3ccc(C(C)(C)C)cc3B3c4cc(C(C)(C)C)cc5c4N(c4c3c2c2c3cc(C(C)(C)C)ccc3n3c6ccc(C(C)(C)C)cc6c4c23)C(C)(C)C5(C)C)cc1 ; CCN1c2ccc(C(C)(C)C)cc2B2c3cc(C(C)(C)C)ccc3N(C)c3c2c1c1c2cc(C(C)(C)C)ccc2n2c4ccc(C(C)(C)C)cc4c3c12 ; CN1c2ccc(C(C)(C)C)cc2B2c3cc(C(C)(C)C)ccc3N(C(C)(C)C)c3c2c1c1c2cc(C(C)(C)C)ccc2n2c4ccc(C(C)(C)C)cc4c3c12]

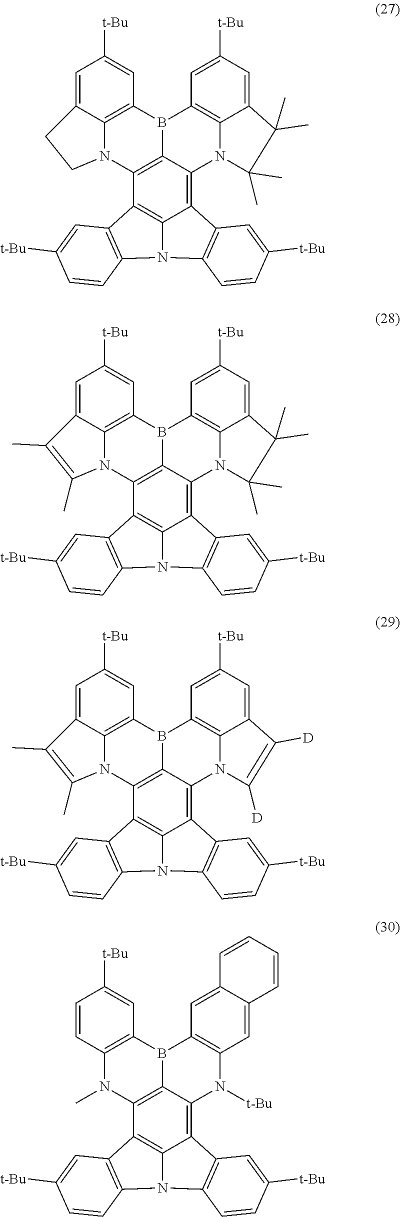

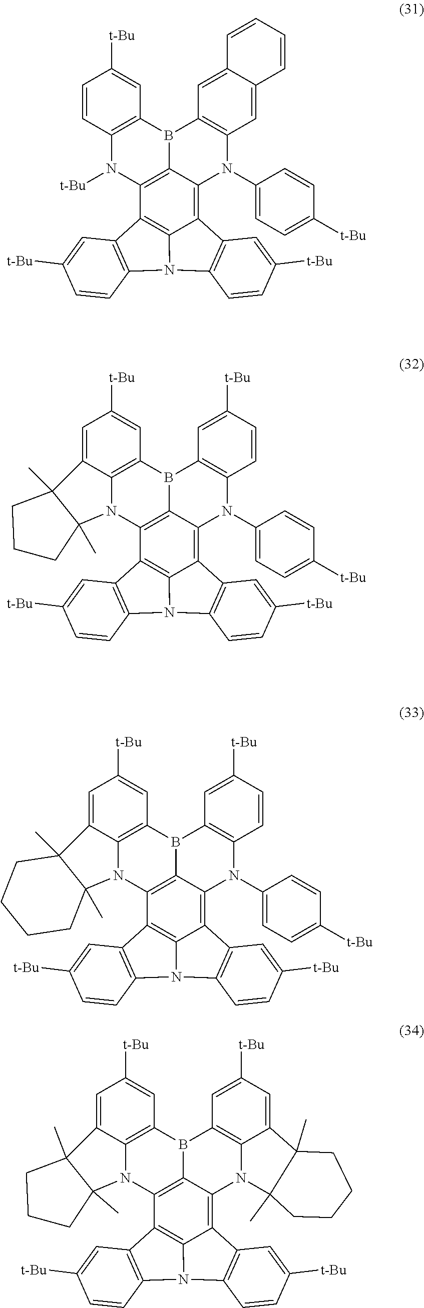

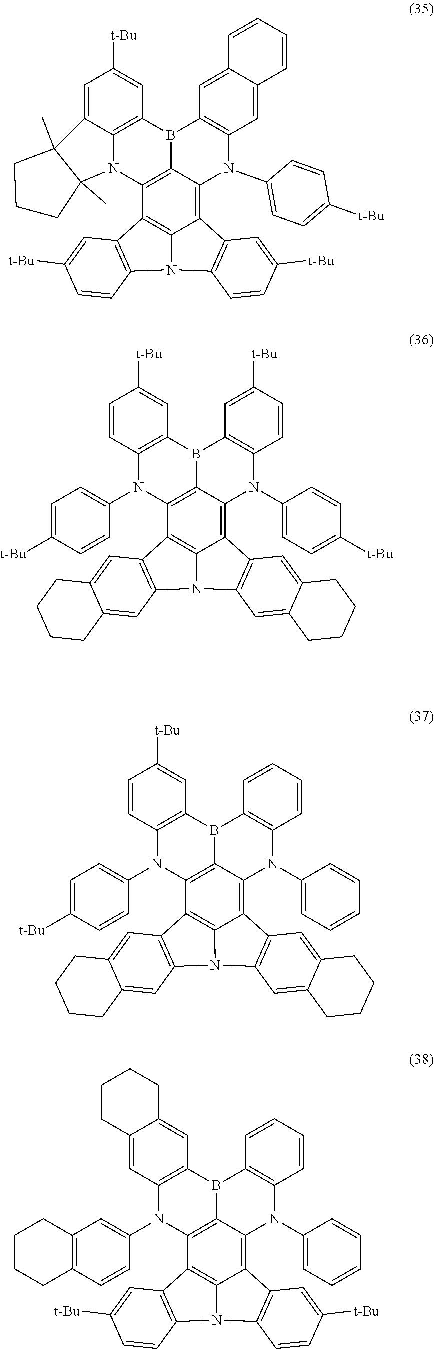 [SMILES: CC(C)(C)c1ccc(N2c3cc4ccccc4cc3B3c4cc(C(C)(C)C)cc5c4N(c4c3c2c2c3cc(C(C)(C)C)ccc3n3c6ccc(C(C)(C)C)cc6c4c23)C2(C)CCCC52C)cc1 ; CC(C)(C)c1ccc(N2c3ccc(C(C)(C)C)cc3B3c4cc(C(C)(C)C)ccc4N(c4ccc(C(C)(C)C)cc4)c4c3c2c2c3cc5c(cc3n3c6cc7c(cc6c4c23)CCCC7)CCCC5)cc1 ; CC(C)(C)c1ccc(N2c3ccc(C(C)(C)C)cc3B3c4ccccc4N(c4ccccc4)c4c3c2c2c3cc5c(cc3n3c6cc7c(cc6c4c23)CCCC7)CCCC5)cc1 ; CC(C)(C)c1ccc2c(c1)c1c3c4c(c5c6cc(C(C)(C)C)ccc6n2c15)N(c1ccc2c(c1)CCCC2)c1cc2c(cc1B4c1ccccc1N3c1ccccc1)CCCC2]

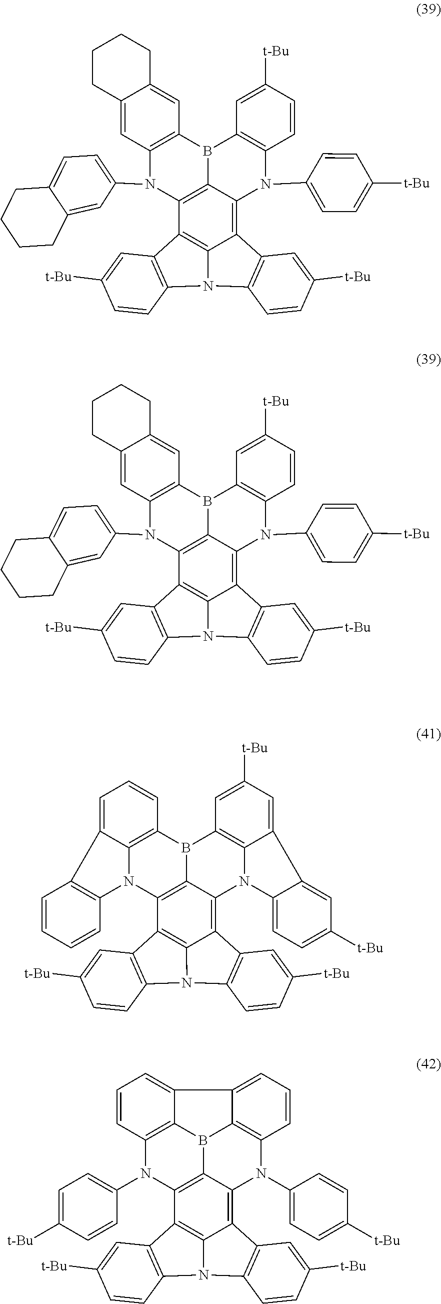 [SMILES: CC(C)(C)c1ccc(N2c3ccc(C(C)(C)C)cc3B3c4cc5c(cc4N(c4ccc6c(c4)CCCC6)c4c3c2c2c3cc(C(C)(C)C)ccc3n3c6ccc(C(C)(C)C)cc6c4c23)CCCC5)cc1 ; CC(C)(C)c1ccc(N2c3ccc(C(C)(C)C)cc3B3c4cc5c(cc4N(c4ccc6c(c4)CCCC6)c4c3c2c2c3cc(C(C)(C)C)ccc3n3c6ccc(C(C)(C)C)cc6c4c23)CCCC5)cc1 ; CC(C)(C)c1ccc2c(c1)c1cc(C(C)(C)C)cc3c1n2-c1c2c(c4c5cc(C(C)(C)C)ccc5n5c6ccc(C(C)(C)C)cc6c1c45)-n1c4ccccc4c4cccc(c41)B23 ; CC(C)(C)c1ccc(N2c3cccc4c3B3c5c-4cccc5N(c4ccc(C(C)(C)C)cc4)c4c3c2c2c3cc(C(C)(C)C)ccc3n3c5ccc(C(C)(C)C)cc5c4c23)cc1]

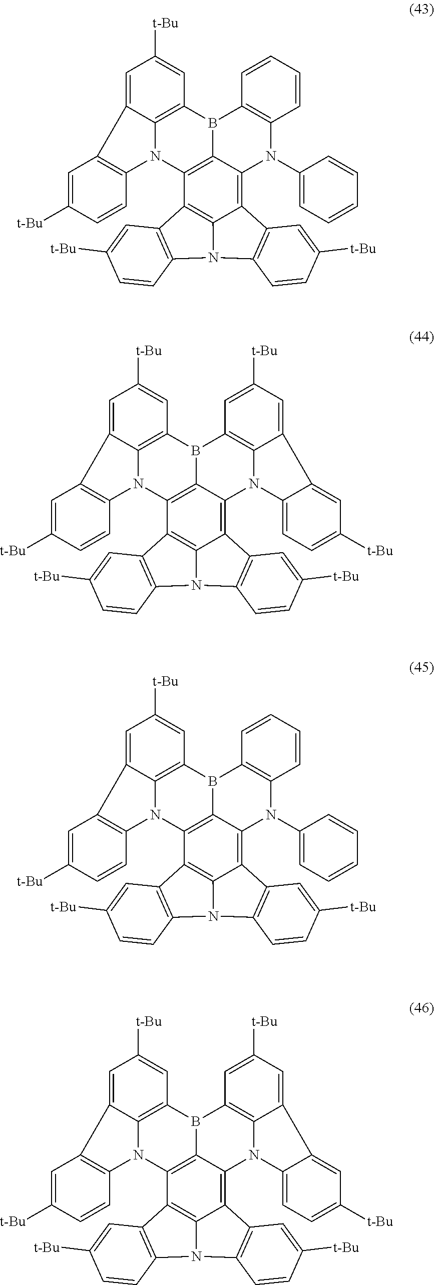

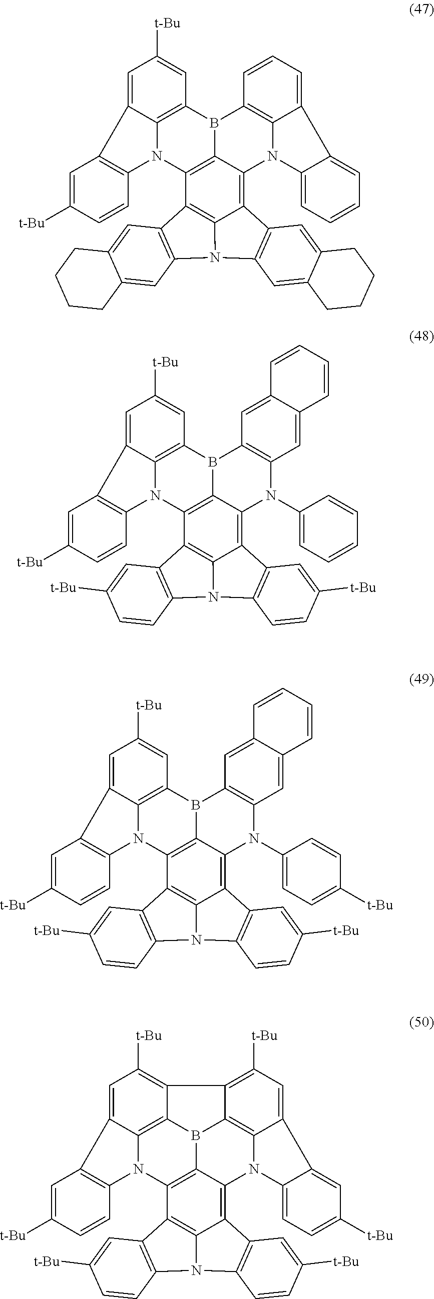

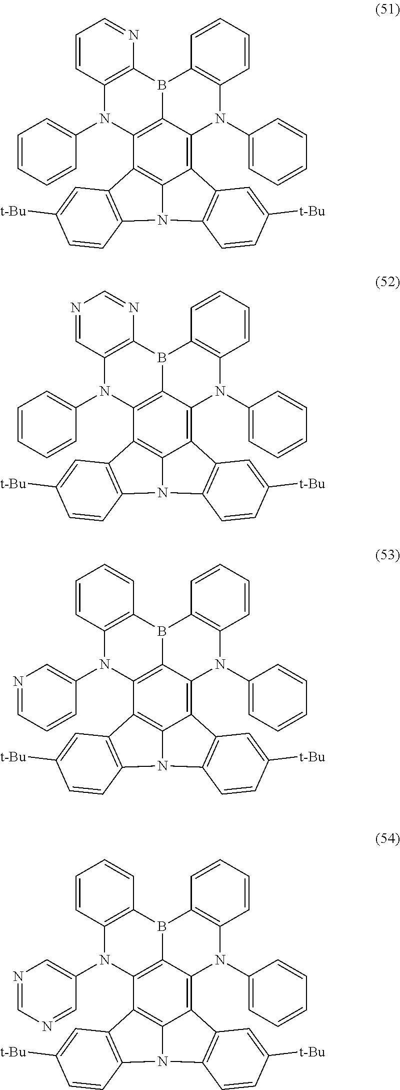

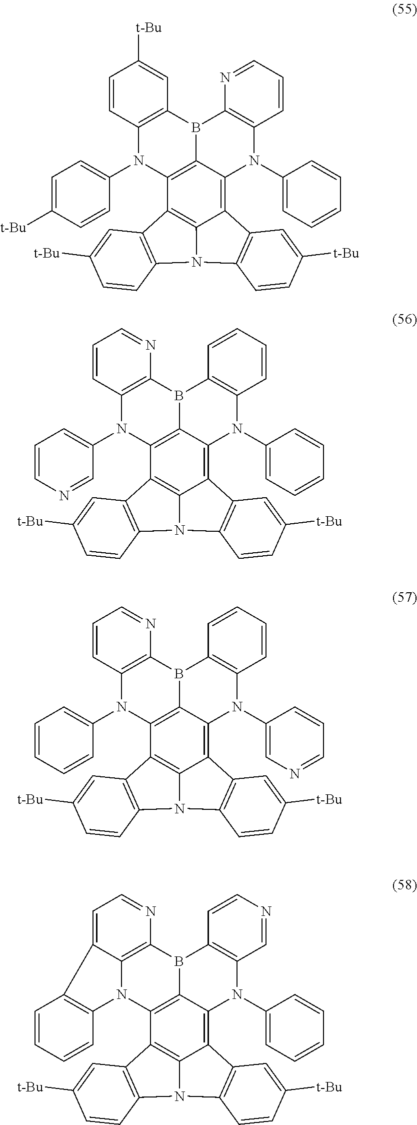

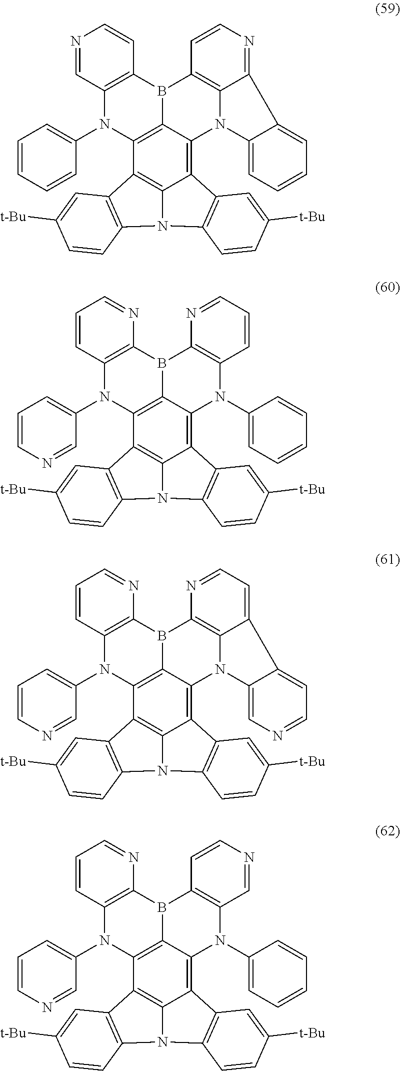

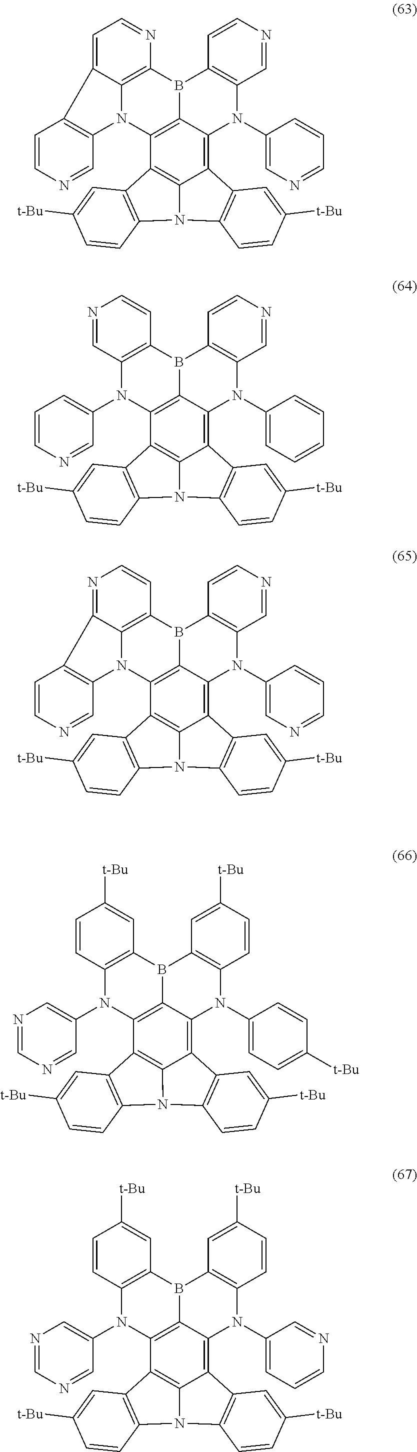

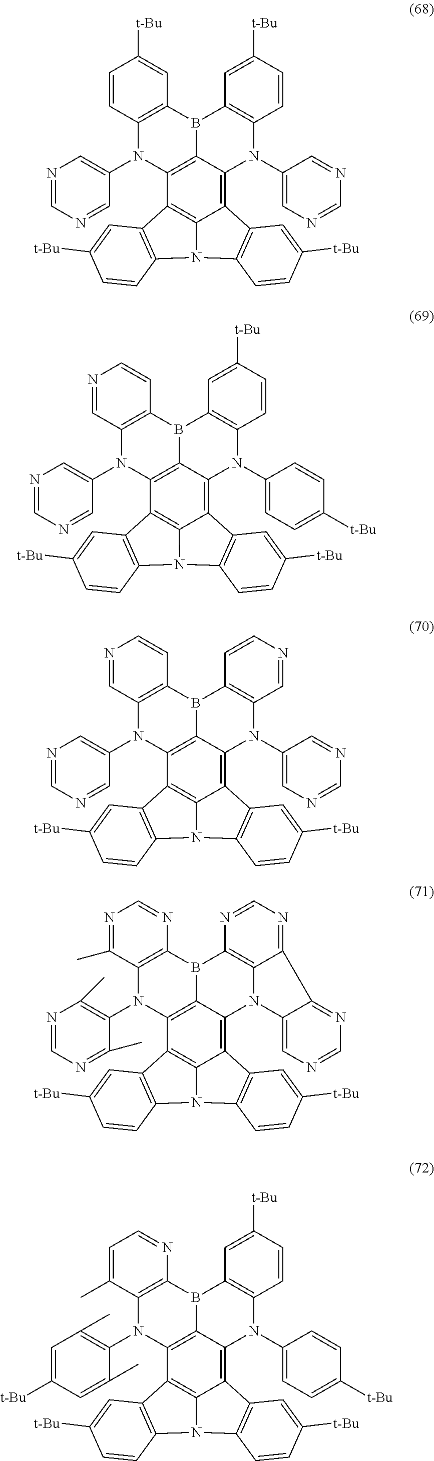

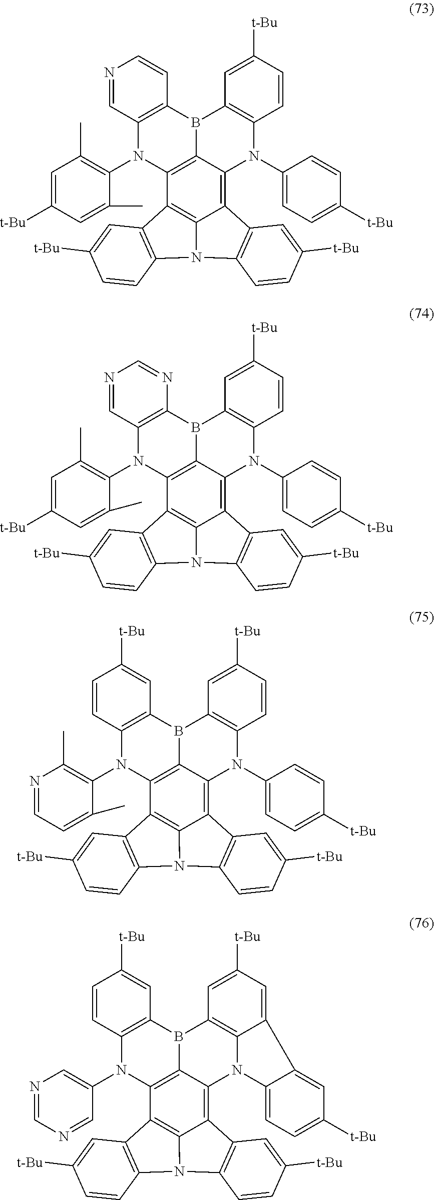

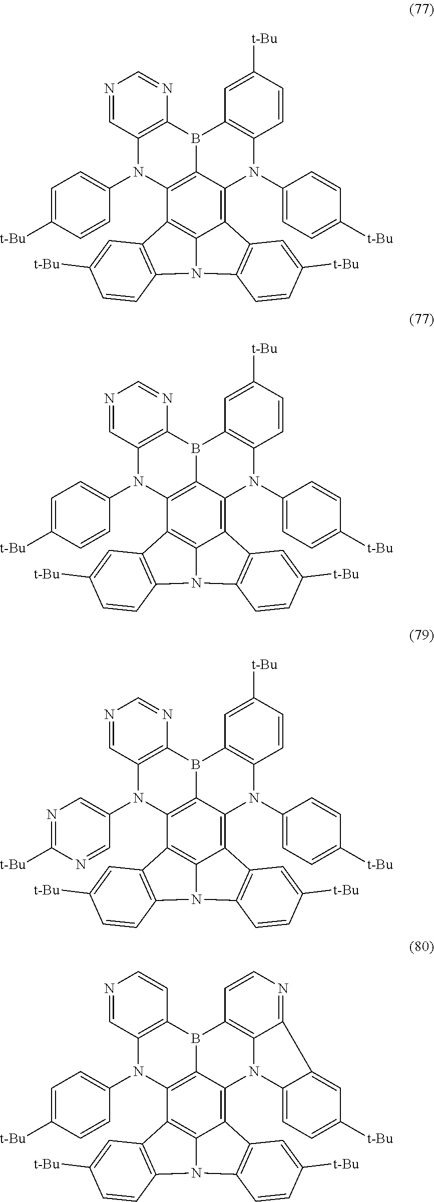

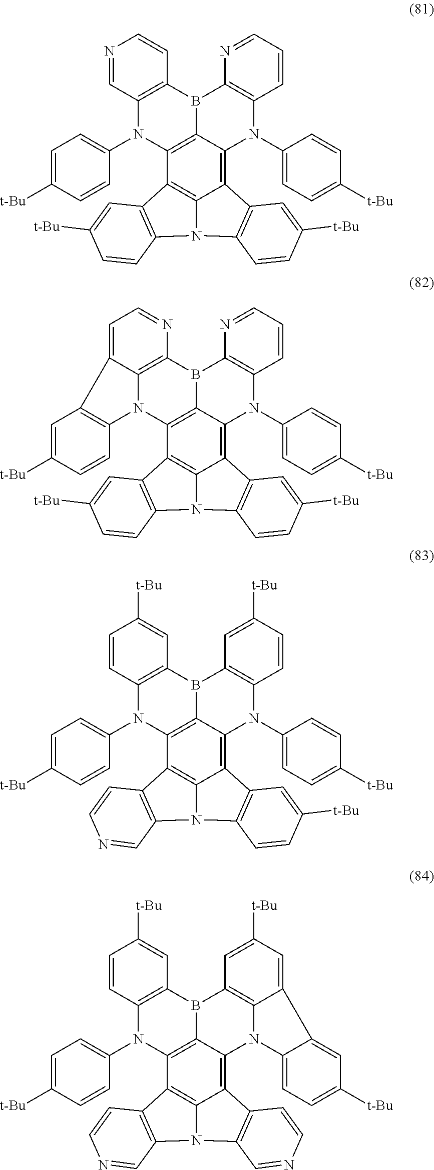

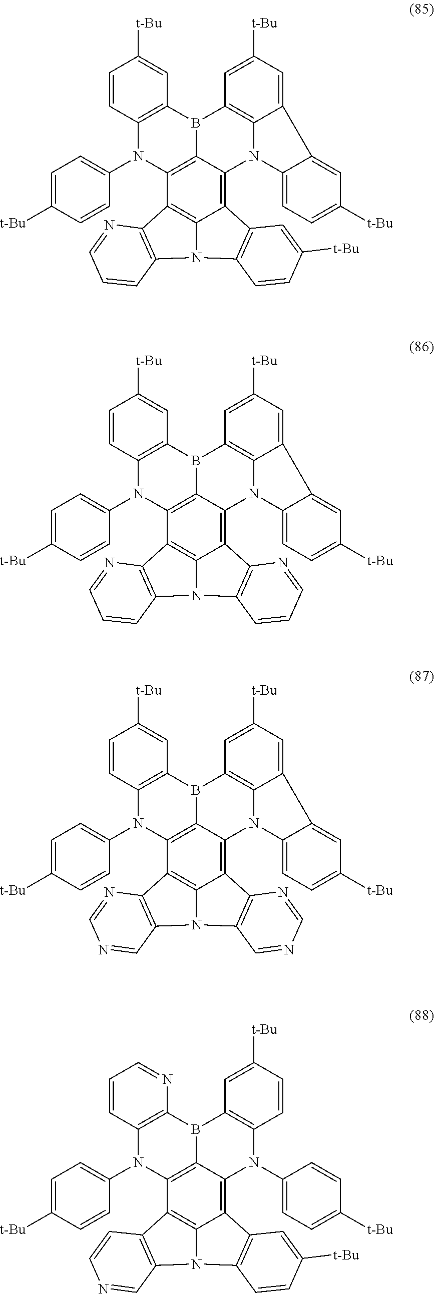 [SMILES: CC(C)(C)c1ccc(N2c3ccc(C(C)(C)C)cc3B3c4c(c5c6cc(C(C)(C)C)ccc6n6c7cccnc7c(c42)c56)-n2c4ccc(C(C)(C)C)cc4c4cc(C(C)(C)C)cc3c42)cc1 ; CC(C)(C)c1ccc(N2c3ccc(C(C)(C)C)cc3B3c4c2c2c5ncccc5n5c6cccnc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5ncncc5n5c6cncnc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4ncccc4N(c4ccc(C(C)(C)C)cc4)c4c3c2c2c3cc(C(C)(C)C)ccc3n3c5cnccc5c4c23)cc1]

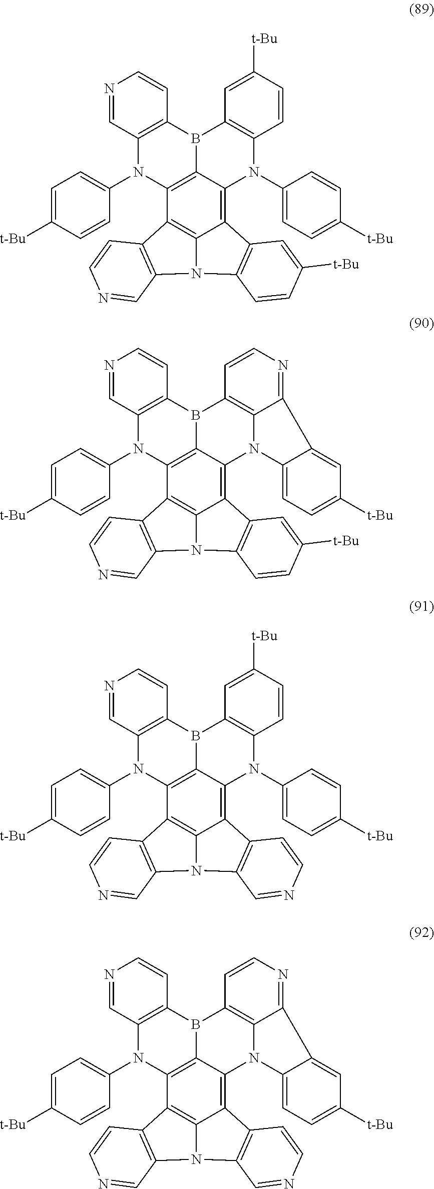 [SMILES: CC(C)(C)c1ccc(N2c3ccc(C(C)(C)C)cc3B3c4ccncc4N(c4ccc(C(C)(C)C)cc4)c4c3c2c2c3cc(C(C)(C)C)ccc3n3c5cnccc5c4c23)cc1 ; CC(C)(C)c1ccc(N2c3cnccc3B3c4c2c2c5ccncc5n5c6ccc(C(C)(C)C)cc6c(c4-n4c6ccc(C(C)(C)C)cc6c6nccc3c64)c25)cc1 ; CC(C)(C)c1ccc(N2c3ccc(C(C)(C)C)cc3B3c4ccncc4N(c4ccc(C(C)(C)C)cc4)c4c3c2c2c3ccncc3n3c5cnccc5c4c23)cc1 ; CC(C)(C)c1ccc(N2c3cnccc3B3c4c2c2c5ccncc5n5c6cnccc6c(c4-n4c6ccc(C(C)(C)C)cc6c6nccc3c64)c25)cc1]

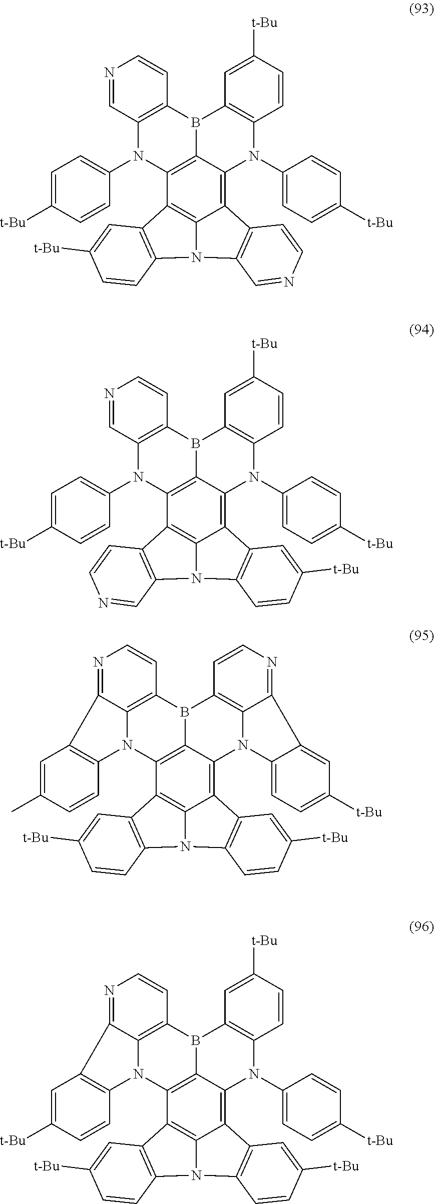

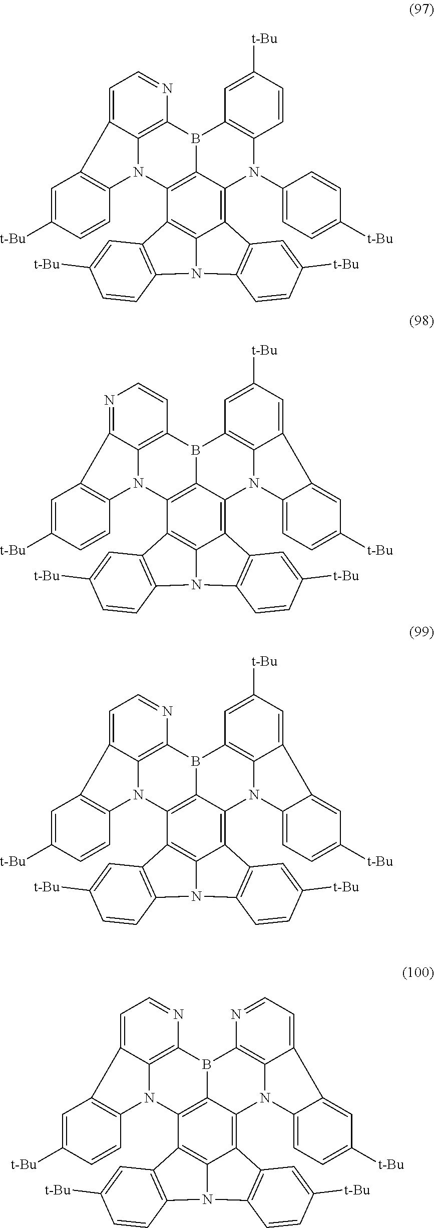

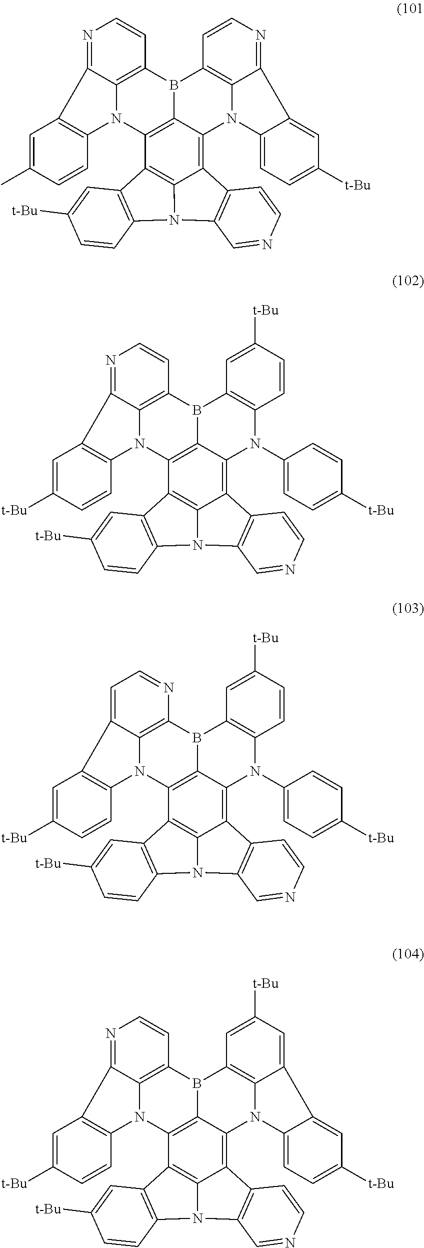 [SMILES: Cc1ccc2c(c1)c1nccc3c1n2-c1c2c(c4c5ccncc5n5c6ccc(C(C)(C)C)cc6c1c45)-n1c4ccc(C(C)(C)C)cc4c4nccc(c41)B23 ; CC(C)(C)c1ccc(N2c3ccc(C(C)(C)C)cc3B3c4c2c2c5ccncc5n5c6ccc(C(C)(C)C)cc6c(c4-n4c6ccc(C(C)(C)C)cc6c6nccc3c64)c25)cc1 ; CC(C)(C)c1ccc(N2c3ccc(C(C)(C)C)cc3B3c4c2c2c5ccncc5n5c6ccc(C(C)(C)C)cc6c(c4-n4c6ccc(C(C)(C)C)cc6c6ccnc3c64)c25)cc1 ; CC(C)(C)c1ccc2c(c1)c1cc(C(C)(C)C)cc3c1n2-c1c2c(c4c5cc(C(C)(C)C)ccc5n5c6cnccc6c1c45)-n1c4ccc(C(C)(C)C)cc4c4nccc(c41)B23]

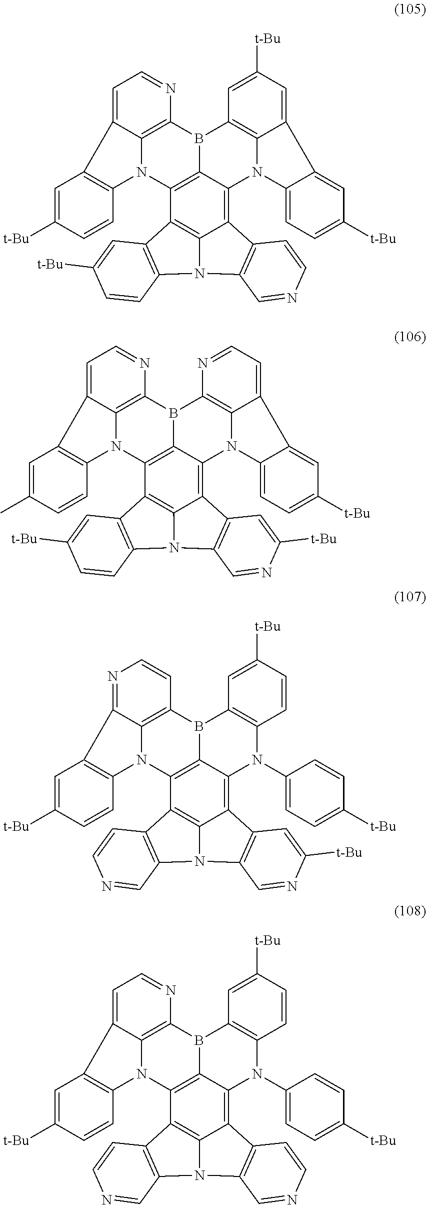 [SMILES: CC(C)(C)c1ccc2c(c1)c1cc(C(C)(C)C)cc3c1n2-c1c2c(c4c5cc(C(C)(C)C)ccc5n5c6cnccc6c1c45)-n1c4ccc(C(C)(C)C)cc4c4ccnc(c41)B23 ; Cc1ccc2c(c1)c1ccnc3c1n2-c1c2c(c4c5cc(C(C)(C)C)ncc5n5c6ccc(C(C)(C)C)cc6c1c45)-n1c4ccc(C(C)(C)C)cc4c4ccnc(c41)B23 ; CC(C)(C)c1ccc(N2c3ccc(C(C)(C)C)cc3B3c4c2c2c5cc(C(C)(C)C)ncc5n5c6cnccc6c(c4-n4c6ccc(C(C)(C)C)cc6c6nccc3c64)c25)cc1 ; CC(C)(C)c1ccc(N2c3ccc(C(C)(C)C)cc3B3c4c2c2c5ccncc5n5c6cnccc6c(c4-n4c6ccc(C(C)(C)C)cc6c6ccnc3c64)c25)cc1]

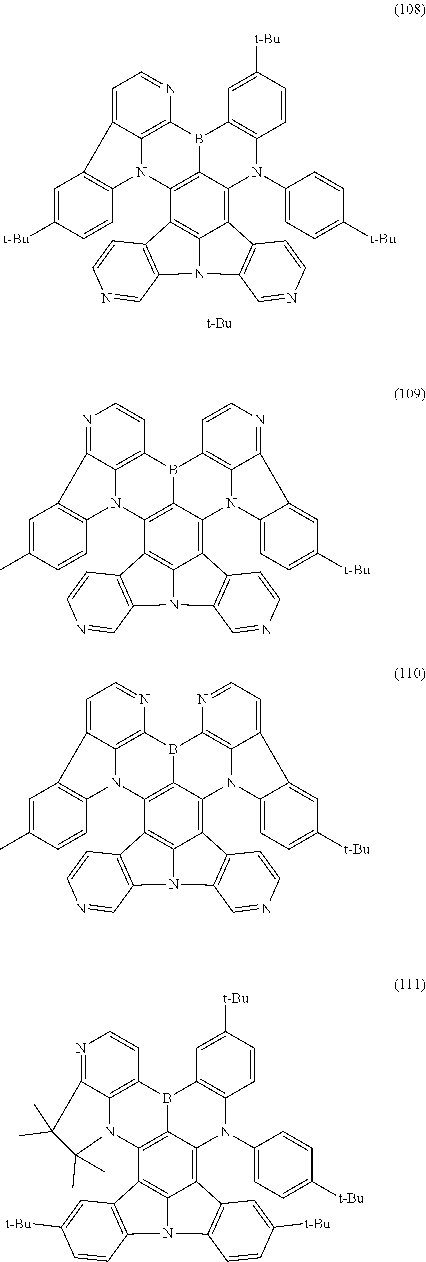 [SMILES: CC(C)(C)c1ccc(N2c3ccc(C(C)(C)C)cc3B3c4c2c2c5ccncc5n5c6cnccc6c(c4-n4c6ccc(C(C)(C)C)cc6c6ccnc3c64)c25)cc1 ; Cc1ccc2c(c1)c1nccc3c1n2-c1c2c(c4c5ccncc5n5c6cnccc6c1c45)-n1c4ccc(C(C)(C)C)cc4c4nccc(c41)B23 ; Cc1ccc2c(c1)c1ccnc3c1n2-c1c2c(c4c5ccncc5n5c6cnccc6c1c45)-n1c4ccc(C(C)(C)C)cc4c4ccnc(c41)B23 ; CC(C)(C)c1ccc(N2c3ccc(C(C)(C)C)cc3B3c4ccnc5c4N(c4c3c2c2c3cc(C(C)(C)C)ccc3n3c6ccc(C(C)(C)C)cc6c4c23)C(C)(C)C5(C)C)cc1]

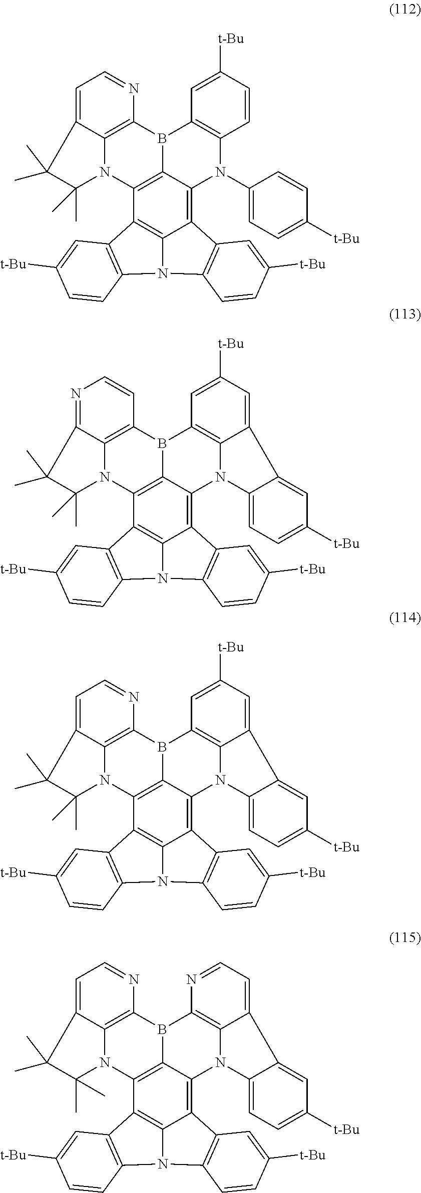

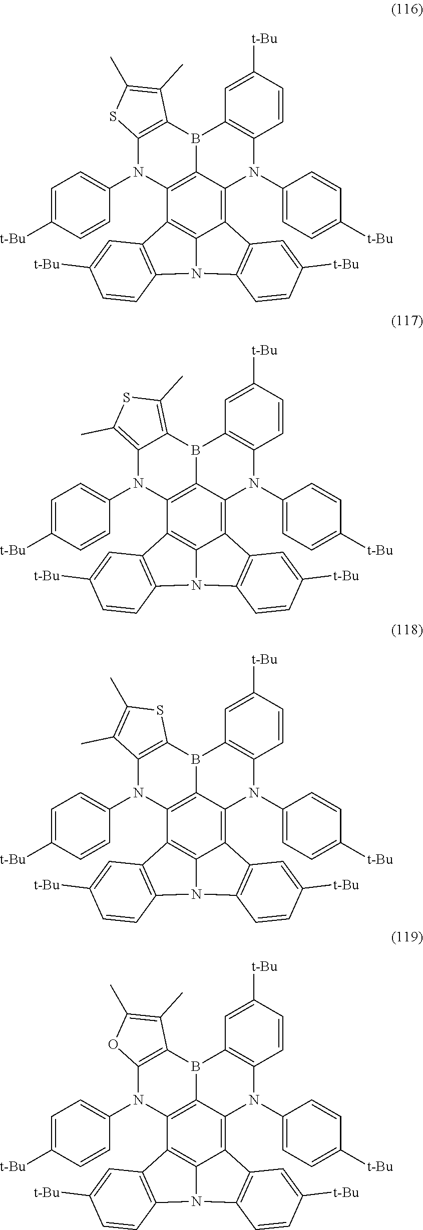

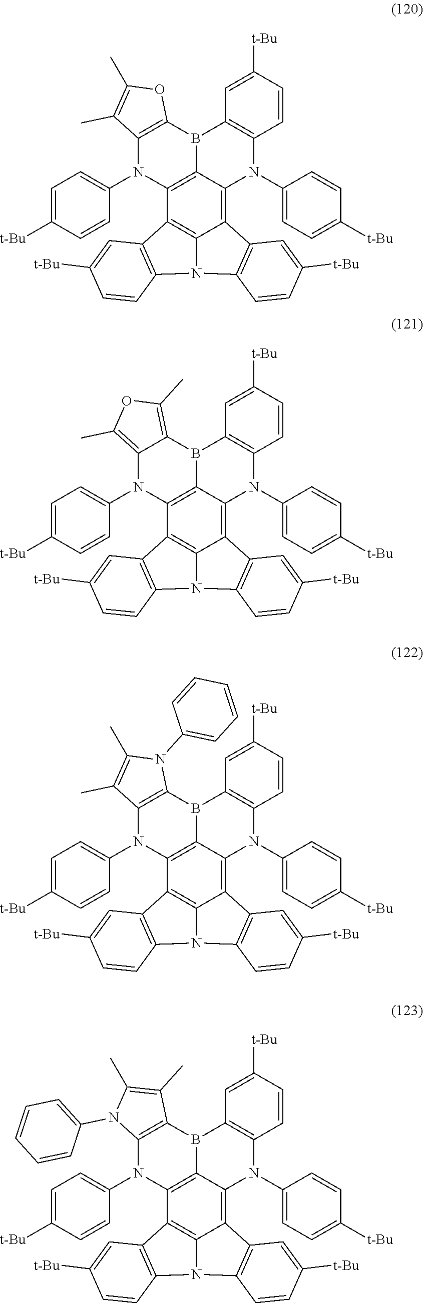

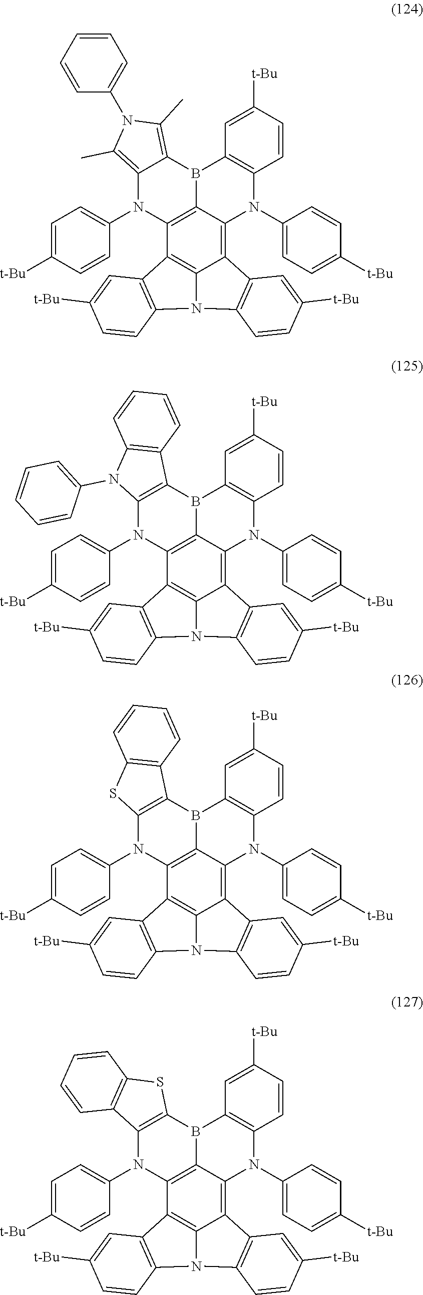

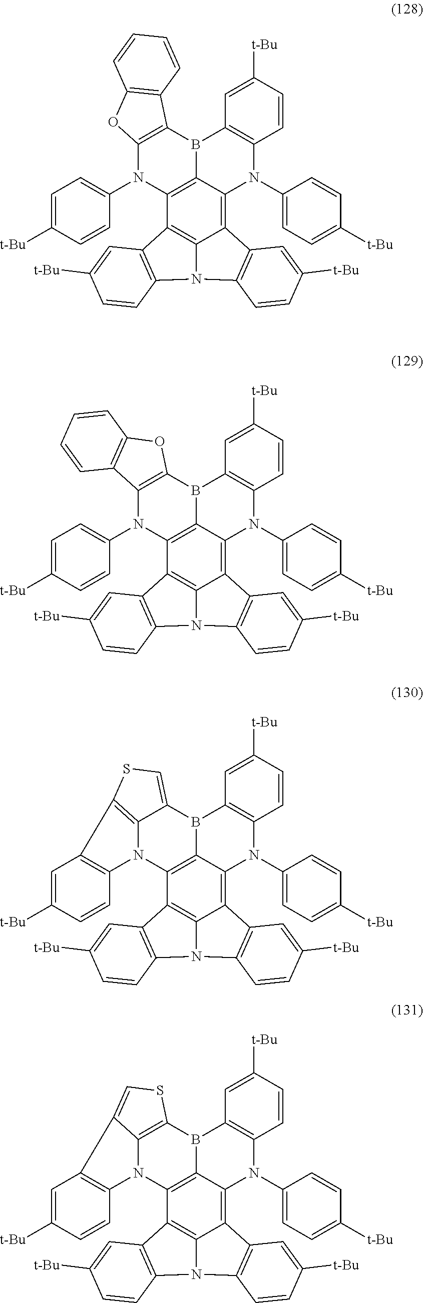

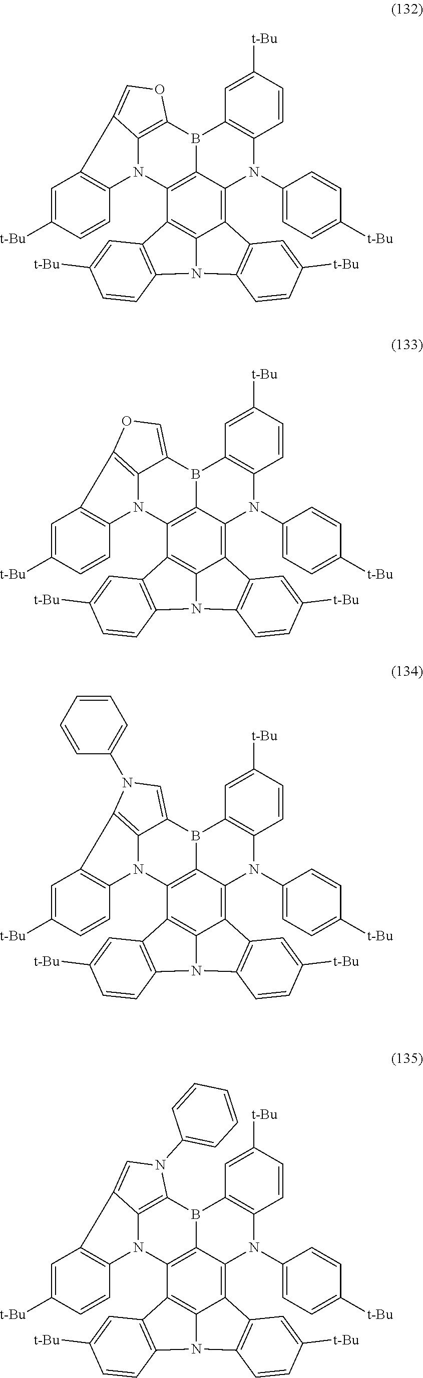

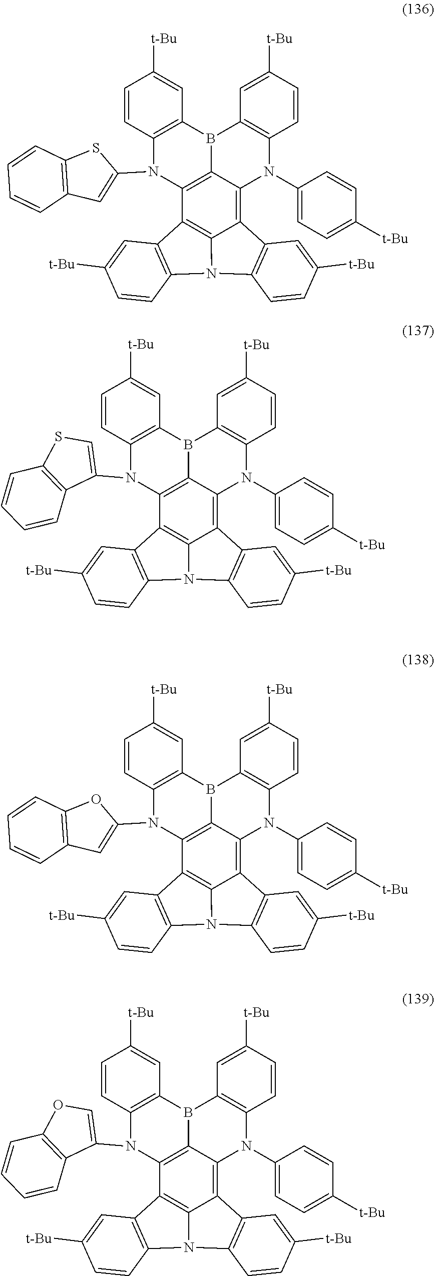

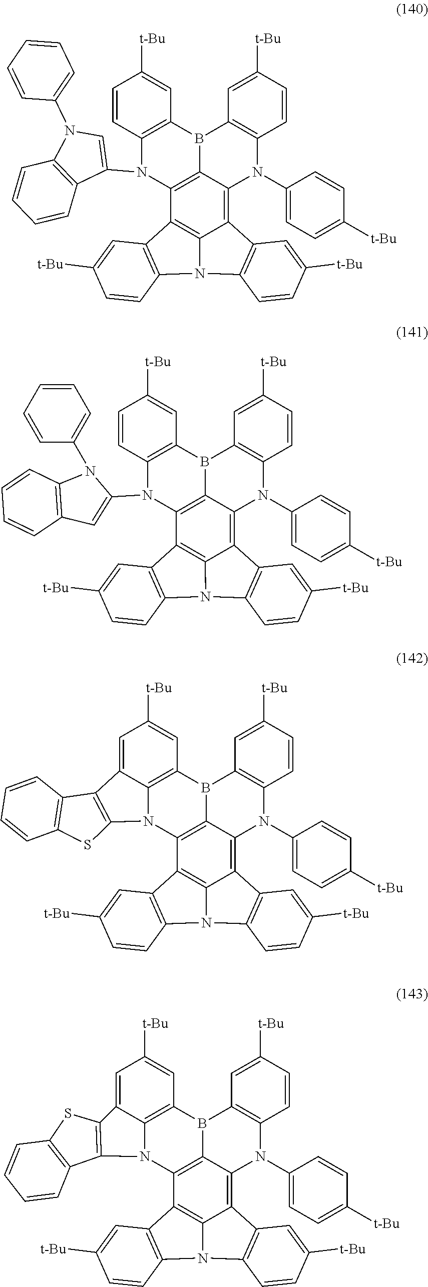

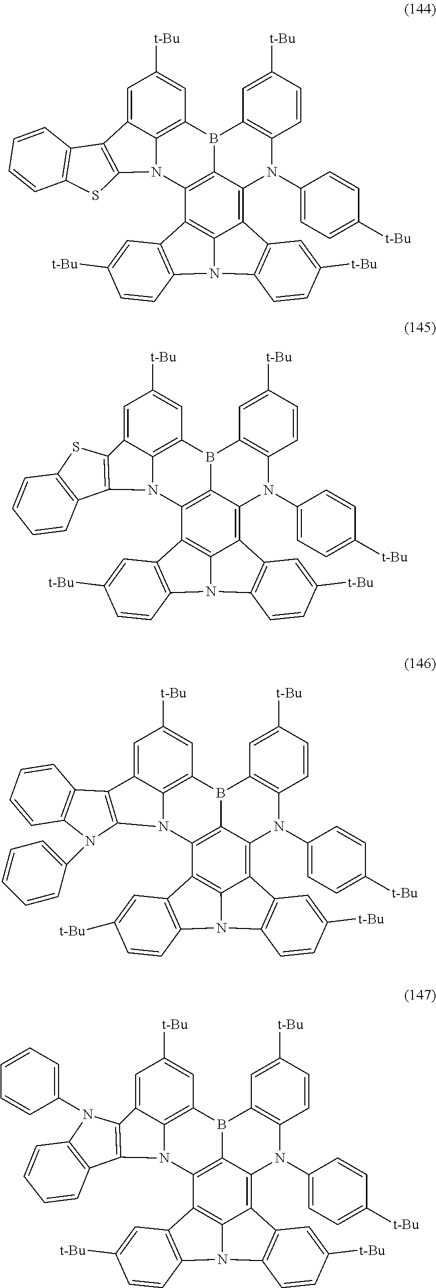

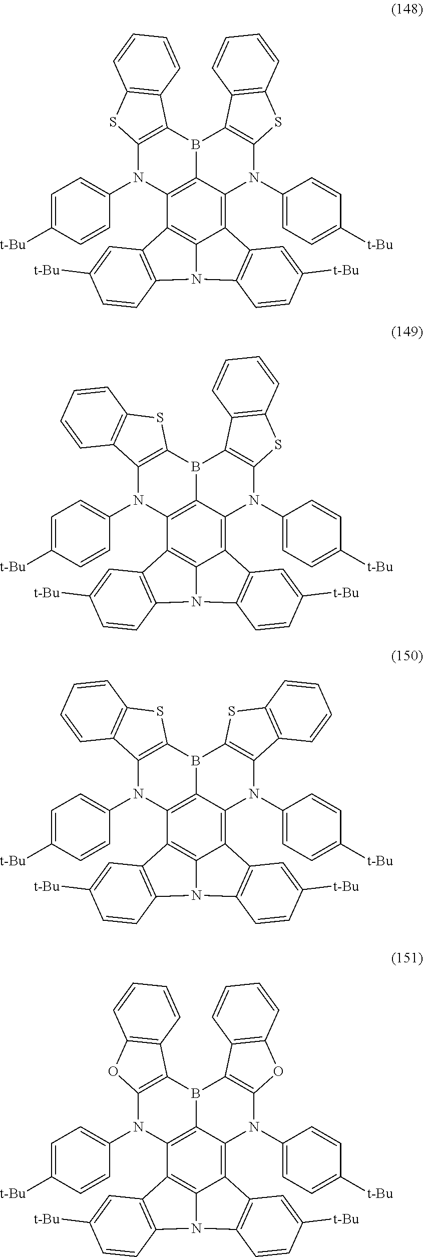 [SMILES: CC(C)(C)c1ccc(N2c3sc4ccccc4c3B3c4c2c2c5cc(C(C)(C)C)ccc5n5c6ccc(C(C)(C)C)cc6c(c4N(c4ccc(C(C)(C)C)cc4)c4sc6ccccc6c43)c25)cc1 ; CC(C)(C)c1ccc(N2c3sc4ccccc4c3B3c4sc5ccccc5c4N(c4ccc(C(C)(C)C)cc4)c4c3c2c2c3cc(C(C)(C)C)ccc3n3c5ccc(C(C)(C)C)cc5c4c23)cc1 ; CC(C)(C)c1ccc(N2c3c(sc4ccccc34)B3c4sc5ccccc5c4N(c4ccc(C(C)(C)C)cc4)c4c3c2c2c3cc(C(C)(C)C)ccc3n3c5ccc(C(C)(C)C)cc5c4c23)cc1 ; CC(C)(C)c1ccc(N2c3oc4ccccc4c3B3c4c2c2c5cc(C(C)(C)C)ccc5n5c6ccc(C(C)(C)C)cc6c(c4N(c4ccc(C(C)(C)C)cc4)c4oc6ccccc6c43)c25)cc1]

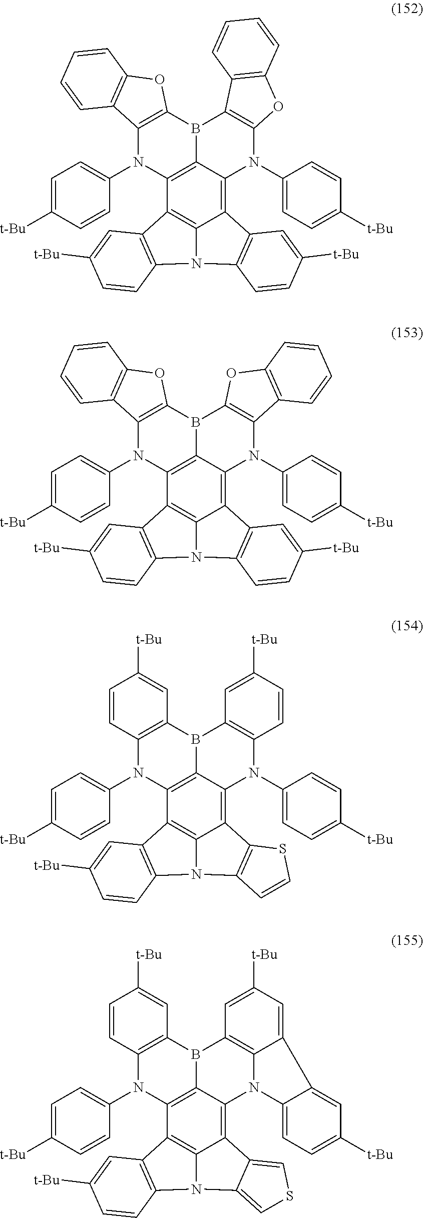 [SMILES: CC(C)(C)c1ccc(N2c3oc4ccccc4c3B3c4oc5ccccc5c4N(c4ccc(C(C)(C)C)cc4)c4c3c2c2c3cc(C(C)(C)C)ccc3n3c5ccc(C(C)(C)C)cc5c4c23)cc1 ; CC(C)(C)c1ccc(N2c3c(oc4ccccc34)B3c4oc5ccccc5c4N(c4ccc(C(C)(C)C)cc4)c4c3c2c2c3cc(C(C)(C)C)ccc3n3c5ccc(C(C)(C)C)cc5c4c23)cc1 ; CC(C)(C)c1ccc(N2c3ccc(C(C)(C)C)cc3B3c4cc(C(C)(C)C)ccc4N(c4ccc(C(C)(C)C)cc4)c4c3c2c2c3cc(C(C)(C)C)ccc3n3c5ccsc5c4c23)cc1 ; CC(C)(C)c1ccc(N2c3ccc(C(C)(C)C)cc3B3c4c2c2c5cc(C(C)(C)C)ccc5n5c6cscc6c(c4-n4c6ccc(C(C)(C)C)cc6c6cc(C(C)(C)C)cc3c64)c25)cc1]

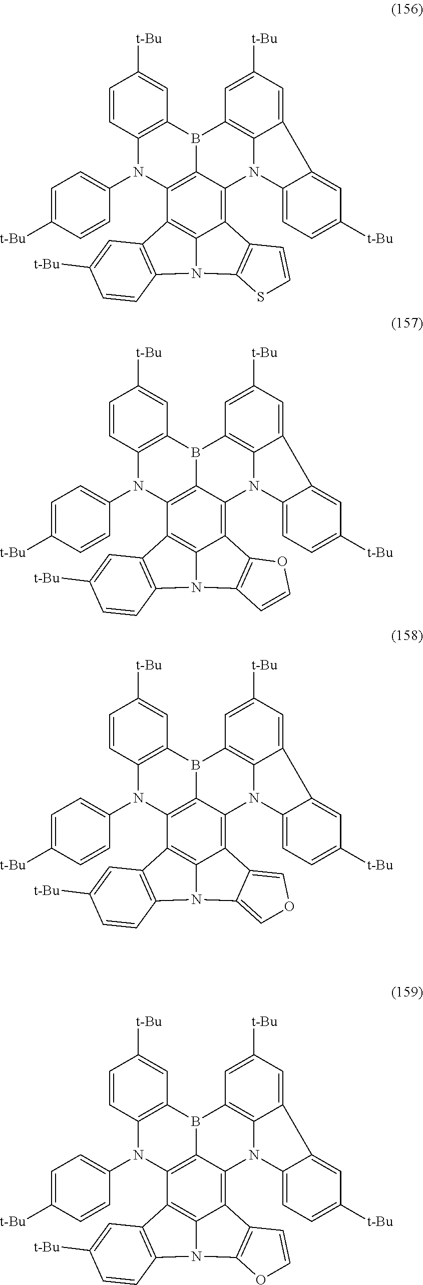 [SMILES: CC(C)(C)c1ccc(N2c3ccc(C(C)(C)C)cc3B3c4c2c2c5cc(C(C)(C)C)ccc5n5c6sccc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5cc(C(C)(C)C)ccc5n5c6ccoc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5cc(C(C)(C)C)ccc5n5c6cocc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5cc(C(C)(C)C)ccc5n5c6occc6c(c4-n4c6ccc(C(C)(C)C)cc6c6cc(C(C)(C)C)cc3c64)c25)cc1]

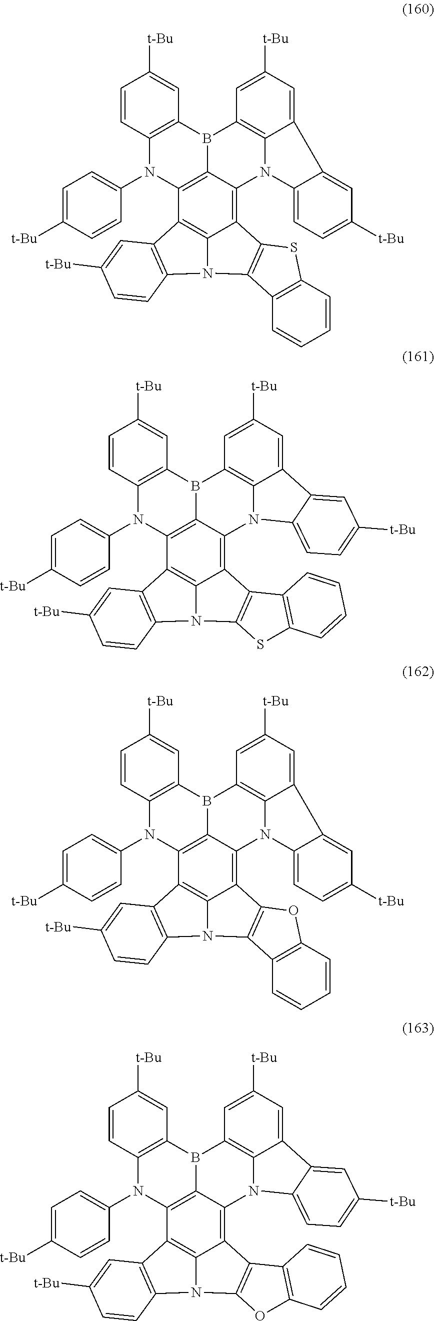

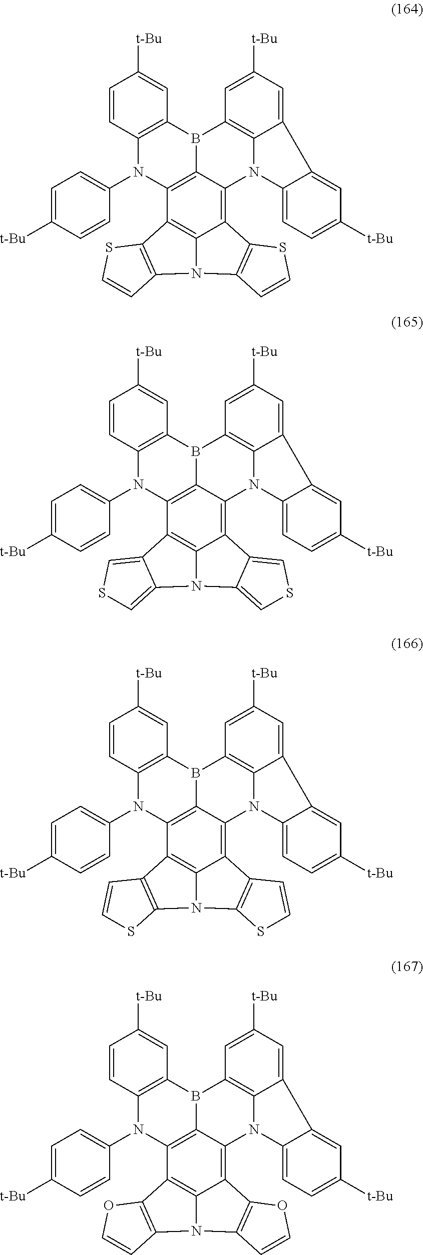 [SMILES: CC(C)(C)c1ccc(N2c3ccc(C(C)(C)C)cc3B3c4c2c2c5sccc5n5c6ccsc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5cscc5n5c6cscc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5ccsc5n5c6sccc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5occc5n5c6ccoc6c(c4-n4c6ccc(C(C)(C)C)cc6c6cc(C(C)(C)C)cc3c64)c25)cc1]

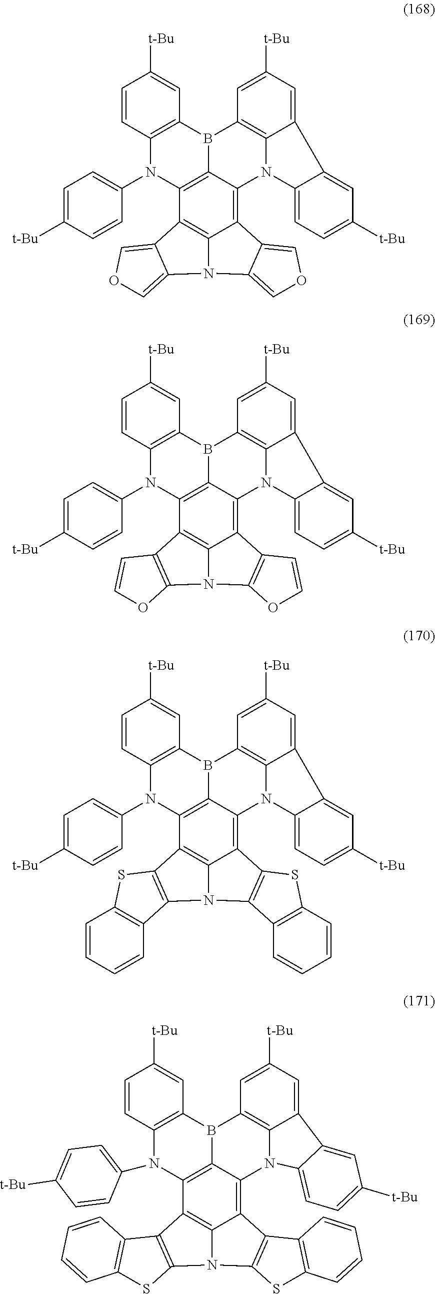 [SMILES: CC(C)(C)c1ccc(N2c3ccc(C(C)(C)C)cc3B3c4c2c2c5cocc5n5c6cocc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5ccoc5n5c6occc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5sc6ccccc6c5n5c6c7ccccc7sc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5c6ccccc6sc5n5c6sc7ccccc7c6c(c4-n4c6ccc(C(C)(C)C)cc6c6cc(C(C)(C)C)cc3c64)c25)cc1]

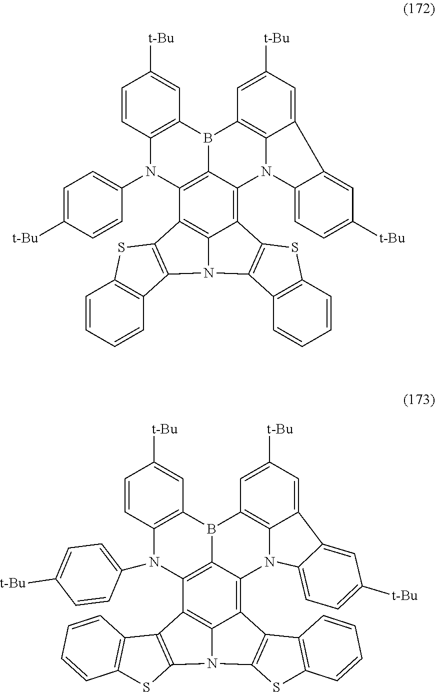 [SMILES: CC(C)(C)c1ccc(N2c3ccc(C(C)(C)C)cc3B3c4c2c2c5sc6ccccc6c5n5c6c7ccccc7sc6c(c4-n4c6ccc(C(C)(C)C)cc6c6cc(C(C)(C)C)cc3c64)c25)cc1 ; CC(C)(C)c1ccc(N2c3ccc(C(C)(C)C)cc3B3c4c2c2c5c6ccccc6sc5n5c6sc7ccccc7c6c(c4-n4c6ccc(C(C)(C)C)cc6c6cc(C(C)(C)C)cc3c64)c25)cc1]

11. Application of the organic electroluminescent materials according to any one of claims 1-10 in an organic electroluminescent device.

12. An organic electroluminescent device, comprising at least one functional layer, wherein the functional layer contains the organic electroluminescent materials according to any one of claims 1-10.

13. The organic electroluminescent device according to claim 12, wherein the organic electroluminescent materials are used as a material for a light-emitting layer or a doping material for the light-emitting layer.

14. A lighting or display device, comprising the organic electroluminescent device according to any one of claims 12-13.
